(19) United States
(12) Patent Application Publication
(10) Pub. No.: US 2010/0220517 A1
(43) Pub. Date: Sep. 2, 2010

(54) SEMICONDUCTOR DEVICE

(75) Inventor: Shota Okayama, Tokyo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 12/702,724

(22) Filed: Feb. 9, 2010

(30) Foreign Application Priority Data
Feb. 27, 2009 (JP) 2009-045815
Sep. 9, 2009 (JP) 2009-208331

(51) Int. Cl. G11C 11/00; G11C 7/00

(52) U.S. Cl. 365/158; 365/189.15; 365/189.16

(57) ABSTRACT

Data which sets up operation parameters, etc. of an internal circuit is supplied stably over a long period of time. In a cell array in which MRAM cells are arranged, read/write of test data is performed in a PROM mode. Finally, data writing is specifically performed to the memory cells in an OTP mode.

### CROSS REFERENCES TO RELATED APPLICATIONS

The disclosure of Japanese Patent Application No. 2009-45815 filed on Feb. 27, 2009 and Japanese Patent Application No. 2009-208331 filed on Sep. 9, 2009 each including the specification, drawings and abstract are incorporated herein by reference in its entirety.

### BACKGROUND OF THE INVENTION

The present invention relates to a semiconductor device, in particular, to configuration of a storage unit which stores internal operation environment setup data, such as trimming data and repair data, in a nonvolatile manner. More specifically, the present invention relates to a magnetic semiconductor memory unit in the semiconductor device which utilizes a variable magnetoresistive element as a data storage element.

One of the nonvolatile semiconductor memories which store data in a nonvolatile manner includes a magnetic semiconductor memory (MRAM). The MRAM utilizes a variable magnetoresistive element, such as an MTJ element (magnetic tunneling junction element) or TMR element (tunneling magnetoresistive element), as a data storage element. The variable magnetoresistive element comprises a fixed layer in which a magnetizing direction is fixedly held irrespective of stored data, a free layer in which a magnetization direction is set corresponding to stored data, and an insulator layer (barrier film) disposed between the fixed layer and the free layer. When the magnetization direction of the fixed layer and the magnetization direction of the free layer are the same (parallel), an electric resistance value of a path which penetrates the variable magnetoresistive element becomes small. On the contrary, when the magnetization direction of the free layer and the magnetization direction of the fixed layer are counter direction (anti-parallel), the electric resistance value of the path which penetrates the variable magnetoresistive element becomes large. The magnitude difference of the electric resistance value is associated with data “0” and “1.”

Not only in an MRAM but in a semiconductor device and a semiconductor storage device at large, it is necessary to perform regulation of an internal reference voltage level, adjustment of an operation timing, and replacement and repair of a bad memory cell by a redundant cell, and others. Therefore, trimming data and repair data for redundancy substitution are stored in the interior. When storing such internal operation adjustment/setup data in a fuse element, the occupied area of the fuse element becomes large, and rewriting of data once programmed in the fuse element is difficult to perform.

Therefore, the internal operation environment setup data, such as the trimming data and the repair data, are held in a nonvolatile memory cell in many cases. As a memory which stores such internal operation environment setup data, there are an OTPROM (onetime programmable ROM) to which data can be written only once, and a PROM (programmable read only memory) to which data can be rewritten repeatedly. When the OTPROM is utilized, once an evaluation result obtained by a wafer test is written in, it becomes very difficult to write in new data obtained by a subsequent chip-level final test. When the PROM is utilized, since a current-induced magnetic field is used for data writing to a normal memory cell in the MRAM, the induced magnetic field may cause data corruption when holding data over the long term. Another possibility is that an OTPROM and a PROM are mounted over the same chip and that the PROM is utilized as a dedicated rewritable memory. However, the present case requires two memory regions with increased area, accordingly an area penalty increases.

Patent Document 1 (Japanese Patent Laid-open No. Hei 11 (1999)-45233) discloses configuration in which a PROM and an OTPROM are switched over in a microcomputer. In the configuration disclosed by Patent Document 1, a flash memory cell array is provided and a flash/OTP control register area is arranged in a specific area of the flash memory cell array. According to a bit value stored in the flash/OTP control register area, the flash memory cell array is utilized as the flash memory or as the OTPROM.

Patent Document 1 avoids the necessity of taking a different process and a different chip layout for the OTPROM and the PROM, by operating the common flash memory cell array as the PROM or as the OTPROM.

(Patent Document 1) Japanese Patent Laid-open No. Hei 11 (1999)-45233.

### SUMMARY OF THE INVENTION

In the configuration disclosed by Patent Document 1, a flash memory cell array is arranged outside the main body of a CPU (central processing unit) in a microcomputer. Data, including an application program etc., is stored in the flash memory cell array. In Patent Document 1, the internal configuration of the flash memory cell array takes no consideration of a memory area which stores timing data for adjusting an operating characteristic of the flash memory cell array and which stores data for redundancy substitution in bad cell repair. When utilizing an MRAM cell array as a memory cell array in particular, a current-induced magnetic field is utilized for data writing. Therefore, when a PROM area is arranged near the MRAM cell array which stores the ordinary data and when data for setting various operating states (operating environment) is stored in the PROM area, disturbance occurs to the data of the PROM area due to a leakage magnetic field of a magnetic field induced at the time of writing of the ordinary data into the memory cell array. Therefore, there arises a problem that the held data might be destroyed when influence of the leakage magnetic field is exerted over a long period of time.

Also in Patent Document 1, when data for operating characteristic adjustment and for operating environment setup of the flash memory cell array is stored in the OTP memory area, leakage of a charge accumulated in a floating gate of a flash memory cell makes it difficult to hold the held data over a long period of time. Therefore, there arises a problem that it is difficult to secure the operating characteristic. Patent Document 1 fails to take into consideration the characteristic of data holding over a long period of time.

In a flash memory cell, the stored data is set up corresponding to charge quantity accumulated in a floating gate, and a memory cell transistor is set in either state of a low threshold voltage state or a high threshold voltage state, corresponding to the stored data. When utilizing the present flash memory cell as an OTPROM cell for example, a memory cell of a low threshold voltage can be made to shift to a memory cell of a high threshold voltage state. Therefore, when a charge of a mode-specifying-bit storing cell which stores data for specifying the mode to use the flash memory cell array as an OTPROM decreases due to leakage and when the mode specifying bit changes to a PROM-mode specifying bit, rewriting of data of the flash memory cell array may occur accidentally. In the reverse case, there arises a problem that a PROM mode is specified as an OTPROM mode and it may become impossible to rewrite a rewritable bit.

The present invention has been made in view of the above circumstances and provides a semiconductor device comprising a memory unit which can set up accurately internal operation state setup data corresponding to an internal operation situation and can hold it stably over a long period of time, without increasing a chip layout area.

A semiconductor device according to an embodiment of the present invention comprises a memory array including plural nonvolatile memory cells which are arranged in a matrix and each of which stores data in a nonvolatile manner, and a write control circuit which writes data to the nonvolatile memory cells of the memory array. The write control circuit writes data to the nonvolatile memory cell non-destructively on a rewritable basis in a first operation mode, and writes data to the nonvolatile memory cell destructively on a non-rewritable basis in a second operation mode. The nonvolatile memory cell has a variable magnetoresistive element as a memory device, and stores data in a nonvolatile manner corresponding to a value of resistance of the variable magnetoresistive element.

Writing to a memory array is enabled in the first operation mode and in the second operation mode. Therefore, when there is possibility of a write data correction, data is written in the first operation mode. When rewriting of data becomes unnecessary, the second operation mode is set and data is written. Accordingly, in a normal operation, data is written in a memory cell having a variable magnetoresistive element as a memory cell of a normal memory cell array, however, in the second operation mode, data is written to the memory cell destructively on a non-rewritable basis; therefore, the data in the memory cell can be held stably over a long period of time.

### BRIEF DESCRIPTION OF THE DRAWINGS

The present invention will become fully understood from the detailed description given hereinafter and the accompanying drawings, wherein:

FIG. 1 is a drawing illustrating roughly the entire configuration of a memory unit of a semiconductor device according to Embodiment 1 of the present invention;

FIG. 2 is a drawing illustrating roughly configuration of a modified example of the memory unit of the semiconductor device according to Embodiment 1 of the present invention;

FIG. 3 is a drawing illustrating an electrical equivalent circuit of a memory cell of the semiconductor device according to the present invention;

FIG. 4 is a drawing illustrating roughly configuration of the principal parts of the semiconductor device according to Embodiment 1 of the present invention;

FIG. 5 is a drawing illustrating roughly configuration of a PROM/OTP-merged circuit illustrated in FIG. 4;

FIG. 6 is a drawing illustrating more specific configuration of the PROM/OTP-merged circuit illustrated in FIG. 5;

FIG. 7 is a drawing illustrating roughly a data read/write path of the PROM/OTP-merged circuit according to Embodiment 1 of the present invention;

FIG. 8 is a drawing illustrating roughly an example of configuration of a mode setting circuit illustrated in FIG. 4;

FIG. 9 is a timing chart illustrating operation of the mode setting circuit illustrated in FIG. 8;

FIG. 10 is a drawing illustrating specifically the data read/write path of the PROM/OTP-merged circuit according to Embodiment 1 of the present invention;

FIG. 11 is a drawing illustrating roughly a current wave form at the time of data reading in a PROM mode of a memory cell illustrated in FIG. 10;

FIG. 12 is a drawing illustrating roughly a current wave form at the time of data reading in an OTP mode of a memory cell illustrated in FIG. 10;

FIG. 13 is a drawing illustrating roughly configuration of a top row driver and a bottom row decoder, illustrated in FIG. 6;

FIG. 14 is a drawing illustrating roughly configuration of a PROM/OTP control circuit according to Embodiment 1 of the present invention;

FIG. 15 is a flow chart illustrating a data read operation in a PROM mode of the semiconductor device according to Embodiment 1 of the present invention;

FIG. 16 is a flow chart illustrating a data write operation in a PROM mode of the semiconductor device according to Embodiment 1 of the present invention;

FIG. 17 is a flow chart illustrating a data write operation in an OTP mode of the semiconductor device according to Embodiment 1 of the present invention;

FIG. 18 is a flow chart illustrating a data write operation in a PROM/OTP mode of the semiconductor device according to Embodiment 1 of the present invention;

FIG. 19 (A) is a drawing illustrating roughly correspondence of stored data of a memory cell and read data at the time of data writing and data reading in a OTP mode of the semiconductor device according to Embodiment 1 of the present invention;

FIG. 19 (B) is a drawing illustrating roughly correspondence of stored data of a memory cell and read data at the time of data writing and data reading in a PROM mode of the semiconductor device according to Embodiment 1 of the present invention;

FIG. 20 is a drawing illustrating configuration of a PROM/OTP-mode write control unit illustrated in FIG. 14;

FIG. 21 is a drawing illustrating roughly configuration of a write controller of a column decoder plus write control circuit illustrated in FIG. 20;

FIG. 22 is a drawing illustrating roughly configuration of a local PROM/OTP write-in column control circuit of the semiconductor device according to Embodiment 1 of the present invention;

FIG. 23 is a drawing illustrating roughly arrangement of the semiconductor device according to Embodiment 1 of the present invention;

FIG. 24 is a drawing illustrating roughly configuration of a part relevant to a PROM-mode writing of the local write control circuit of the semiconductor device according to Embodiment 1 of the present invention;

FIG. 25 is a drawing illustrating roughly configuration of a writing driver of the semiconductor device according to Embodiment 1 of the present invention;

FIG. 26 is a drawing illustrating roughly configuration of an address generation unit of the semiconductor device according to Embodiment 1 of the present invention;

FIG. 27 is a timing chart illustrating operation of the address generation unit illustrated in FIG. 26;

FIG. 28 is a drawing illustrating roughly an example of configuration of a majority circuit illustrated in FIG. 6;

FIG. 29 is a table listing truth-values of the majority circuit illustrated in FIG. 28;

FIG. 30 is a drawing illustrating roughly configuration of the principal parts of the semiconductor device according to Embodiment 2 of the present invention;

FIG. 31 is a drawing illustrating roughly a plane layout of an impurity range of an MRAM cell and a gate word line according to Embodiment 2 of the present invention;

FIG. 32 is a drawing illustrating roughly a layout of a first metal wiring in the upper layer of the plane layout illustrated in FIG. 31;

FIG. 33 is a drawing illustrating roughly a plane layout of a second metal wiring in the upper layer of the plane layout illustrated in FIG. 32;

FIG. 34 is a drawing illustrating roughly a plane layout of a third metal wiring in the upper layer of the plane layout illustrated in FIG. 33;

FIG. 35 is a drawing illustrating roughly a plane layout of a fourth metal wiring in the upper layer of the plane layout illustrated in FIG. 34;

FIG. 36 is a drawing illustrating roughly a layout of a variable magnetoresistive element in the upper layer of the plane layout illustrated in FIG. 35;

FIG. 37 is a drawing illustrating roughly a layout of a fifth metal wiring in the upper layer of the plane layout illustrated in FIG. 36;

FIG. 38 is a drawing illustrating roughly a cross-section structure along a line L38-L38 illustrated in FIG. 37;

FIG. 39 is a drawing illustrating roughly a modified example of a plane layout of an MRAM cell according to Embodiment 2 of the present invention;

FIG. 40 is a drawing illustrating roughly a cross-section structure along a line L40-L40 illustrated in FIG. 39;

FIG. 41 is a drawing illustrating roughly a layout of an active area of a PROM/OTP cell and a gate word line according to Embodiment 2 of the present invention;

FIG. 42 is a drawing illustrating roughly a cross-section structure along a line L42-L42 illustrated in FIG. 41;

FIG. 43 is a drawing illustrating roughly a cross-section structure along a line L43-L43 illustrated in FIG. 41;

FIG. 44 is a drawing illustrating roughly a cross-section structure along a line L44-L44 illustrated in FIG. 41;

FIG. 45 is a drawing illustrating roughly a layout of a first metal wiring and a second metal wiring in the upper layer of the plane layout illustrated in FIG. 41;

FIG. 46 is a drawing illustrating roughly a cross-section structure along a line L46-L46 illustrated in FIG. 45;

FIG. 47 is a drawing illustrating roughly a cross-section structure along a line L47-L47 illustrated in FIG. 45;

FIG. 48 is a drawing illustrating roughly a cross-section structure along a line L48-L48 illustrated in FIG. 45;

FIG. 49 is a drawing illustrating roughly a layout of a third metal wiring and a fourth metal wiring in the upper layer of the plane layout illustrated in FIG. 45;

FIG. 50 is a drawing illustrating roughly a cross-section structure along a line L50-L50 illustrated in FIG. 49;

FIG. 51 is a drawing illustrating roughly a cross-section structure along a line L51-L51 illustrated in FIG. 49;

FIG. 52 is a drawing illustrating roughly a cross-section structure along a line L52-L52 illustrated in FIG. 49;

FIG. 53 is a drawing illustrating roughly a cross-section structure along a line L53-L53 illustrated in FIG. 49;

FIG. 54 is a drawing illustrating roughly a layout of a fifth metal wiring and a local wiring in the upper layer of the plane layout illustrated in FIG. 49;

FIG. 55 is a drawing illustrating roughly a cross-section structure along a line L55-L55 illustrated in FIG. 54;

FIG. 56 is a drawing illustrating roughly a cross-section structure along a line L56-L56 illustrated in FIG. 54;

FIG. 57 is a drawing illustrating roughly arrangement of a memory cell of a PROM/OTP array according to Embodiment 2 of the present invention;

FIG. 58 is a flow chart illustrating operation of a semiconductor device according to Embodiment 3 of the present invention;

FIG. 59 is a flow chart illustrating detailed operation of a perfect non-volatilization step of stored data in the flow chart illustrated in FIG. 58;

FIG. 60 is a drawing illustrating roughly entire configuration of the semiconductor device according to Embodiment 3 of the present invention;

FIG. 61 is a drawing illustrating roughly an example of configuration of a mode setting circuit illustrated in FIG. 60;

FIG. 62 is a drawing illustrating roughly an example of configuration of an input selection circuit and a fuse register illustrated in FIG. 62;

FIG. 63 is a timing chart illustrating operation of the mode setting circuit, a fuse register, and an input selection circuit illustrated in FIG. 61;

FIG. 64 is a drawing illustrating roughly configuration of the mode setting circuit of the modified example of Embodiment 3 of the present invention; and

FIG. 65 is a timing chart illustrating operation of the mode setting circuit illustrated in FIG. 64.

### DETAILED DESCRIPTION OF THE INVENTION

Hereinafter, with reference to the accompanying drawings, the embodiments of the present invention are explained in detail.

### Embodiment 1

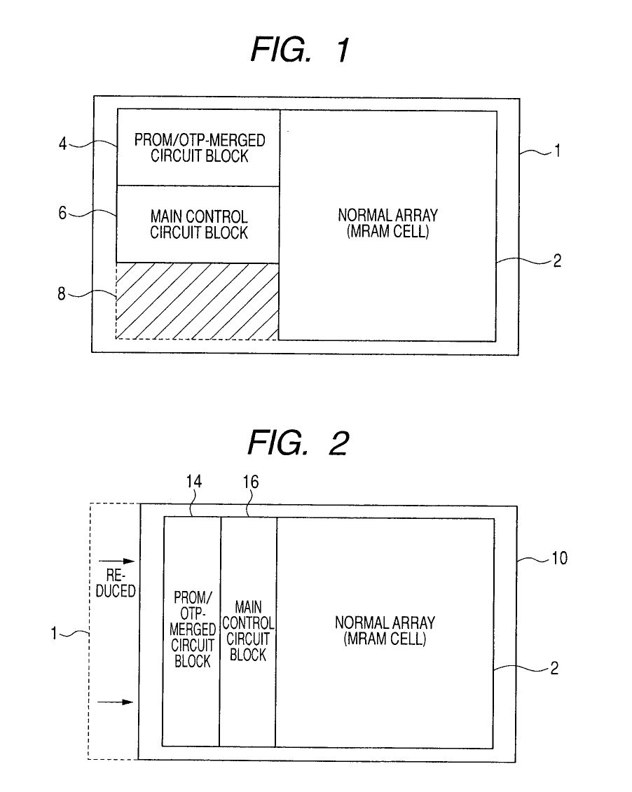

FIG. 1 illustrates roughly a chip layout of a nonvolatile memory unit of a semiconductor device according to the present invention. In FIG. 1, the nonvolatile memory unit of the semiconductor device is an MRAM including an MRAM cell which utilizes a variable magnetoresistive element as a data storage element.

In FIG. 1, a normal array 2 is arranged over a semiconductor chip region 1 in the shape of a rectangle. In the normal array 2, MRAM cells are arranged in a matrix and hold data which is accessible from the exterior. The present semiconductor chip region 1 may be a chip as a single body, or may be a macro area which is a part of area over a semiconductor chip and forms a part of a system LSI.

Adjoining to the normal array 2, a PROM/OTP-merged circuit block 4 and a main control circuit block 6 are arranged in a rectangle area, respectively. The PROM/OTP-merged circuit block 4 includes a common MRAM cell array and operates as either PROM or OTPROM (hereafter simply called as OTP) corresponding to a operation mode. The PROM/OTP-merged circuit block 4 stores data for setting up an internal operation state (called as internal operation environment setup data), including trimming data for adjusting a reference voltage level and an operation timing in the main control circuit block 6, and repair data for replacing a bad cell in the memory array 2 by a redundant cell, etc.

In the PROM/OTP-merged circuit block 4, data writing is performed in a PROM mode, since it becomes necessary to rewrite later due to change of the internal operation environment setup data for every chip at the time of a wafer-level test. On the other hand, after a final test before shipment, data writing is performed in an OTP mode, since the test is done for a chip as a single body (in a packaged state) and a nondefective article is shipped.

The main control circuit block 6 performs data access to the normal array 2 and control of an operation mode to the PROM/OTP-merged circuit block 4.

As illustrated in FIG. 1, by arranging the PROM/OTP-merged circuit block 4 in the semiconductor chip region 1, a space area 8 can be secured in the lower part of the main control circuit block 6. Therefore, a chip layout area of the MRAM can be reduced, and the other peripheral circuits can be arranged in the space area 8 to extend the function of the MRAM.

FIG. 2 illustrates roughly a modified example of the chip layout of the MRAM according to the present invention. In the MRAM illustrated in FIG. 2, a normal array (MRAM cell array) 2 is arranged in the shape of a rectangle over a semiconductor chip region 10 in the shape of a rectangle, similarly to the configuration illustrated in FIG. 1. Along with the direction of a long side of the chip area 10, and adjoining to the normal array 2 in series, a PROM/OTP-merged circuit block 14 and a main control circuit block 16 are arranged.

In the chip layout illustrated in FIG. 2, the PROM/OTP-merged circuit block 4 and the main control circuit block 6, illustrated in FIG. 1, are arranged along with the direction of the long side of the chip area, accordingly, a chip occupied area can be reduced as much as the space area 8 illustrated in FIG. 1, and the area of the semiconductor chip region 10 can be reduced, compared with the semiconductor chip region 1.

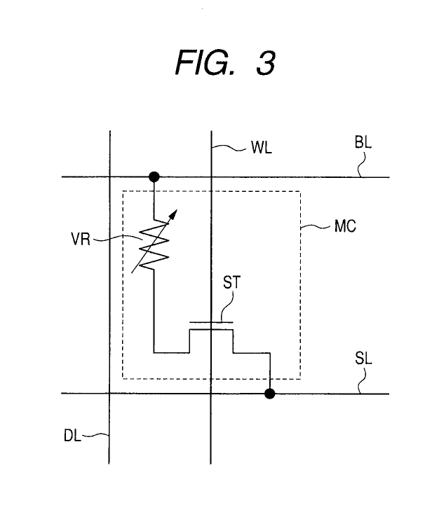

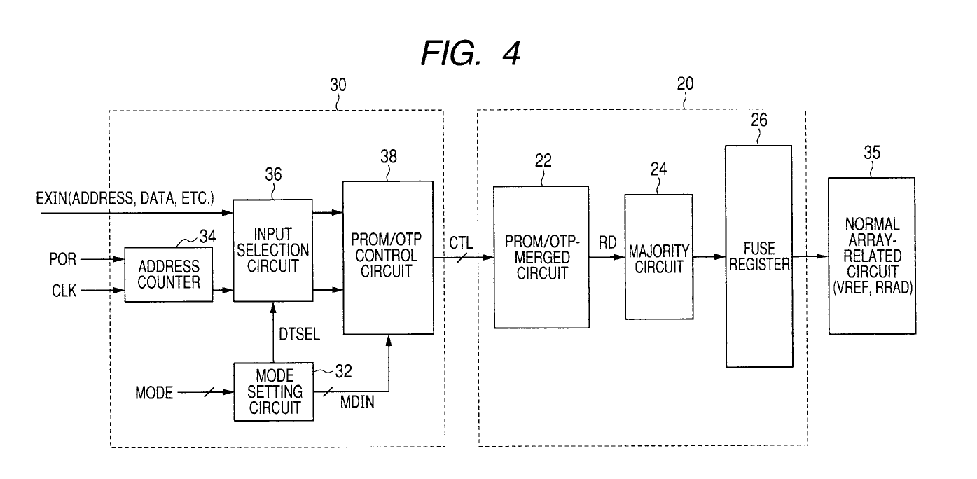

FIG. 3 illustrates an electrical equivalent circuit of an MRAM cell MC utilized in the MRAM as a nonvolatile memory unit of the semiconductor device according to the present invention. In FIG. 3, the MRAM cell MC includes a variable magnetoresistive element VR which stores data with a value change of resistance, and a select transistor ST which forms a current path to the variable magnetoresistive element VR in data reading. The variable magnetoresistive element VR may be any of an MTJ element and a TMR element.

Although FIG. 3 illustrates configuration in which a current-induced magnetic field sets up a resistor state of the variable magnetoresistive element VR, the MRAM cell may be an MTJ element in which spin injection torque sets up the magnetization direction of the free layer. Therefore, a term of a “variable magnetoresistive element” is used as a memory device here so that elements of various configuration may be included. The variable magnetoresistive element VR includes a free layer, a fixed layer, and a barrier layer therebetween, and the value of resistance is set up by the parallel/anti-parallel magnetization directions of the free layer and the fixed layer. The cross-section structure is known widely in general, therefore, description of the cross-section structure is omitted here.

One electrode (upper electrode) of the variable magnetoresistive element VR is coupled to a bit line BL, and a select transistor ST is provided between the other electrode (lower electrode) of the variable magnetoresistive element VR and a source line SL. A gate (control electrode) of the select transistor ST is electrically coupled to a word line WL. A digit line DL is arranged in opposition to the variable magnetoresistive element VR and in parallel with the word line WL.

At the time of data writing, the magnetization direction of the free layer of the variable magnetoresistive element VR is set up by a combined magnetic field of magnetic fields induced by the current flowing through the digit line DL and the current flowing through the bit line BL. At the time of the data writing, the word line WL is in a not-selected state, and a current path from the bit line BL to the source line SL is cut off. Ordinarily, at the time of data writing, current flows through the digit line DL in a fixed direction, and current flows through the bit line BL in a direction corresponding to write data.

At the time of data reading, the digit line DL is maintained in a not-selected state, and the word line WL is driven to a selected state. At this time, the amount of current which flows from the bit line BL to the source line SL changes corresponding to the value of resistance of the variable magnetoresistive element VR. Data is read by detecting the amount of current which flows through the bit line BL (or the amount of current which flows through the source line SL) by a sense amplifier (not shown).

When the MRAM cell MC illustrated in FIG. 3 is a spin injection cell, the direction of current which flows between the bit line BL and the source line SL is set up corresponding to write data. At this time, in order to generate the write assist magnetic field, current is flowed through the digit line DL in a constant direction.

FIG. 4 illustrates the more detailed configuration of the PROM/OTP-merged circuit blocks 4, 14 and the main control circuit blocks 6, 16, illustrated in FIGS. 1 and 2. FIG. 4 illustrates configuration of a controller relevant to the PROM/OTP-merged circuit included in the main control circuit blocks 6, 16, but does not illustrate a control circuit which performs an access control to the normal array 2.

In FIG. 4, the PROM/OTP-merged circuit block 20 (4 or 14) includes a PROM/OTP-merged circuit 22 which includes a common MRAM cell array and operates in a PROM mode and an OTP mode, a majority circuit 24 which performs majority decision of read data RD from the PROM/OTP-merged circuit 22 and generates final read-out data, and a fuse register 26 which stores the output data of the majority circuit 24.

In the PROM mode, the PROM/OTP-merged circuit 22 writes data into the internal MRAM cell on a rewritable basis. In the OTP mode, the PROM/OTP-merged circuit 22 writes data into the MRAM cell on a non-rewritable basis, namely, writes data so that a variable magnetoresistive element of the MRAM may produce dielectric breakdown. Reading operation is performed on the same basis in any of the PROM mode and the OTP mode.

The PROM/OTP-merged circuit 22 writes the same data bit into plural memory cells, and the majority circuit 24 determines, based on a majority decision criterion, the logical value of data stored in the plural memory cells (three memory cells in the present embodiment as explained later) in which the same data bit has been written, and generates the final read-out data. By performing the majority decision, influence of bit error in read due to malfunction can be made minimum, accordingly, it is possible to read out accurately the data set up and to set up the internal environment.

The fuse register 26 stores data for setting up an operating state of the normal array-related circuit 35, and stores data for performing trimming of an internal reference voltage and an internal operation timing, and a repair address (RRAD) of a bad cell in the normal array. According to the data stored in the fuse register 26, an on/off state is set up for a switching transistor which is arranged in place of a fuse element. The present switching transistor is arranged in parallel with a resistance element in the case of trimming setup, and is used in place of a fuse for a bad address bit setup in the case of bad address repair.

The PROM/OTP-related controller 30 is included in the main control circuit block 6 or 16 illustrated in FIG. 1 or 2 and has an address counter 34, a mode setting circuit 32, an input selection circuit 36, and a PROM/OTP control circuit 38. The address counter 34 generates an internal address signal, according to a power-on detection signal POR and a clock signal CLK from the exterior. The mode setting circuit 32 generates an input data selection signal DTSEL and an internal mode instruction signal MDIN, according to a mode instruction signal MODE from the exterior. The input selection circuit 36 selects one of an internal address from the address counter 34 and an input data-signal EXIN from the exterior, according to the input data selection signal DTSEL from the mode setting circuit 32. The PROM/OTP control circuit 38 generates a control signal CTL for performing an operation mode specified by the internal mode instruction signal MDIN supplied by the mode setting circuit 32.

The mode setting circuit 32 generates the input data selection signal DTSEL and the internal mode instruction signal MDIN, according to the mode instruction signal MODE which specifies one of an OTP mode, a PROM mode, a data write mode, and a data read mode. When the power-on detection signal POR is activated, or at the time of power-on of the MRAM, the address counter 34 generates an internal address and an address for reading data stored in the PROM/OTP-merged circuit 22. The input selection circuit 36 selects externally-supplied address and data at the time of data writing, and selects an internal address from the address counter 34 according to the data selection signal DTSEL, for example, when an OTP mode is set up and the PROM/OTP-merged circuit 22 is utilized as a fixed data storing memory.

According to the internal operation mode instruction signal MDIN, the PROM/OTP control circuit 38 controls the PROM/OTP-merged circuit 22 to operate in one of an PROM mode, an OTP mode, and a data read mode.

The present PROM/OTP control circuit 38 is provided so as to control both the PROM mode and the OTP mode to the PROM/OTP-merged circuit 22, accordingly, the control circuit can be merged corresponding to a PROM-mode circuit and an OTP mode circuit which are included in the PROM/OTP-merged circuit 22. Consequently, it is possible to reduce a layout area of the PROM/OTP-related controller 30 included in the present main control circuit block.

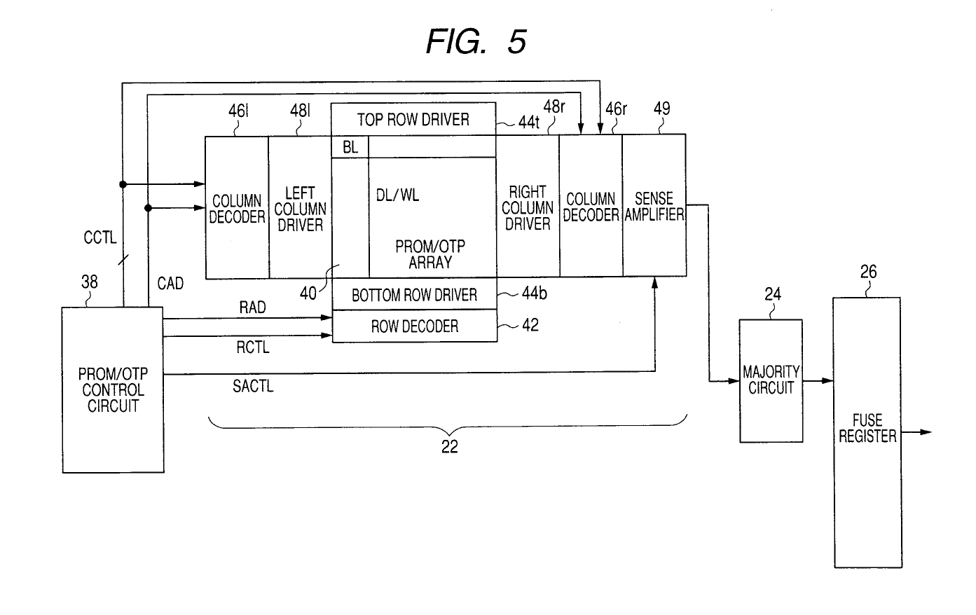

FIG. 5 illustrates more detailed configuration of the PROM/OTP-merged circuit 22 illustrated in FIG. 4. In FIG. 5, the PROM/OTP control circuit 38, the majority circuit 24, and the fuse register 26 are also illustrated, in order to clarify a transmission path of a signal and data.

In FIG. 5, the PROM/OTP-merged circuit 22 includes a PROM/OTP array 40 in which MRAM cells are arranged in a matrix. In the PROM/OTP array 40, MRAM cells are arranged in a matrix, a bit line BL is arranged corresponding to each memory cell column, and a digit line DL and a word line WL are arranged corresponding to each MRAM cell row.

The PROM/OTP-merged circuit 22 includes a row decoder 42, a top row driver 44t, and a bottom row driver 44b, in order to select a memory cell row of the PROM/OTP array 40. The row decoder 42 generates a signal which selects a memory cell row of the PROM/OTP array 40, according to a row group control signal RCTL and a row address signal RAD which are supplied by the PROM/OTP control circuit 38. That is, the row decoder 42 generates a signal for selecting a digit line DL at the time of data writing, and generates a signal for selecting a word line WL at the time of data reading.

The top row driver 44t and the bottom row driver 44b are arranged face to face with respect to the projection direction of the digit line DL and the word line WL of the PROM/OTP array 40. The top row driver 44t and the bottom row driver 44b include respectively a driver transistor arranged corresponding to the digit line DL and the word line WL, and drive the digit line DL or the word line WL corresponding to a specified row to a selected state, according to a row selection signal supplied by the row decoder 42.

The PROM/OTP-merged circuit 22 includes further column decoders 46r and 46l, column drivers 48r and 48l, and a sense amplifier 49, as circuits for performing selection of a memory cell column of the PROM/OTP array 40 and read/write of data. The column decoders 46r and 46l are arranged face to face on both sides of the bit line BL of the PROM/OTP array 40, and generate a column selection signal according to a column address signal CAD and a column group control signal CCTL which are supplied by the PROM/OTP control circuit 38.

The right column driver 48r and the left column drivers 48l include bit-line writing drivers for data writing, arranged at both ends of each bit line. The right column driver 48r and the left column driver 48l include a bit-line writing driver for data writing in a PROM mode, and a bit-line writing driver for data writing in an OTP mode.

In the column drivers 48r and 48l, by providing a driver for writing in the PROM mode and a driver for writing in the OTP mode to each bit line, writing in the PROM mode and writing in the OTP mode are selectively executed.

To the right column driver 48r, a read column selecting gate is provided further for selecting a bit line of a read-out column at the time of data reading. At the time of data reading, a sense amplifier 49 is activated selectively according to a sense control signal SACTL supplied by the PROM/OTP control circuit 38, detects data of a memory cell selected by the read column selecting gate, and generates an internal read data. The internal read data read by the sense amplifier 49 is supplied to the majority circuit 24.

The PROM/OTP control circuit 38, the majority circuit 24, and the fuse register 26 have the same configuration as illustrated in FIG. 4; therefore, the same reference number is attached to the corresponding part and the detailed explanation thereof is omitted.

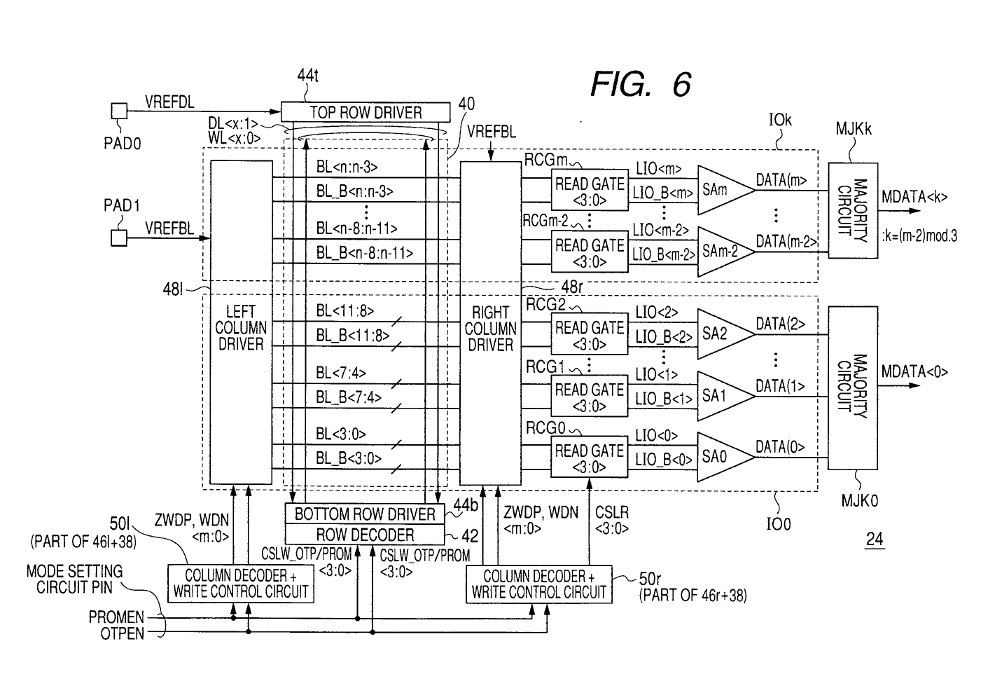

FIG. 6 illustrates more detailed configuration of the PROM/OTP-merged circuit 22 illustrated in FIG. 5. In the PROM/OTP array 40 illustrated in FIG. 6, a bit line BL<n:0> and BL_B<n:0> are arranged, and a digit line DL<x:0> and a word line WL<x:0> are arranged.

The digit line DL is driven by the top row driver 44t and the bottom row driver 44b. The word line WL is driven by the bottom row driver 44b. A reference voltage VREFDL is supplied to the top row driver 44t from an external circuit tester for example, via a pad PAD0, and the amount of current which flows through the digit line is adjusted. The bottom row driver 44b selects a digit line corresponding to a selection row, according to a row address signal. Therefore, at the time of selecting a digit line DL, current flows from the top row driver 44t toward the bottom row driver 44b.

The bit lines BL<n: 0> and BL_B<n:0> are arranged in pairs, and four-to-one selection is made in which one bit-line pair is selected in four pairs of bit lines. In the bit lines BL<n:0> and BL_B<n:0>, division is made so that 12 pairs of bit lines may correspond to one read/write data bit. In the arrangement illustrated in FIG. 6, the bit lines BL<11:0> and BL_B<11:0> are included in an IO block IO0, and the bit lines BL<n−8:n−11> and BL_B<n−8:n−11> correspond to an IO block IOk. Writing of one piece of data is performed in four pairs of bit lines as a group, and the same data (bit) is written in three memory cells in each of (k+1) IO blocks (actually, complementary data is written).

Similarly, at the time of read, data reading of three bits is performed in parallel in one IO block. Here, an IO block corresponds to one bit of external data (it corresponds to one input/output pin).

Column decoder+write control circuits 50r and 50l are provided, respectively corresponding to the right column driver 48r and the left column driver 48l. The column decoders in the circuits 50r and 50l correspond to the column decoders 46r and 46l illustrated in FIG. 5, respectively. The write control circuit corresponds to the write controller included in the PROM/OTP control circuit 38 illustrated in FIG. 5.

The column decoder+write control circuits 50r and 50l receive a PROM-mode indication signal PROMEN and an OTP-mode indication signal OTPEN from the mode setting circuit 32 illustrated in FIG. 4, as an internal operation mode instruction signal MDIN, respectively, and generate a write column selection signal CSLW_OTP/PROM <3:0> and write data ZWDP<m:0> and WDN<m:0>. The write data ZWDP<m: 0> and WDN<m: 0> are write data of (m+1) bits corresponding to the write data from the exterior. A group of write data ZWDP<i> and WDN<i> are supplied to one column driver, and electric charge or electric discharge of a corresponding bit line is set up.

According to the write column selection signal CSLW_OTP/PROM <3:0>, the writing driver corresponding to an OTP mode and a PROM mode is selected in the column drivers 48r and 48l. Therefore, in four pairs of bit lines BL<i+3:i> and BL_B<i+3:i>, one pair of bit lines are selected at the time of data writing, and complementary write data is stored to the selected complementary bit-line pair.

The column decoder+write control circuit 50r further generates a read column selection signal CSR <3:0> in a data read mode. The read column selection signal CSR<3:0> specifies one pair of bit lines from four pairs of bit lines BL<i+3:i> and BL_B<i+3:i>.

Read gates RCG0-RCGm are provided corresponding to each of four pairs of bit lines. According to the read column selection signal CSR <3:0>, the read gates RCG0-RCGm select one pair of bit lines among the corresponding four pairs of bit lines. Therefore, the read gate <3:0> includes four read column selecting gates.

Read data from the read gates RCG0-RCGm is transferred to local I/O lines LIO<0> and LIOB<0> through LIO<m> and LIO_B<m>, respectively.

Sense amplifier circuits SA0-SAm included in the sense amplifier 49 are provided, respectively corresponding to the read gates RCG0-RCGm. As for the sense amplifier circuits SA0-SAm, three sense amplifier circuits are arranged in each of the IO blocks IO0-IOk. In each IO block, three-bit data read from the corresponding read gates RCG(i+3)-RCGi is amplified to generate internal read data DATA. In FIG. 6, the sense amplifier circuits SA0-SAm generate internal read data DATA<0>-DATA<m>.

Majority circuits MJK0-MJKk are provided corresponding to each group of three sense amplifier circuits included in one IO block. By the respective majority decision process, i.e., based on a two-thirds majority decision criterion, the majority circuits MJK0 -MJKk determine a logical value of the internal read data, and generate final read-out data MDATA<0>-MDATA<k>. Here, k is equal to the result of an operation of (m−2) mod 3, and it corresponds to a remainder when (m−2) is divided by 3.

As illustrated in FIG. 6, in the PROM/OTP array 40, the 4:1 selection is made to the bit lines, the selected result is divided into groups of three bits, and the majority decision is performed to the three-bit data to generate the final read-out data. Writing of complementary data is performed at the time of data writing. Accordingly, write and read of data can be performed accurately, and read of the internal storage data can be ensured.

At the time of data writing, in each of the IO blocks, one pair of bit lines are selected from four pairs of bit lines, and the same data is written to the bit-line pairs, according to the write column selection signal CSLW_OTP/PROM <3:0>.

A reference voltage VREFBL at the time of writing is supplied from the exterior via a pad PAD1 to the left column driver 48l and the right column driver 48r. The bit-line reference voltage VREFBL is supplied from an external circuit tester via the pad PAD1 at the time of data writing in the OTP mode. The bit-line writing voltage having an accurately trimmed level is supplied, and data writing is executed nondestructively.

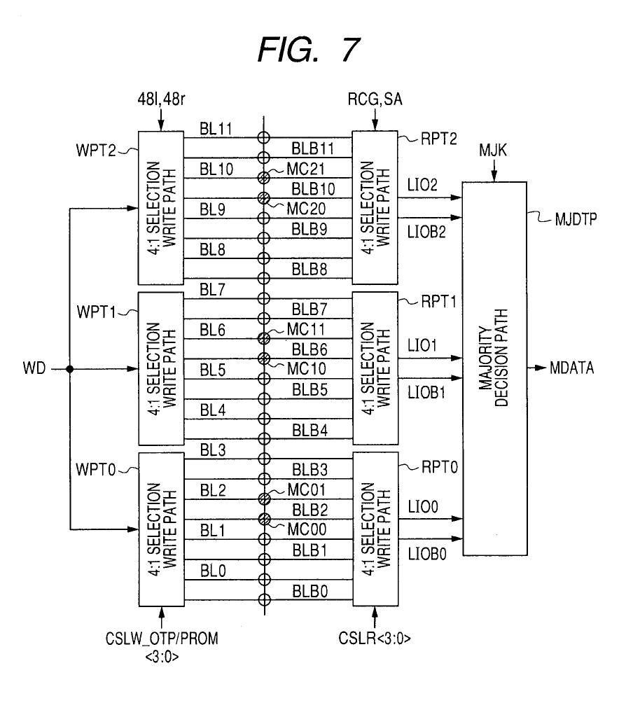

FIG. 7 illustrates schematically a data access basis for one IO block in the PROM/OTP-merged circuit illustrated in FIG. 6. In FIG. 7, bit lines BL0-BL11 and bit lines BLB0-BLB11 are provided. A bit line BLi and a bit line BLBi are arranged as a pair. In a data read path, 4:1 selection read paths RPT2-RPT0 are correspondingly arranged to groups of four pairs of bit lines. The 4:1 selection read paths RPT2-RPT0 correspond to the read gate RCG<j:j−2> and the sense amplifiers SAj-SA (j−2) which are illustrated in FIG. 6. The 4:1 selection read paths RPT2-RPT0 select one pair of bit lines from the corresponding four pairs of bit lines, according to the read column selection signal CSR <3:0>. In FIG. 7, the 4:1 selection read paths RPT2-RPT0 select a pair of bit lines BL10, BLB10, a pair of bit lines BL6, BLB6, and a pair of bit lines BL2, BLB2, respectively.

Therefore, from the 4:1 selection read paths RPT2-RPT0 to the local read-out data lines LIO2 and LIOB2 through LIO0 and LIOB0, complementary data of MRAM cells MC21, MC20, complementary data of MRAM cells MC11, MC10, and complementary data of MRAM cells MC01, MC00 are transferred, respectively. A decision of a logical value of the read data is made in accordance with a majority decision criterion by a majority decision path MJDTP formed by majority circuits MJKj-MJKj−2, and one-bit internal read data MDATA is generated.

On the other hand, also in a write path, 4:1 selection write paths WPT2-WPT0 are provided to groups of four pairs of bit lines. The 4:1 selection write paths WPT2-WPT0 correspond to the column drivers 48l and 48r, illustrated in FIG. 6. The 4:1 selection write paths WPT2-WPT0 select one pair of bit lines from a group of corresponding four pairs of bit lines, according to the write column selection signal CSLW_OTP/PROM <3:0>. The 4:1 selection write paths WPT2-WPT0 generate complementary data from the internal write data WD, and write the complementary data to a group of selected MRAM cells MC21, MC20, a group of MRAM cells MC11, MC10, and a group of MRAM cells MC01, MC00, respectively. Therefore, in one IO block, six MRAM cells (MC21, MC20, MC11, MC10, MC01, MC00) are selected. The same complementary data is written into each pair of memory cells arranged to each pair of bit lines, Data reading from the six MRAM cells in which the same data has been written and majority decision are performed.

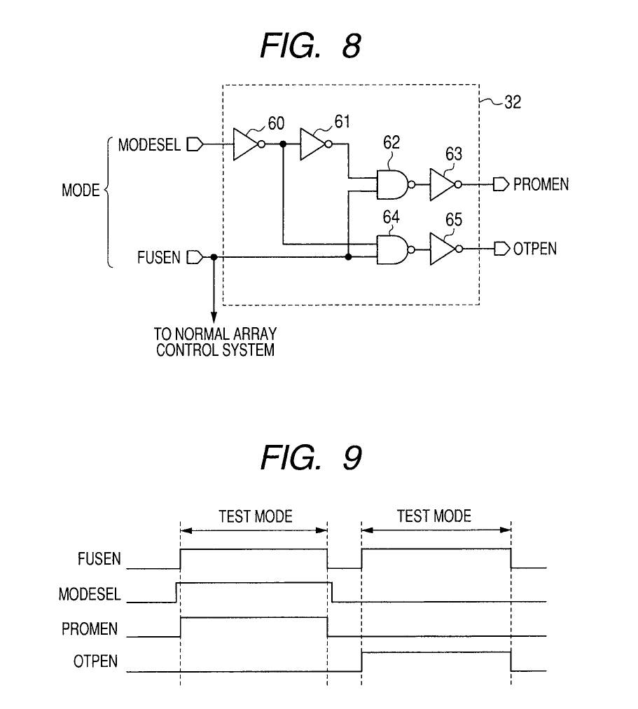

FIG. 8 illustrates an example of configuration of the mode setting circuit 32 illustrated in FIG. 4. The mode setting circuit 32 illustrated in FIG. 8 includes two-stage cascade-coupled inverters 60, 61 which receive a mode selection signal MODESEL, a NAND gate 62 which receives a fuse activation signal FUSEN and an output signal of the inverter 61, an inverter 63 which inverts an output signal of the NAND gate 62 and generates a PROM-mode enable signal PROMEN, a NAND gate 64 which receives an output signal of the inverter 60 and the fuse activation signal FUSEN, and an inverter 65 which receives an output signal of the NAND gate 64 and generates an OTP-mode enable signal OTPEN.

The fuse activation signal FUSEN is activated (set to H level) when performing a data access to the PROM/OTP-merged circuit, namely, the fuse activation signal FUSEN is activated at the time of the test mode. While the fuse activation signal FUSEN is activated, a normal array control system which controls a normal array is maintained in a non-active state, and a data access to the normal array is prohibited.

FIG. 9 is a timing chart illustrating operation of the mode setting circuit 32 illustrated in FIG. 8. Hereafter, with reference to FIG. 9, the operation of the mode setting circuit 32 illustrated in FIG. 8 is explained.

When the fuse activation signal FUSEN is L level, the output signal of the NAND gates 62 and 64 is H level, and the mode enable signal PROMEN from the inverter 63 and the mode enable signal OTPEN from the inverter 65 are both maintained in a non-active state of L level. In this state, both the PROM mode and the OTP mode are set in a not-selected state, and access to the PROM/OTP memory array 40 is prohibited.

When entered into the test mode, the fuse activation signal FUSEN is set to H level. It is assumed here that the mode selection signal MODESEL is set to H level. Correspondingly, the NAND gates 62 and 64 operate as an inverter, the PROM-mode enable signal PROMEN from the inverter 63 becomes H level, and the PROM mode is specified. At this time, the OTP-mode enable signal OTPEN from the inverter 65 is L level. In the present state, read/write of data in the PROM mode are executed.

On the other hand, when the mode selection signal MODESEL is maintained at L level in the present test mode, the output signal of inverter 60 becomes H level and the output signal of inverter 61 becomes L level. Then, the PROM-mode enable signal PROMEN becomes L level, and the OTP-mode enable signal OTPEN becomes H level, and the OTP mode is specified. In the present state, data writing in the OTP mode is executed. Data reading is executed on the same basis in any of the PROM mode and the OTP mode (read/write of data are specified according to a control signal from the PROM/OTP control circuit in response to an external signal (EXIN)).

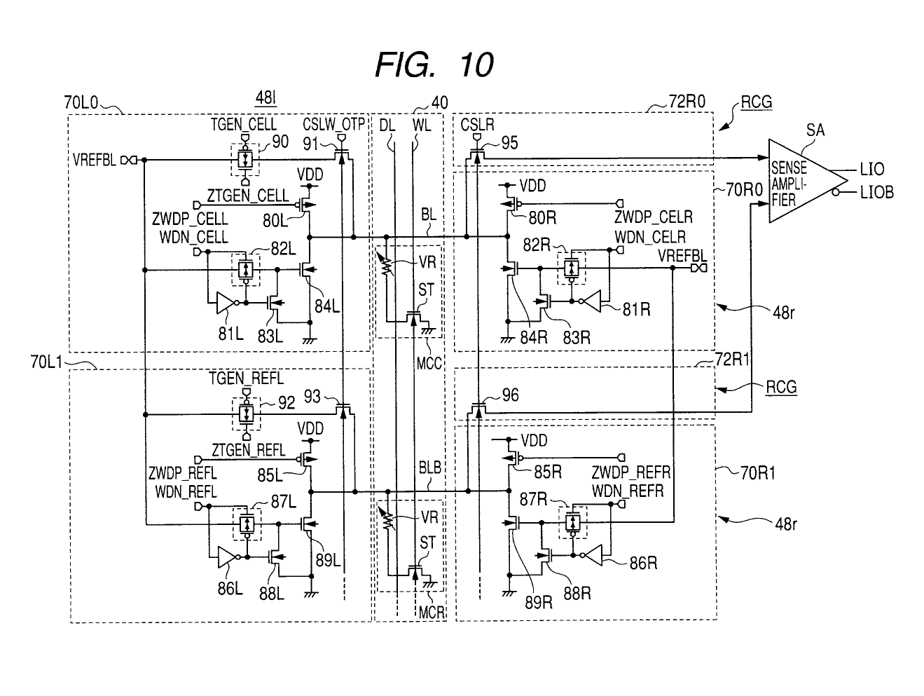

FIG. 10 illustrates roughly configuration of a part relevant to one pair of bit lines BL and BLB of the PROM/OTP array 40. A memory cell MCC is coupled to the bit line BL, and a memory cell MCR is coupled to the bit line BLB. A digit line DL and a word line WL are arranged common to these memory cells MCC and MCR. Data of a logical value corresponding to the write data is written in the memory cell MCC by a value of resistance of the variable magnetoresistive element VR. On the other hand, complementary data of the write data of the memory cell MCC is written in the memory cell MCR. The memory cell MCR is utilized as a reference cell at the time of data reading.

Bit-line write drive circuits 70R0 and 70L0 are arranged at both sides of the bit line BL, and bit-line write drive circuits 70R1 and 70L1 are arranged at both sides of the bit line BLB, respectively. The bit-line write drive circuits 70L0 and 70L1 are included in the left column driver 48l illustrated in FIG. 4, and the bit-line write drive circuits 70R0 and 70R1 are included in the right column driver 48r illustrated in FIG. 6.

The bit-line write drive circuit 70R0 includes a P-channel MOS transistor 80R for charging the bit line, an N-channel MOS transistor 84R for discharging the bit line, an N-channel MOS transistor 83R which maintains the MOS transistor 84R in a non-conductive state, and a CMOS transmission gate 82R which transfers the reference voltage VREFBL to a gate of the MOS transistor 84R.

The P-channel MOS transistor 80R couples a power node with the bit line BL according to a cell write control signal ZWDP_CELR generated according to cell write data. The CMOS transmission gate 82R transfers the bit-line writing voltage VREFBL to the gate of the MOS transistor 84R, according to a cell write control signal WDN_CELR inverted by the inverter 81R and a complementary cell write control signal WDN_CELR. The cell write control signals are generated according to the cell write data as explained minutely later.

The N-channel MOS transistor 84R couples the bit line BL with a ground node according to the bit-line writing voltage VREFBL transferred via the CMOS transmission gate 82R. The N-channel MOS transistor 83R couples the gate of the N-channel MOS transistor 84R with the ground node according to an output signal of the inverter 81R.

The bit-line write drive circuit 70R1 includes a P-channel MOS transistor 85R which couples the bit line BLB with the power node according to a reference cell write control signal ZWDP_REFR, an inverter 86R which inverts the reference cell write control signal WDN_REFR, a CMOS transmission gate 87R which transfers the bit-line writing voltage VREFBL according to the write control signal WDN_REFR and an output signal of the inverter 86R, an N-channel MOS transistor 89R which couples the bit line BLB with the ground node according to the bit-line writing voltage VREFBL transferred via the CMOS transmission gate 87R, and an N-channel MOS transistor 88R which couples the gate of the MOS transistor 89R with the ground node according to an output signal of the inverter 86R.

The bit-line write drive circuits 70R0 and 70R1 compose the PROM write driver which performs writing in a PROM mode, and can adjust accurately an amount of current which flows via the bit lines BL and BLB, by supplying the write reference voltage (bit-line writing voltage) VREFBL from an external circuit tester via a pad. The write control signals ZWDP_CELR, WDN_CELR, ZWDP_REFR, and WDN_REFR are generated according to the write data, the write mode, and the write column selection signal.

The left bit-line write driver circuit 70L0 includes, similarly to the right bit-line write driver circuit 70R0, a P-channel MOS transistor 80L for charging the bit line BL, an N-channel MOS transistor 84L for discharging the bit line BL, a CMOS transmission gate 82L which transfers the bit-line writing voltage VREFBL, an N-channel MOS transistor 83L which adjusts gate potential of the MOS transistor 84L, and an inverter 81L which generates a signal for controlling conduction of the CMOS transmission gate 82L.

A cell write control signal ZWDP_CELL is supplied to a gate of the P-channel MOS transistor 80L, and the CMOS transmission gate 82L is selectively conducted according to a cell write control signal WDN_CELL. At the time of data writing, the cell write control signals ZWDP_CELL and ZWDP_CELR become as a complementary signal with each other, and the cell write control signals WDN_CEL and WDN_CELR become as a complementary signal with each other.

The left bit-line write driver circuit 70L0 further includes a CMOS transmission gate 90 which transfers the bit-line writing voltage VREFBL according to OTP-mode cell write control signals TGEN_CELL and ZTGEN_CELL, and an N-channel MOS transistor 91 which transfers the bit-line writing voltage VREFBL from the CMOS transmission gate 90 to the bit line BL according to the OTP-mode write-in column selection signal CSLW_OTP. An OTP write driver which performs a data writing in the OTP mode is formed by the CMOS transmission gate 90 and the MOS transistor 91.

The left bit-line write driver circuit 70L1 includes, similarly to the right bit-line write driver circuit 70R1, a P-channel MOS transistor 85L for charging the bit line BLB, an N-channel MOS transistor 89L for discharging the bit line BLB, an N-channel MOS transistor 88L which couples a gate of the MOS transistor 89L with the ground potential, an inverter 86L which inverts an OTP mode write control signal WDN_REFL, and a CMOS transmission gate 87L which supplies the bit-line writing voltage VREFBL to a gate of the MOS transistor 89L according to a write control signal WDN_REFL. The MOS transistor 85L is selectively conducted according to a cell write control signal ZWDP_REFL. The write control signals ZWDP_REFL and ZWDP_REFR are a complementary signal with each other at the time of data writing, and the write control signals WDN_REFL and WDN_REFR are a complementary signal with each other at the time of data writing. The write control signals are also generated according to the write data, the write column selection signal, and the write mode.

The left bit-line write driver circuit 70L1 further includes a CMOS transmission gate 92 which transfers the bit-line writing voltage VREFBL according to the OTP mode write control signals TGEN_REF, ZTGEN_REF, and an N-channel MOS transistor 93 which transfers the bit-line writing voltage VREFBL from the CMOS transmission gate 92 to the bit line BLB according to the OTP-mode write-in column selection signal CSLW_OTP. At the time of data writing in the OTP mode, an OTP mode write control signal OTPW_REF and a write control signal OTPW_CELL become as a complementary signal with each other, and the bit-line writing voltage VREFBL is transferred to one of the bit lines BL and BLB.

Read column selecting gates 72R0 and 72R1 are provided to each of the bit lines BL and BLB. The read column selecting gates 72R0 and 72R1 are respectively provided with N-channel MOS transistors 95 and 96 which are selectively conducted according to a read column selection signal CSLR. When the read column selecting gate transistors 95 and 96 are conducted, the bit lines BL and BLB are coupled with a sense amplifier circuit SA. The sense amplifier circuit SA performs a differential amplifier operation, generates internal read data, and transfers complementary internal read data to the local data lines LIO and LIOB.

At the time of data writing to the memory cells MCC and MCRA, data writing in the PROM mode is performed on the same basis as the data writing to the MRAM cell of the normal array. Namely, current is flowed through the bit line BL in the direction corresponding to write data by the bit-line write drive circuits 70R0 and 70L0, and current is flowed through the digit line DL by the row driver; accordingly, a value of resistance of the variable magnetoresistive element VR is set up. At the same time, current is also flowed through the bit line BLB in an opposite direction to the bit line BL, by the bit-line write drive circuits 70R1 and 70L1; accordingly, a value of resistance of the variable magnetoresistive element VR of the memory cell MCR is set up.

Specifically, when current is flowed through the bit line BL from the right-hand side to the left-hand side, both the write control signal ZWDP_CELR and the write control signal WDN_CELR are set to L level. In the present state, the P-channel MOS transistor 80R becomes in ON state, and supplies current to the bit line BL from the power node. On the other hand, the output signal of the inverter 81R becomes H level, the MOS transistor 83R becomes in ON state; accordingly, the gate potential of the MOS transistor 84R is maintained to the ground potential, and the MOS transistor 84R is maintained in OFF state.

In the left bit-line write driver circuit 70L0, both the cell write control signal ZWDP_CELL and the cell write control signal WDN_CELL are set to H level. Correspondingly, the MOS transistor 80L becomes in OFF state, and the bit-line writing voltage VREFBL is supplied to the gate of the MOS transistor 84L by the CMOS transmission gate 82L. At this time, the MOS transistor 83L is in OFF state according to the output signal of the inverter 81L. Therefore, current flows through the bit line BL from the power node to the ground node, via the MOS transistor 80R and the MOS transistor 84L on both sides of the bit line BL. By adjusting the voltage level of the bit-line writing voltage VREFBL from the exterior, the amount of writing current which flows through the bit line BL can be adjusted reliably.

Data writing to the bit line BLB is performed similarly. When current flows through the bit line BL from the right-hand side to the left-hand side, current flows through the bit line BLB from the left-hand side to the right-hand side. In the present case, the write control signal is set in a complementary state with each other to the memory cell MCC and the memory cell MCR.

On the other hand, at the time of data writing in the OTP mode, in the left bit-line write driver circuits 70L0 and 70L1, one of the transmission gate 90 and the transmission gate 92 becomes in ON state, and the bit-line writing voltage VREFBL is transferred to one of the bit line BL and the bit line BLB. At this time, the word line WL is driven to a selected state, and the select transistor ST is set in ON state. By setting the bit-line writing voltage VREFBL to a voltage level about two times as high as the power supply voltage VDD, for example, the high voltage is applied to the variable magnetoresistive element VR of one of the memory cell MCC and the memory cell MCR, and a barrier film of the variable magnetoresistive element is destroyed; accordingly, the variable magnetoresistive element VR becomes in a short-circuited state, i.e., in a super-low resistance state LL level. In the OTP mode, data writing is performed destructively; therefore, it is not possible to perform rewriting of the stored data of the memory cell in which data writing has been performed.

In the OTP mode, as for the memory cells forming a pair, the bit-line writing voltage VREFBL is not transferred to the corresponding bit line. Therefore, since a high voltage is not applied to the variable magnetoresistive element concerned even if the select transistor becomes in ON state, data writing to the memory cell forming a pair is not performed, and the previous state is maintained.

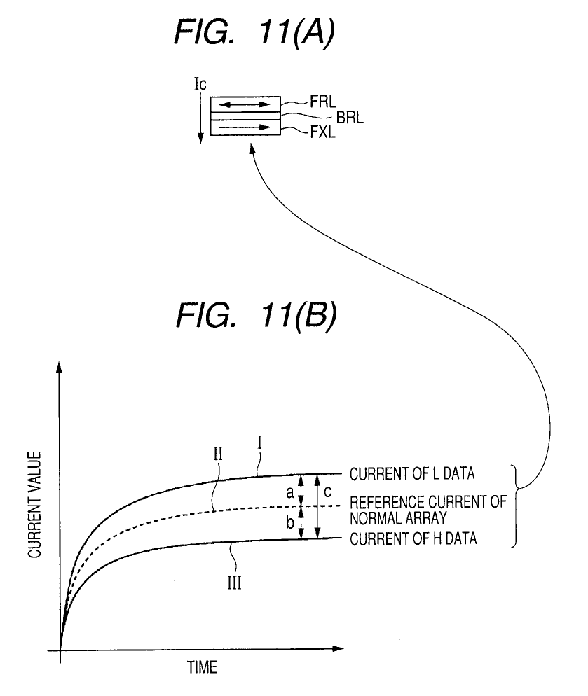

FIG. 11 (A) illustrates an example of a magnetization state at the time of writing in a variable magnetoresistive element in a PROM mode. In FIG. 11 (A), the variable magnetoresistive element has a fixed layer FXL, a free layer FRL, and a barrier layer BRL therebetween. A magnetization direction of the free layer FRL is set up corresponding to stored data, and a magnetization direction of the fixed layer FXL is fixed, for example in the right direction as illustrated in FIG. 11 (A). In data reading, current Ic flows passing through the variable magnetoresistive element.

FIG. 11 (B) illustrates a waveform of a cell read-out current of a normal array. In FIG. 11 (B), the vertical axis is a current value and the horizontal axis is time. Curves I and III indicate read current waveforms when memory cells storing L data and H data respectively are selected, and a curve II indicates a reference current waveform which gives reference data in the middle of the L data and the H data. In the example illustrated in FIG. 11 (B), the L data and the H data are associated with a low resistance state and a high resistance state, respectively.

In data reading from the normal array, the read-out current of the curve I or the curve III is obtained depending on the stored data of a selected memory cell, and the read-out current is compared in magnitude with the reference current illustrated by the curve II, accordingly the data reading is accomplished. Therefore, in the present case, a margin in the sense amplifier of the bit-line read current in a normal array is given by “a” and “b”, respectively.

Complementary data is read from a cell which is written in the PROM mode. Therefore, the curves I and III are transferred to the sense amplifier as the current waveform. In the present case, the read margin in the sense amplifier is “c.” Therefore, in the PROM mode, by reading the complementary data, compared with the configuration in which data of one memory cell in a normal array is read and compared with the reference current, the read margin of the sense amplifier can be enlarged and data reading can be performed more accurately.

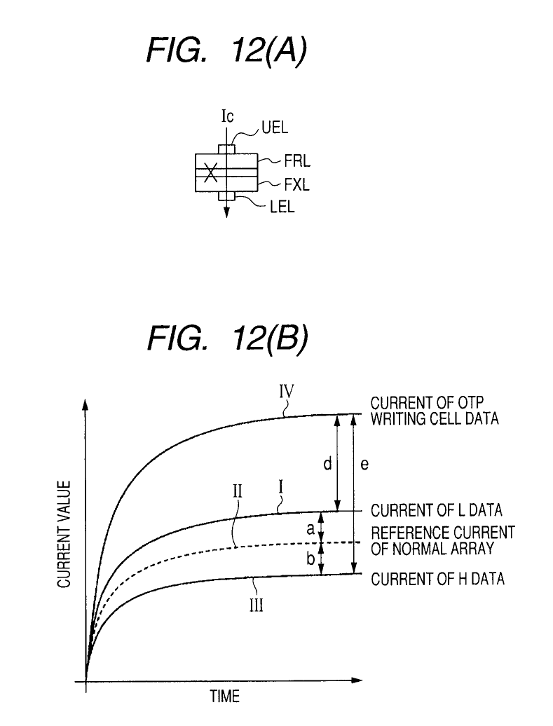

FIG. 12 (A) illustrates roughly configuration of a memory cell which has been written in an OTP mode. In FIG. 12 (A), when written in the OTP mode, the barrier layer is destroyed by a high voltage and the upper electrode UEL and the lower electrode LEL are short-circuited. In the present state, the magnetization directions of the fixed layer FXL and the free layer FXL do not have influence on the read current.

FIG. 12 (B) illustrates a read current waveform of a memory cell which is written in an OTP mode. In FIG. 12 (B), curves I, II, and III correspond to the curves I, II, and III illustrated in FIG. 11 (B). A curve IV indicates current which flows through a cell which is written in the OTP mode. The barrier film of the variable magnetoresistive element is destroyed by the data writing in the OTP mode, and the variable magnetoresistive element becomes in a super-low resistance state, exhibiting a resistance state still lower than the low resistance state when data “0” is stored. Therefore, current supplied to the sense amplifier in the present case is current indicated by the curve I or the curve III, and current indicated by the curve IV. The sense current margin is given by “d” or “e”, which is sufficiently larger than the margin “a” or “b” given by the read current of the MRAM cell in the normal array. Therefore, even when a reference cell is in a non-destructive state and stores L data or H data in the OTP mode, it is possible to read data of the memory cell reliably.

FIG. 13 illustrates roughly an example of configuration of the top row driver 44t and the bottom row driver 44b, illustrated in FIG. 6. In the top row driver 44t, P-channel MOS transistors TRT0-TRTx are provided corresponding to respective digit lines DL0-DLx. A digit-line reference voltage VREFDL is supplied from the exterior to gates of these MOS transistors TRT0-TRTx. A voltage level of the digit-line reference voltage VREFDL is trimmed externally so as to adjust the amount of current which flows through the corresponding digit line from the power node VDD via the MOS transistors TRT0-TRTx.

In the bottom row driver 44b, N-channel MOS transistors TRB0 -TRBx are provided corresponding to respective digit lines DL0-DLx. Digit-line selection signals DLG0-DLGx are supplied to gates of the MOS transistors TRB0-TRBx from the row decoder 42 illustrated in FIG. 6. Therefore, among the digit lines DL0-DLx, current flows through a digit line DLi, which is specified by the digit-line selection signal DLGi, from the power node to the ground node, and generates a write magnetic field.

In the bottom row driver 44b, word-line driver circuits WLDV0 -WLDVx are provided corresponding to respective word lines WL0-WLx. These word-line driver circuits WLDV0-WLDVx drive the corresponding word line to a selected state according to word-line selection signals WLG0-WLGx from the row decoder 42 (not shown), respectively.

The word lines WL0-WLx are driven to a selected state in a read mode and in writing in the OTP mode. On the other hand, the digit lines DL0-DLx are driven to a selected state in data writing in the PROM mode. Therefore, the digit-line selection signals DLG0 -DLGx are generated according to a PROM-mode enable signal PROMEN, a write-mode instruction signal, and a row address signal. The word-line selection signals WLG0-WLGx are generated, according to a group of an OTP-mode enable signal OTPEN and a write instruction signal, or according to a read instruction signal and a row address signal.

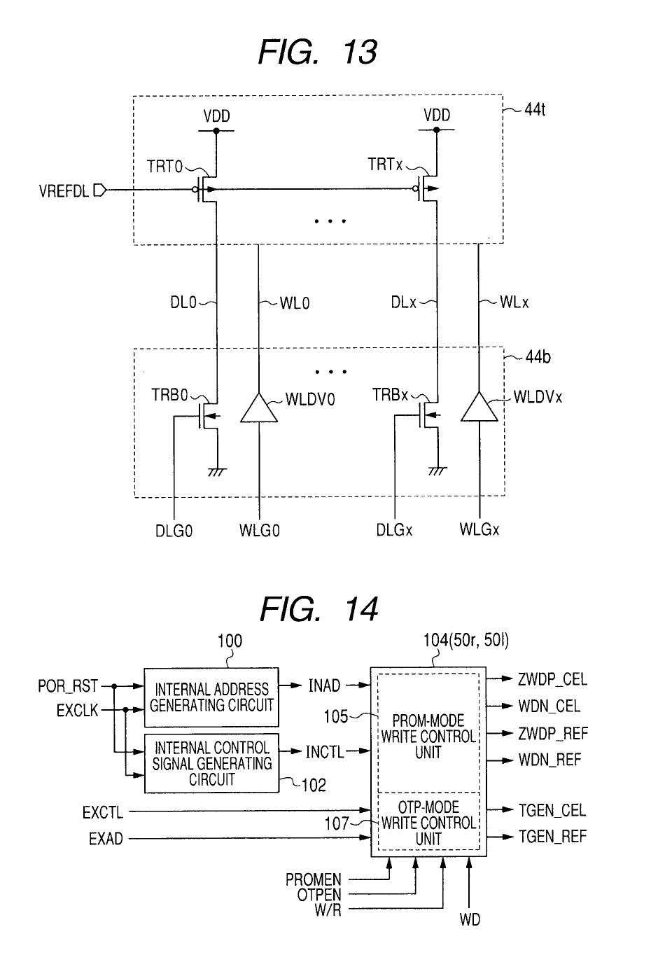

FIG. 14 is a drawing more specifically illustrating control signals relevant to write control of the column decoder+write control circuits 50r and 50l which are illustrated in FIG. 6. In FIG. 14, for ease of drawing, a write control circuit of the blocks 50r and 50l is illustrated as an identical configuration as expressed by a write control circuit 104. However, in write control in the PROM mode of the blocks 50r and 50l, a control signal to be generated becomes simply complementary in practice, and a circuit which controls writing in the PROM mode of the blocks 50r and 50l is shown typically by a PROM-mode write control unit 105 in the write control circuit 104. A write control in an OTP mode is only performed in the left column driver, and is not performed in the right column driver. A complementary signal is generated from an output signal of the PROM-mode write control unit 105 of FIG. 14, and supplied to the right column driver and the left column driver. Therefore, the OTP-mode write control unit 107 is arranged in the block 50l.

In FIG. 14, an internal address generating circuit 100 and an internal control signal generating circuit 102 are provided to the write control circuit 104 (50r, 50l). The internal address generating circuit 100 generates an internal address INAD according to an external clock signal EXCLK and a reset signal POR_RST which is a power-on detection signal, for example. The internal control signal generating circuit 102 generates an internal control signal (a row group control signal and a column group control signal) INCTL corresponding to each internal address signal INAD, according to the reset signal POR_RST and the external clock signal EXCLK.

To the write control circuit 104, the internal address signal INAD, the internal control signal INCTL, the external control signal EXCTL, an external address signal EXAD, an external write data WD, a PROM-mode enable signal PROMEN, an OTP-mode enable signal OTPEN, and a read/write mode instruction signal W/R are supplied.

In the write control circuit 104, the PROM-mode write control unit 105 generates write control signals ZWDP_CEL, WDN_CEL, ZWDP_REF, and WDN_REF, according to the write data WD and a column address signal. At the time of writing in the OTP mode, the OTP-mode write control unit 107 generates OTP write control signals TGEN_CEL and TGEN_REF, according to the write data, and also generates an OTP-mode write-in column selection signal CSLW_OTP. The PROM-mode write control unit 105 is provided in the column decoder+write control circuits 50r and 50l, illustrated in FIG. 6, respectively. On the other hand, the OTP-mode write control unit 107 is provided to the column decoder+write control circuit 50l illustrated in FIG. 6. Although detailed configuration of the write control circuit 104 is explained later, the write control circuit 104 includes a local write control circuit provided corresponding to each IO block, and the final write control signals are generated by the local write control circuit.

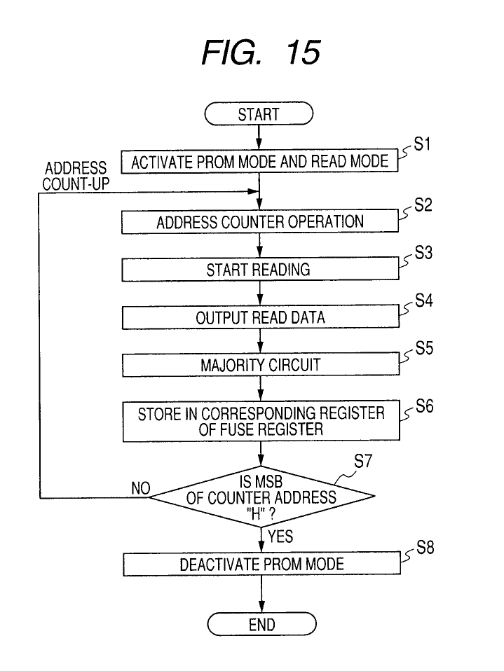

FIG. 15 is a flow chart illustrating a data read operation of the nonvolatile semiconductor memory unit of the semiconductor device according to Embodiment 1 of the present invention. Hereafter, with reference to FIG. 15, the data reading operation of the PROM/OTP array illustrated in FIG. 6 through FIG. 13 is explained.

First, a data read mode is set up (Step S1). Although any of a PROM mode and an OTP mode may be set up in the present read mode to perform data reading, FIG. 15 illustrates a case where the PROM mode is specified as an example. The present read mode is set up according to a read/write mode instruction signal W/R as an external control signal, or is specified according to power activation. Here, operation in the case where the read mode is specified according to power activation is explained as an example.

When the read mode is turned to ON state (when the read mode is set up), the internal address generating circuit 100 and the internal control signal generating circuit 102 which are illustrated in FIG. 14 generate the internal address INAD and the internal control signal INCTL, respectively, according to the activation of the reset signal POR_RST. The internal address generating circuit 100 includes an address counter internally. At the time of activation, the internal address generating circuit 100 performs a count operation according to the external clock signal EXCLK and generates an internal address (Step S2).

Subsequently, the write control circuit 104 becomes in a non-active state when the read/write mode instruction signal W/R specifies a read mode, and each write control signal is maintained in an initial state (non-active state). The column decoder generates a read column selection signal CSLR according to the internal address INAD, and the bottom row decoder drives a word line WL of the selected row to a selected state according to the row address of the internal address signal INAD. Data of a selected memory cell is supplied to the sense amplifier circuit, and internal read of data is executed (Step S3).

The internal read data from the sense amplifier circuit is supplied to the majority circuit, the logical value of the internal read data is determined in accordance with the majority decision criterion, and the majority decision result is stored in a corresponding register of the fuse register 26 (refer to FIG. 5) (Steps S4, S5, S6).

Subsequently, it is determined whether the most significant bit MSB of the counter address of the address signal generated by the address counter is set to H level (Step S7). When the most significant bit MSB of the address (counter address) generated by the address counter is determined to be H level, the PROM mode is set to OFF state since the stored data of all the reading-target memory cells has been read and stored in the fuse register, and the data reading operation is completed (Step S8).

On the other hand, at Step S7, when the most significant bit MSB of the counter address is determined not to be H level, the address counter will operate again to perform count-up of the address, and henceforth operations from Step S4 to Step S7 are repeated. Operations from Step S2 to Step S7 are repeatedly executed until the most significant bit MSB of the counter address reaches H level, and internal read of necessary data, majority decision, and storing to the fuse register are performed.

By the series of operations, the stored data of the memory cell can be automatically read internally according to the power activation. In the data reading, the internal read and storing in the fuse register may be performed according to the external control signal EXCTL, the external address signal EXAD, and the read/write mode instruction signal W/R. That is, the PROM mode is set up using the mode selection signal MDSEL and the fuse activation signal FUSEN which are supplied by the mode setting circuit, and the PROM-mode enable signal PROMEN is activated. At this time, the read/write mode instruction signal W/R is set to the state which indicates a read mode. In the state, the internal data read is performed in a test mode, and data is stored in the fuse register. It is sufficient that the present mode is used in order to verify whether the internal state is programmed accurately.

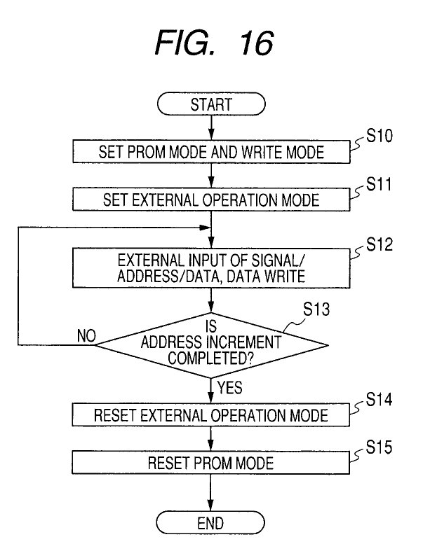

FIG. 16 is a flow chart illustrating operation in a write mode in which data writing is performed in a PROM mode. Hereafter, with reference to FIG. 16, the data write operation in the PROM mode of the PROM/OTP-merged circuit illustrated in FIG. 6 through FIG. 13 is explained.

First, the PROM mode is set up using the mode selection signal MDSEL and the fuse activation signal FUSEN which are supplied by the mode setting circuit, and the PROM-mode enable signal PROMEN is activated. At this time also, the read/write mode instruction signal W/R is set to the state which indicates a write mode (Step S10).

When the PROM write mode is specified, the write control circuit 104 illustrated in FIG. 14 is set to the state in which the control signal EXCTL from the exterior and the address signal EXAD from the exterior are selected (Step S11). By setting the external operation mode, write control signals ZWDP_CEL, WDN_CEL, ZWDP_REF, and WDN_REF are generated according to the externally-supplied signals EXCTL and EXAD and the write data WD, and data writing is performed to a memory cell specified by the external address EXAD (Step S12). In the present case, as explained with reference to FIG. 10, in the bit-line write drive circuits 70R0, 70R1, 70L0, and 70L1, the PROM write drive circuit is driven to a selected state according to the column address and the write data, and current is flowed in an opposite direction mutually through the selected bit line BL and the selected bit line BLB which are arranged in a pair. On the other hand, the digit line DL is also driven to a selected state according to the row address signal and the PROM-mode write indication signal. Complementary data is written to the memory cell MCC and the memory cell MCR by magnetic field induced by the current which flows through the bit line BL, the bit line BLB, and the digit line DL. In the present data writing, as explained earlier, the same data is written to three sets of memory cells per one IO internally.

After the data writing has completed, it is determined whether the address has arrived at the last address (Step S13). It is sufficient that the present determination is performed by determining whether the last address has been arrived at in an external circuit tester. Alternatively, it is also preferable that the last address is stored in a register (not shown) in the main control circuit, and that the current address is compared with the last address stored in the register. A flag is outputted to the external tester when the comparison result is in agreement.

When the current address has not arrived at the last address, the flow returns to Step S12 again. Then, the following address and data are supplied from the exterior and data writing to the new address is performed.

On the other hand, when it is determined that data writing to the last address has completed at Step S13, the external operation mode is reset (Step S14). The reset is performed by deactivating the write-mode instruction signal, for example.

Subsequently, the PROM-mode enable signal PROMEN is deactivated to reset the PROM mode (Step S15). A series of the processes described above can perform data writing in the PROM mode to the memory cell as a write target.

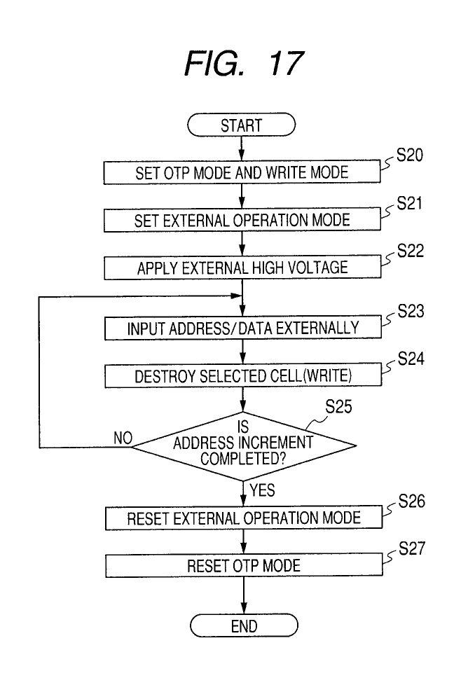

FIG. 17 is a flow chart illustrating a data write operation in an OTP mode. Hereafter, with reference to FIG. 17, the data write operation in the OTP mode of the PROM/OTP-merged circuit illustrated in FIG. 6 through FIG. 13 is explained.

First, in the mode setting circuit 32, the OTP mode is specified by the mode selection signal MODESEL and the fuse activation signal FUSEN which are supplied from the exterior, and the OTP-mode enable signal OTPEN is activated. At this time, the read/write mode instruction signal W/R is set to the state which indicates data writing.

When the read/write mode instruction signal W/R is set to the state which indicates data writing, the internal operation mode is set in the write control circuit 104 (Step S21).

Subsequently, the bit-line writing voltage VREFBL is set to a high voltage level (Step S22). By supplying the present bit-line writing voltage VREFBL from the exterior, it is possible to avoid the necessity of generating the high writing voltage inside the PROM/OTP-merged circuit, accordingly it is possible to reduce the layout area of an otherwise required internal high voltage generation circuit.

Subsequently, an external control signal EXCTL and an external address signal EXAD are supplied together with write data WD (Step S23). In the OTP-mode write control unit 107 in the write control circuit 104 illustrated in FIG. 12, write control signals OTPW_CEL and OTPW_REF are generated according to the external control signal EXCTL, the external address signal EXAD, and the write data WD. According to the data write directions in the OTP mode, the row decoder drives a word line of a selected row to a selected state according to the address signal. To the addressed three-bit memory cells, the high bit-line writing voltage VREFBL is applied, a barrier film of the variable magnetoresistive element is destroyed, and an upper electrode and a lower electrode of the variable magnetoresistive element are short-circuited; accordingly destructive writing is performed (Step S24).

Subsequently after completion of the writing, it is determined whether the address has arrived at the last address (Step S25). When the address has not arrived at the last address, the flow returns to Step S23 again, and destructive writing of data is performed according to the address signal AD, the control signal EXCTL, and write data WD which are supplied next from the exterior.

At Step S25, when it is determined that the last address have been arrived at, the read/write mode instruction signal W/R is set to a non-active state, and the external operation mode is reset (Step S26). Then, the mode selection signal MODESEL and the fuse activation signal FUSEN are deactivated, and the OTP mode is reset (Step S27). Accordingly, data writing in the OTP mode to the necessary memory cell is completed.

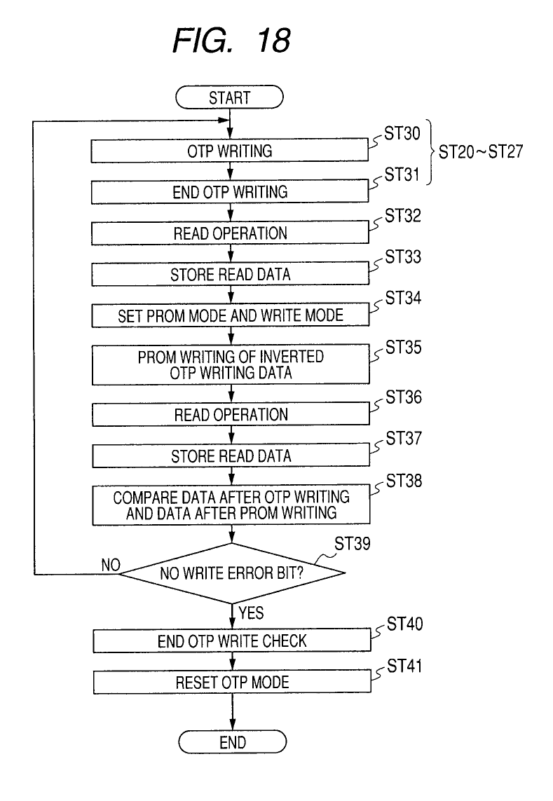

FIG. 18 is a flow chart illustrating an OTP write verify mode in which OTP-mode write data is checked. Hereafter, with reference to FIG. 18, the OTP write verifying operation of the PROM/OTP-merged circuit illustrated in FIG. 6 through FIG. 13 is explained.

First, Step ST20 to Step ST27 illustrated in FIG. 17 are executed to perform data writing in the OTP mode (Step ST30). When data writing is completed to all the write target addresses, writing in the OTP mode is terminated (Step ST31).

Subsequently, the read/write mode instruction signal W/R is set to the state which specifies the read mode, and data reading is performed (Step ST32). In the present case, since the read operation is performed on the same basis in any of the PROM mode and the OTP mode, the OTP mode may not be reset, and the data read operation may be performed in the state where the OTP mode remains still specified.

Subsequently, data read at Step ST32 is stored (Step ST33). As the storing area of the read data at Step ST33, it is also preferable to provide a dedicated data storing region (register) or to use the fuse register 26 illustrated in FIG. 5.

Subsequently, after storing all of the read data, the PROM mode is set, and the write mode which performs data writing is set (Step ST34). Since the write mode is set in the present case, data writing is performed according to the externally-supplied address signal under the control of the external tester. In the data writing in the PROM mode, inverted data of the write data which has been written at the time of data writing in the OTP mode is written in the PROM mode (Step ST35). Writing of the inverted data in the PROM mode is based on the following reasons.

Namely, in the data writing in the OTP mode, a variable magnetoresistive element in one memory cell is set to a short-circuit condition and, the other memory cell is maintained in an unfixed state (previous state). Therefore, a memory cell to which the OTP-mode writing is not performed is in a high resistance state or in a low resistance state like a normal cell. By writing the inverted data into a memory cell which has not been written in the OTP mode, the memory cell concerned is set to a fixed resistance state from an unfixed state.

Writing is completed after writing inverted data in all the memory cells as the writing targets. Then, the read/write mode instruction signal W/R is deactivated, and set to the state which specifies the read mode (Step ST36). At the time of the read operation, data reading may be performed according to a control signal and an address signal which are supplied from the exterior, or as explained earlier, data reading may be performed according to an internal address and an internal control signal.

In the read mode, a memory cell is selected according to the address, the internal reading of data is performed by the sensing operation and the majority decision, (Step S36), and the read data is stored (Step ST37). The read data obtained at Step ST37 is stored in a dedicated test data register etc. as an example.

Data read out and stored at Step ST33 and Step ST37 are compared (Step ST38). A memory cell to which OTP writing has been performed and is in a low resistance state is in a state where the value of resistance is still lower than a memory cell in a low resistance state, as illustrated in FIG. 12. A memory cell as a comparison target is in a low resistance state, and it is possible to determine whether destructive writing which produces insulator layer destruction has been accomplished reliably. In the present comparison, that is, when data writing in the OTP mode has been accurately performed, the logical values of write data in the PROM write mode and in the OTP write mode are in agreement. Therefore, in the present comparison, it is determined whether data in disagreement exists (Step ST39). When there is even one bit of a write error (destructive write failure), the flow returns to Step ST30, data writing to the memory cell of a write error is performed in the OTP mode, and hereafter, the same processes after Step S30 are executed again. In the present case, the address of a memory cell in which a write error has occurred is stored in an external circuit tester, and data writing is performed to the memory cell in which the write error has occurred.

When it is determined at Step ST39 that no write error bit exists, the OTP write check is completed and the OTP write verify mode is completed (Step ST40). Accordingly, supply of an address and write data from the external tester is completed, and the OTP mode is reset according to the mode selection signal MODESEL (Step ST41). Accordingly, the write period in the OTP mode is completed.

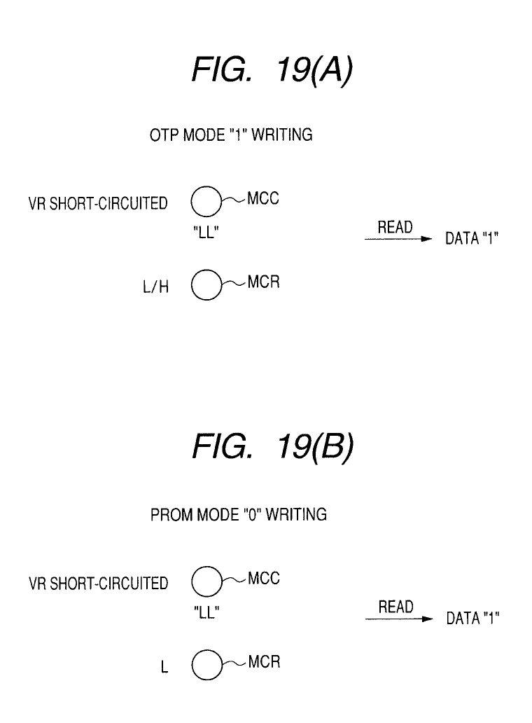

FIG. 19 (A) and FIG. 19 (B) illustrate specifically the operation at Step ST38 of the OTP write verify mode. In FIG. 19 (A), writing in the OTP mode is performed at Step ST30. Now, let's consider the state where writing of data “1” is performed. Here, it is assumed that data “1” is associated with a low resistance state (L data). In the present case, in the memory cell MCC, a variable magnetoresistive element VR becomes in a short-circuit condition, and in a super-low resistance state; accordingly data “LL” is stored. On the other hand, since a high writing voltage is not transferred to the reference memory cell MCR, the reference memory cell MCR is maintained in the write state in the previous PROM mode, and remains in a normal low resistance state or in a high resistance state, namely in a state of storing L data or H data. When data reading is performed in the present case, the memory cell MCC has a lower value of resistance than the reference cell MCR, and reading of data “1” is performed.

On the other hand, as illustrated in FIG. 19 (B), writing of the inverted data “0” is performed in the PROM mode at Step ST35. In the present case, the variable magnetoresistive element of the memory cell MCC is a short-circuit condition, even if data writing in the PROM mode is performed, the resistance state does not change, but the memory cell MCC is in a super-low resistance state, namely in a state of storing “LL” data. On the other hand, data “1” is stored in the reference cell MCR, and the reference cell MCR is set to a low resistance state and L data is stored. When data reading is performed, even in the present case, the memory cell MCC has the value of resistance lower than the value of resistance of the reference cell MCR in a low resistance state, and data “1” is read.

On the contrary, when data “0” is written in the OTP mode, the reference cell MCR becomes in a super-low resistance state (LL data), and the memory cell MCC is in an unfixed state. When the inverted data “1” is written in the PROM mode, the memory cell MCC becomes in a low resistance state, and the reference cell MCR becomes in a super-low resistance state. Therefore, in data reading, the memory cell MCC becomes in a fictitiously high resistance state, and data “0” is read.

Therefore, by writing data in the OTP mode and then writing the inverted data in the PROM mode, it is possible to identify externally whether a memory cell as a writing target has been certainly set to the short-circuit condition, and it is possible to identify whether data writing has been accurately performed by the OTP mode. Next, internal configuration of peripheral circuits, such as individual write control circuit, is explained.

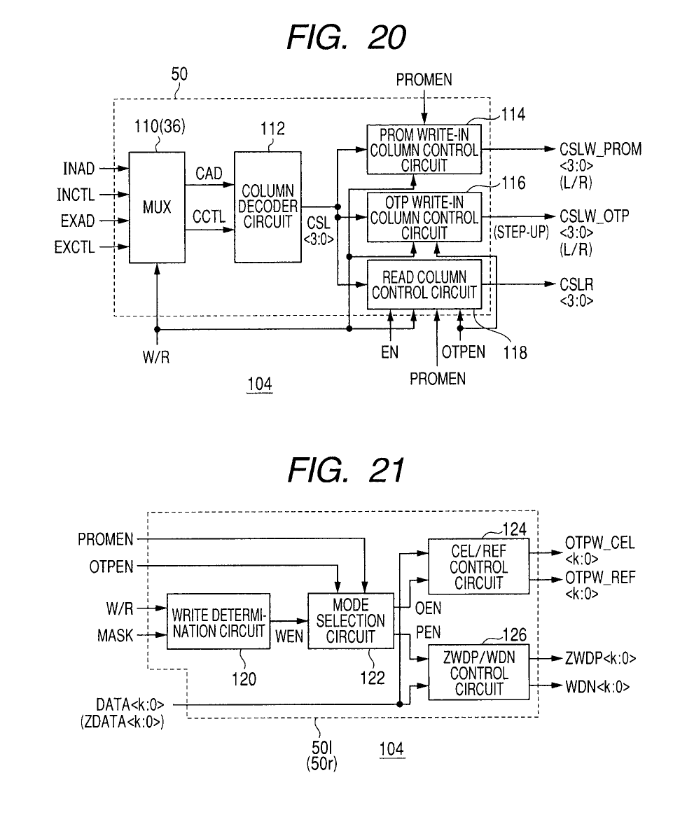

FIG. 20 illustrates roughly configuration of a column decoder 50 which is a part of the write control circuit 104 illustrated in FIG. 14. The column decoder 50 illustrated in FIG. 20 is the part of the column decoder included in the column decoder+write control circuits 50r and 50l, illustrated in FIG. 6. Since the configuration of the column decoder of the block 50r and the configuration of the column decoder of the block 50l is the same except for the configuration of a part which generates a read column selection signal, in FIG. 20, the column decoder 50 illustrates the configuration of a part which generates a column selection control signal to the right column driver and the left column driver.

The column decoder 50 illustrated in FIG. 20 includes a multiplexer (MUX) 110, a column decoder circuit 112, a PROM write-in column control circuit 114, an OTP write-in column control circuit 116, and a read column control circuit 118. The multiplexer (MUX) 110 selects either a group of an internal address INAD and an internal control signal INCTL or a group of an external address EXAD and an external control signal EXCTL, according to the read/write mode instruction signal W/R. The column decoder circuit 112 performs a decode operation according to a column address signal CAD and a column group control signal CCTL supplied by the multiplexer 110. Each of the PROM write-in column control circuit 114, the OTP write-in column control circuit 116, and the read column control circuit 118 receives a column selection signal CSL <3:0> from the column decoder circuit 112.

When the read/write mode instruction signal W/R indicates a write mode, the multiplexer 110 selects the external address signal EXAD and the external control signal EXCTL, and generates the column address signal CAD and the column group control signal CCTL. On the other hand, when the read/write mode instruction signal W/R indicates a read mode, the multiplexer 110 selects the internally-generated address INAD and the internally-generated control signal INCTL, and generates the column address signal CAD and the column group control signal CCTL.

The column decoder circuit 112, of which the decode timing is specified according to the column group control signal CCTL, decodes the column address signal CAD and generates a four-bit column selection signal CSL <3:0>.

The PROM write-in column control circuit 114 receives the PROM-mode enable signal PROMEN and the read/write mode instruction signal W/R. The PROM write-in column control circuit 114 is activated when data writing in the PROM mode is indicated, and generates a PROM write-in column selection signal CSLW_PROM <3:0> according to the column selection signal CSL <3:0> from the column decoder circuit 112.

The OTP write-in column control circuit 116 receives the OTP-mode enable signal OTPEN and the read/write mode instruction signal W/R. The OTP write-in column control circuit 116 is activated when these signals indicate data writing in the OTP mode, and generates an OTP-mode write-in column selection signal CSLW_OTP <3:0>, according to the column selection signal CSL <3:0>.

The read column control circuit 118 is arranged only in the column decoder+write control circuit 50r illustrated in FIG. 6. The read column control circuit 118 is activated when either the OTP enable signal OTPEN or the PROM enable signal PROMEN is in an active state and when the read/write mode instruction signal W/R indicates data reading. Then, the read column control circuit 118 generates a read column selection signal CSLR <3:0>, according to the column selection signal CSL <3:0>.

Therefore, when data writing in the PROM mode and in the OTP mode is performed, a column selection operation is controlled according to the external address signal EXAD and the external control signal EXCTL. In the data read mode, reading operation is controlled according to internally-generated address signal INAD and the internally-generated control signal INCTL.

In FIG. 20, the letters (L/R) attached at the lower part of the write column selection signals indicate the state where the left write-in column selection signal and the right write-in column selection signal are generated separately. As for the write column selection signals CSLW_PROM <3:0> and CSLW_OTP <3:0>, a column selection signal of the same logical value is generated in the right column decoder and the left column decoder.

FIG. 21 illustrates roughly configuration of a part which generates a write control signal of the write control circuit 104 illustrated in FIG. 14. FIG. 21 illustrates roughly the configuration of a part corresponding to the column decoder+write control circuit 50l, illustrated in FIG. 6.

In FIG. 21, the column decoder+write control circuit 50l includes a write determination circuit 120, a mode selection circuit 122, a CEL/REF control circuit 124, and a ZWDP/WDN control circuit 126. The write determination circuit 120 receives the read/write mode instruction signal W/R and the mask indication signal MASK. The mode selection circuit 122 selects a write mode in response to the output signal WEN of the write determination circuit 120, the PROM-mode enable signal PROMEN, and the OTP-mode enable signal OTPEN. The CEL/REF control circuit 124 receives the OTP-mode indication signal OEN outputted by the mode selection circuit 122, and the write data DATA<m:0>. The ZWDP/WDN control circuit 126 receives the PROM-mode indication signal PEN from the mode selection circuit 122 and the write data DATA<m:0>.

The mask indication signal MASK is a signal which instructs masking of the data writing to the PROM/OTP cell array. The data write mask may mask the data writing in units of one bit, or alternatively, may mask the data writing in units of two or more bits.

The write determination circuit 120 drives the write instruction signal WEN to an active state, when the read/write mode instruction signal W/R indicates the data writing and when the mask indication signal MASK indicates a non mask to the data writing,

When the write instruction signal WEN from the write determination circuit 120 is activated, the mode selection circuit 122 activates either the OTP-mode write indication signal OEN or the PROM-mode write indication signal PEN, according to the active state/non-active state of the PROM-mode enable signal PROMEN and the OTP-mode enable signal OTPEN.

The CEL/REF control circuit 124 is provided in common to an IO block <m:0>. When the OTP-mode write indication signal OEN is activated, the CEL/REF control circuit 124 generates OTP-mode write data indication signals OTPW_CEL<m:0> and OTPW_REF<m:0>, according to the write data DATA<m:0>. When the write data bit DATA<i> is H data bit, the CEL/REF control circuit 124 sets the OTP-mode write data indication signal OTPW_CEL<i> as H level, and transfers the writing voltage VREFBL from the exterior to the memory cell MCC. On the other hand, when the write data bit DATA<i> is L data bit, the CEL/REF control circuit 124 sets the OTP-mode write data indication signal OTPW_REF<i> to the reference cell as H level, and transfers the bit-line writing voltage VREFBL to the reference cell MCR.

When the OTP-mode write indication signal OEN is deactivated, the CEL/REF control circuit 124 sets all of the OTP-mode write data indication signals OTPW_CEL<m:0> and OTPW_REF<m:0> as L level, and cuts off the bit-line writing voltage supply path from the exterior.

The ZWDP/WDN control circuit 126 is provided common to the IO block <m:0>. When the PROM-mode write indication signal PEN from the mode selection circuit 122 is activated, the ZWDP/WDN control circuit 126 is activated and generates bit-line write-data indication signals ZWDP<m:0> and WDN<m:0>, according to the write data DATA<m:0>. When the write data bit DATA<i> is H data bit, the ZWDP/WDN control circuit 126 sets the write data instruction signal ZWDP<i> as H level, and sets the write data instruction signal WDN<i> as H level. Accordingly, the transistor for electric discharge to a bit line is conducted. On the other hand, when the write data bit DATA<i> is L data bit, the write data instruction signals ZWDP<i> and WDN<i> are set to L level, and the charging transistor to the bit line is set to ON state. When the PROM-mode write indication signal PEN is deactivated, the ZWDP/WDN control circuit 126 sets the write data instruction signal ZWDP<m:0> as H level, and sets the write data instruction signal WDN<m:0> as L level. Accordingly, in the bit-line writing driver, both the transistors which perform electric charge and electric discharge of the bit line are set to OFF state, and the PROM bit-line writing driver is set to a high output impedance state.

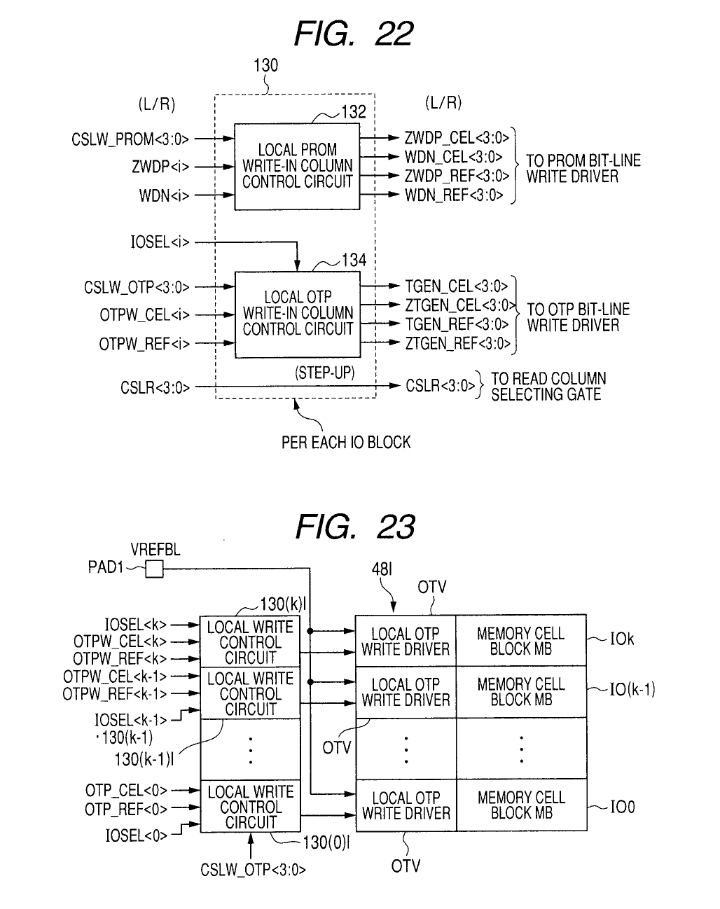

FIG. 22 illustrates roughly configuration of a local write control unit of the write control circuit. The local write control circuit 130 illustrated in FIG. 22 is provided for every IO block, and is arranged corresponding to each of IO blocks IO0-IOm in the left column driver 48l and the right column driver 48r, illustrated in FIG. 6.

The local write control circuit 130 includes a local PROM write-in column control circuit 132 for controlling data writing in the PROM mode, and a local OTP write-in column control circuit 134 for controlling data writing in the OTP mode.

Upon receiving a four-bit PROM-mode write-in column selection signal CSLW_PROM <3:0> and write data instruction signals ZWDP<i> and WDN<i>, the local PROM write-in column control circuit 132 generates write control signals ZWDP_CEL <3:0>, WDN_CEL <3:0>, ZWDP_REF <3:0>, and WDN_REF <3:0>, which are supplied to the corresponding PROM bit-line write driver. The local PROM write-in column control circuit 132 is arranged in each of the left column driver and the right column driver. In FIG. 22, as shown by the letters (L/R), these write control signals are generated in each of the left column write driver and the right column write driver. The write data instruction signals ZWDP<i> and WDN<i> are a one-bit signal among the write data instruction signals ZWDP<m:0> and WDN<m:0> generated by the ZWDP/WDN control circuit 126 illustrated in FIG. 21, according to the write data supplied to the IO block IOi.

The write control signals ZWDP_CEL <3:0>, WDN_CEL <3:0>, ZWDP_REF <3:0> and WDN_REF <3:0> are supplied to each of three groups of bit-line pairs of which four pairs of bit lines are included in each of the corresponding IO blocks. Based on the write column selection signal CSLW_PROM <3:0>, one pair of bit lines are selected in each group. According to the write data instruction signals ZWDP<i> and WDN<i> to the selected bit-line pair, a write control signal to the selected bit-line pair is generated, and the direction of the bit-line current is determined. The write control signals ZWDP_CEL <3:0> and WDN_CEL <3:0> control data writing to the memory cell MCC, and the write control signal ZWDP_REF <3:0> and WDN_REF <3:0> control data writing to the reference cell MCR.

Therefore, the write control signal ZWDP_REF <3:0> becomes in a non-active state when the write control signal ZWDP_CEL <3:0> is activated, and the write control signal WDN_REF <3:0> becomes in a non-active state when the write control signal WDN_CEL <3:0> is activated. Accordingly, complementary data can be written into the memory cell MCC and the reference cell MCR.

The local OTP write-in column control circuit 134 is activated when the IO block selection signal IOSEL<i> is activated, receives the OTP-mode write-in column selection signal CSLW_OTP <3:0> and the OTP-mode write data indication signals OTPW_CEL<i> and OTPW_REF<i>, and generates write control signals TGEN_CEL <3:0>, ZTGEN_CEL <3:0>, TGEN_REF <3:0>, and ZTGEN_REF <3:0>, for controlling the conduction of the OTP bit-line write driver and the transmission gate. In data writing in the OTP mode, a bit-line writing voltage from the exterior is transferred to a selected I/O block to perform data writing. Therefore, data writing is sequentially performed for every IO block at the time of data writing in the OTP mode. Accordingly, it is possible to supply voltage with sufficient amplitude by using the bit-line writing voltage VREFBL supplied from the exterior, and it is possible to perform destructive writing by low consumption current.

The OTP mode write control signals TGEN_CELL <3:0> and ZTGEN_CEL <3:0> are activated when performing data writing to the memory cell MCC, and the write control signals TGEN_REF <3:0> and ZTGEN_REF <3:0> are activated when performing data writing to the reference cell MCR. Accordingly, a high writing voltage is transferred to one of the bit line BL and the bit line BLB which are arranged in pairs.

When the write data instruction signal OTPW_CEL<i> is activated, the write control signals TGEN_CEL <3:0> and ZTGEN_CEL <3:0> to a memory cell are selectively activated according to the write column selection signal CSLW_OTP <3:0>. On the other hand, when the write data instruction signal OTPW_REF<i> is activated, the reference cell write control signals TGEN_REF <3:0> and ZTGEN_REF <3:0> are selectively activated according to the OTP write-in column selection signal CSLW_OTP <3:0>.

The read column selection signal CSLR <3:0> is supplied to the corresponding read column selecting gate, bypassing the present local write control circuit 130.

An OTP bit-line write driver is provided in the left column driver 48l. The local OTP write-in column control circuit 134 is provided to the left column driver.

FIG. 23 illustrates roughly a way of application of control signals to the local write control circuit in data writing in the OTP mode.

In FIG. 23, the local write control circuits 130(0)-130(k) are provided corresponding to each of IO blocks IO0-IOk. The OTP-mode write-in column selection signal CSLW_OTP <3:0> is supplied in common to the local write control circuits 130(0)-130(k). On the other hand, the IO block selection signal and the OTP-mode write data indication signal are individually supplied to the local write control circuits 130(0)-130(k). That is, an IO block selection signal IOSEL<0>, and OTP-mode write data indication signals OTPW_CEL<0> and OTPW_REF<0> are supplied to the local write control circuit 130(0). An IO block selection signal IOSEL<k−1> and OTP-mode write data instruction signals OTPW_CEL<k−1> and OTPW_REF<k−1> are supplied to the local write control circuit 130(k−1). An IO block selection signal IOSEL<k> and OTP-mode write data instruction signals OTPW_CEL<k> and OTPW_REF<k> are supplied to the local write control circuit 130(k).

Each of the IO blocks IO0-IOk includes a memory cell block MB and a local OTP write driver OTV. The local OTP write driver OTV is included in the left column driver 48l illustrated in FIG. 7. The bit-line writing voltage VREFBL from the pad PAD1 is supplied in common to the local OTP write driver OTV corresponding to each of the IO blocks IO0-IOk. Each of the local write control circuits 130(0)-130(k) controls transferring of the bit-line writing voltage VREFBL to the corresponding local OTP write driver. Accordingly, data writing is performed in units of IO block at the time of data writing in the OTP mode.

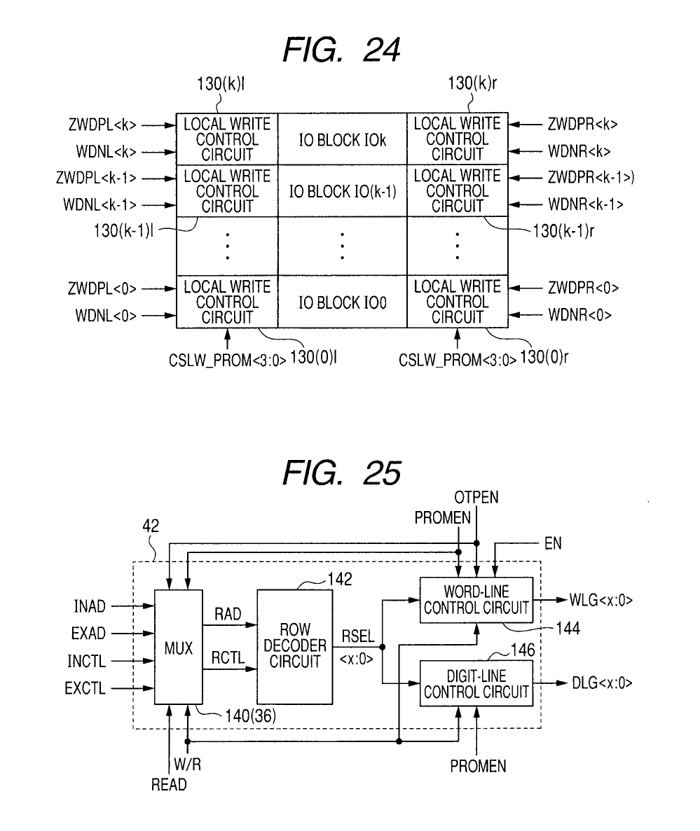

FIG. 24 illustrates roughly a way of application of control signals in data writing in the PROM mode. In FIG. 24, local write control circuits 130(k)l-130(0)l are provided in the left-hand side of the IO blocks IO0-IOk, and local write control circuits 130(k)r -130(0)r are provided in the right-hand side of the IO blocks IO0-IOk. The PROM-mode write-in column selection signal CSLW_PROM<3:0> is supplied in common to the local write control circuits 130(k)l-130(0)l, and the PROM-mode write-in column selection signal CSLW_PROM<3:0> is supplied in common to the local write control circuits 130(k)r-130(0)r.

Write data instruction signals WDNL<0> and ZWDPL<0> through WDNL<k> and ZWDPL<k> are supplied individually to the local write control circuits 130(0)l-130(k)l, and write data instruction signals WDNR<0> and ZWDPR<0> through WDNR<k> and ZWDPR<k> are supplied individually to the local write control circuits 130(0)r -130(k)r. Therefore, data writing is performed in parallel to the blocks IO0-IOk at the time of data writing in the PROM mode (when the mask signal MASK is in a non-active state and in a non-masked state to data writing).

FIG. 25 illustrates roughly an example of configuration of the row decoder 42 illustrated in FIGS. 5 and 6. In FIG. 25, the row decoder 42 includes a multiplexer (MUX) 140, a row decoder circuit 142, a word-line control circuit 144, and a digit-line control circuit 146. The multiplexer (MUX) 140 selects one of the internal address signal INAD and the external address signal EXAD, and one of the internal control signal INCTL and the external control signal EXCTL. The row decoder circuit 142 performs a decode operation according to a row address signal RAD and a row group control signal RCTL supplied by the multiplexer 140, and generates a row selection signal RSEL<x:0>. The word-line control circuit 144 generates a word-line selection signal WLG<x: 0> according to the row selection signal RSEL<x: 0>. The digit-line control circuit 146 generates a digit selection signal DLG<x:0> according to the row selection signal RSEL<x:0>.

The multiplexer 140 selects the external address signal EXAD and the external control signal EXCTL, when the PROM-mode enable signal PROMEN and the OTP-mode enable signal OTPEN are activated and when the read/write mode instruction signal W/R indicates a write mode. On the other hand, the multiplexer 140 selects the internal address signal INAD and the internal control signal INCTL, when either the PROM-mode enable signal PROMEN or the OTP-mode enable signal OTPEN is activated, and when the read/write mode instruction signal W/R indicates a data reading or when the read activation signal READ is in an active state. The read activation signal READ is activated internally at the time of power-on etc., and puts into operation the data reading and the setup of the initial state.

When decode timing is set up according to the row group control signal RCTL, the row decoder circuit 142 decodes the internal row address signal RAD and drives one of the row selection signals RSEL<x:0> to a selected state.

The word-line control circuit 144 generates a word-line selection signal WLG<x:0> according to the row selection signal RSEL<x:0>, when one of the enable signals PROMEN, OTPEN, and EN is activated, and when the read/write mode instruction signal W/R indicates data reading. The enable signal EN is activated in a cell-data read mode in the interior, and activates the word-line control circuit 144. The present word-line control circuit 144 generates also the word-line selection signal WLG<x:0> according to the row selection signal RSEL<x:0>, when the read/write mode instruction signal W/R indicates data writing and when the OTP-mode enable signal OTPEN is in an active state.

When the PROM-mode enable signal PROMEN is activated and when the read/write mode instruction signal W/R indicates data writing, the digit-line control circuit 146 is activated and generates a digit-line selection signal DLG<x:0> according to the row selection signal RSEL<x:0>. When the OTP-mode enable signal OTPEN is in an active state, the digit-line control circuit 146 is maintained in a non-active state even if the read/write mode instruction signal W/R indicates data writing. Accordingly, the digit-line control circuit 146 maintains the digit-line selection signal DLG<x:0> in a non-selection state.

The present row decoder 42 is provided in common to the IO blocks IO0-IOk. The row decoder 42 transfers the word-line selection signal WLG<x:0> and the digit-line selection signal DLG<x:0> respectively to the word-line driver circuit and the digit-line driver circuit which are included in the top row driver (44t) and in the bottom row driver (44b).

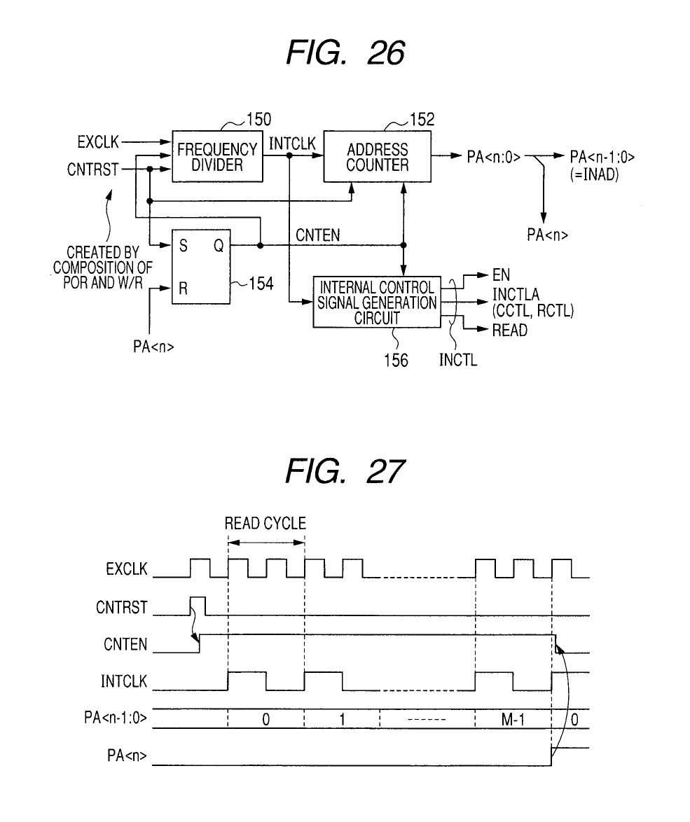

FIG. 26 illustrates roughly an example of configuration of the internal address generating circuit (100) and the internal control signal generating circuit (102) illustrated in FIG. 14. In FIG. 26, the internal address generating circuit includes a frequency divider 150, an address counter 152, a set/reset flip-flop 154, and an internal control signal generation circuit 156. The frequency divider 150 divides the external clock signal EXCLK to generate an internal clock signal INTCLK at the time of activation. The address counter 152 performs a count operation according to the internal clock signal INTCLK, and generates a (n+1)-bit count value PA<n:0>. The set/reset flip-flop 154 is set by a reset signal CNTRST, and is reset by the most significant count bit PA<n>. The internal control signal generation circuit 156 generates an internal control signal INCTL synchronizing with the internal clock signal CINTCLK, at the time of activation.

The internal state of the frequency divider 150 is set to an initial state in response to the activation of the count reset signal CNTRST. Then, the frequency divider 150 performs the dividing operation while a count enable signal CNTEN from the output Q of the set/reset flip-flop 154 is in an active state, and generates the internal clock signal INTCLK by dividing the external clock signal EXCLK to one half, for example. The count reset signal CNTRST is generated by logical addition of the reset signal POR_RST and the read/write mode instruction signal W/R. The count reset signal CNTRST is activated at the time of power-on, at the time of system reset, or in the data read mode in the test mode.

The count value of the address counter 152 is reset to an initial value in response to the activation of the count reset signal CNTRST. Then, the address counter 152 counts the internal clock signal INTCLK to generate the count value PA<n:0>. An n-bit count PA<n−1:0> of the present count value PA<n:0> is supplied as the internal address INAD to the column decoder and the row decoder.

The set/reset flip-flop 154 is set when the count reset signal CNTRST is activated, and is reset when the most significant count bit PA<n> is set to H level.

The internal control signal generation circuit 156 generates the internal control signal INCTL in a predetermined sequence according to the internal clock signal INTCLK, while the count enable signal CNTEN is in an active state. The internal control signal INCTL includes a control signal INCTLA (a column group control signal CCTL, a row group control signal RCTL), a read activation signal READ, and a read enable signal EN. The read activation signal READ activates the data read mode of data stored in the PROM/OTP-merged circuit at the time of system reset, etc. A sense amplifier is activated according to the present signal, and reading of internal data and storing of data to the fuse register are performed. In addition, the multiplexer 140 is set to the state of selecting the internal signals INCLT and INAD.

Since it is at the time of data read mode that the internal control signal INCTL outputted from the internal control signal generation circuit 156 is utilized, the word-line selection timing, the bit-line selection timing, and the sense amplifier activation timing are set up according to the control signals RCTL, CCTL, and READ, respectively. It is sufficient that given data are sequentially stored in the fuse register on a first-in first-out basis, for example, synchronizing with the internal clock signal INTCLK.

In the configuration illustrated in FIG. 26, the frequency divider 150 and the set/reset flip-flop 154 are shared by the internal address generating circuit 100 and the internal control signal generating circuit 102 which are illustrated in FIG. 14, and the address counter 152 and the internal control signal generation circuit 156 are included in the internal address generating circuit 100 and the internal control signal generating circuit 102, respectively.

FIG. 27 is a timing chart illustrating operation of the internal address generating circuit illustrated in FIG. 26. Hereafter, with reference to FIG. 27, an internal address generating operation of the circuit illustrated in FIG. 26 is explained.

First, the count reset signal CNTRST is supplied. The present count reset signal CNTRST is a reset signal by the power-on detection signal POR, for example, or it is a reset signal externally supplied when the data reading starts. The set/reset flip-flop 154 is set by the activation of the count reset signal CNTRST, and sets its output, namely, the count enable signal CNTEN, to H level.

The frequency divider 150 performs dividing of the external clock signal EXCLK according to the activation of the count enable signal CNTEN (driven to H level), and generates the internal clock signal INTCLK. FIG. 27 illustrates an example operation in which the frequency divider 150 divides the external clock signal EXCLK to one half to generate the internal clock signal INTCLK. The address counter 152 counts from the count initial value synchronizing with the internal clock signal INTCLK, and increments the count value according to the internal clock signal INTCLK.

When the count bit PA<n−1:0> outputted by the address counter 152 increases from 0 to (M-1), access to the memory cell included in the PROM/OTP-merged circuit is completed. In the following clock cycle, when the count value of the address counter 152 is incremented, the most significant count bit PA<n> rises to H level, the set/reset flip-flop 154 is reset, and the count enable signal CNTEN is deactivated. The count bit PA<n−1:0> has all the bits in a state of “0.” Therefore, by utilizing the count reset signal CNTRST and the most significant count bit PA<n>, it is possible to set the internal circuit to a predetermined state at the time of power-on of MRAM, after reading data stored in the interior and storing the data in a fuse register, for example.

The internal control signal generation circuit 156 generates the read activation signal READ and the enable signal EN while the count enable signal CNTEN is in an active state. The internal control signal generation circuit 156 supplies the enable signal EN to the word-line control circuit 144 illustrated in FIG. 25, and supplies the read activation signal READ to the multiplexer 140.

The present read enable signal EN is supplied to the read column control circuit 118 illustrated in FIG. 20. When the read enable signal EN is activated, the read column control circuit 118 generates the read column selection signal CSLR <3:0> internally, according to the column selection signal from the column decoder circuit.

When the power-on detection signal POR is utilized as the count reset signal CNTRST, it is sufficient that the power-on detection circuit is provided in the main control circuit which controls the operation of the normal array, and that the power-on detection circuit is provided in common to the circuits which control the operation of the PROM/OTP array. It is sufficient to utilize configuration in which, in data reading in the PROM mode, the count reset signal CNTRST is activated according to a read-mode instruction signal (R) supplied from the exterior. Moreover, similarly in data reading in the OTP mode (at the time of an OTP write verifying operation), if it is possible to utilize configuration in which the count reset signal CNTRST is compulsorily activated according to the read-mode instruction signal (W/R) supplied from the exterior, it is possible to generate the address internally at the time of the verifying operation.

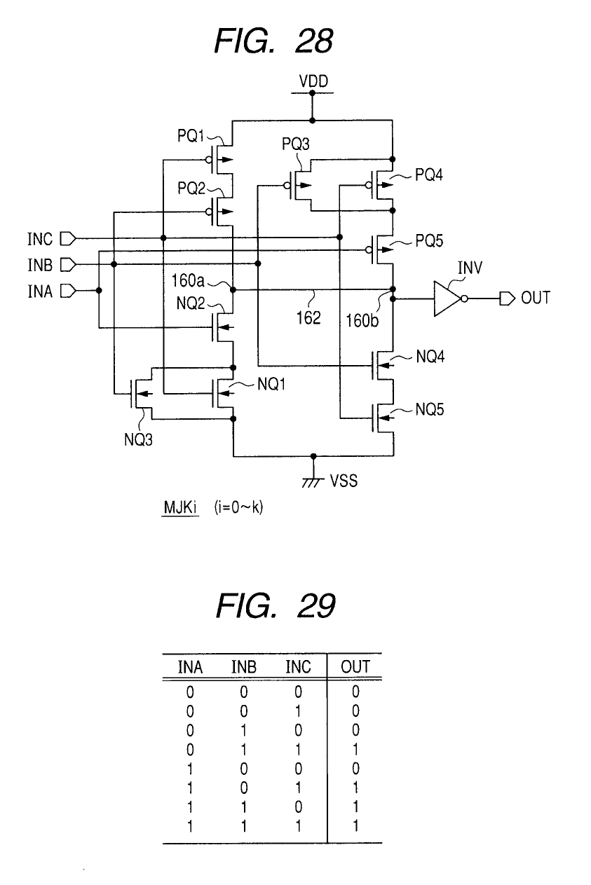

FIG. 28 illustrates an example of configuration of the majority circuits MJK0-MJKk illustrated in FIG. 6. Since all of the majority circuits MJK0-MJKk have the same configuration, FIG. 28 illustrates a majority circuit MJKi as a typical example.

In FIG. 28, the majority circuit MJKi includes a P-channel MOS transistors PQ1, PQ2 coupled in series with each other between a power node and an output node 160a, a P-channel MOS transistors PQ4, PQ5 coupled in series between the power node and an output node 160b, and a P-channel MOS transistor PQ3 coupled in parallel with the MOS transistor PQ4. The output node 160a and the output node 160b are interconnected by an output signal line 162.

An input signal INC is supplied to gates of the MOS transistors PQ1, PQ4, and an input signal INB is supplied to gates of the MOS transistors PQ2, PQ3. An input signal INA is supplied to a gate of the MOS transistor PQ5.

The majority circuit MJKi further includes N-channel MOS transistors NQ2, NQ1 coupled in series with each other between the output node 160a and the ground node, an N-channel MOS transistor NQ3 coupled in parallel with the MOS transistor NQ1, and N-channel MOS transistors NQ4, NQ5 coupled in series with each other between the output node 160b and the ground node. The input signal INC is supplied to gates of the MOS transistors NQ1, NQ5, and the input signal INB is supplied to gates of the MOS transistors NQ3, NQ4. The input signal INA is supplied to a gate of the MOS transistor NQ2.

A signal on the output signal line 162 is inverted by an inverter INV, and a majority decision result signal OUT is generated.

FIG. 29 is a table listing truth-values of the majority circuit MJKi illustrated in FIG. 28. As illustrated in FIG. 29, the majority circuit MJKi illustrated in FIG. 28 outputs, as the output signal OUT, an operation result of logical product of the input signal INB and the input signal INC, when the input signal INA is a logical value “0” (L level). On the other hand, when the input signal INA is a logical value “1” (H level), the majority circuit MJKi outputs an operation result of logical addition of the input signal INB and the input signal INC, as the output signal OUT.

That is, in the majority circuit MJKi of FIG. 28, when the input signal INA is L level, the MOS transistor NQ2 becomes in OFF state and the MOS transistor PQ5 becomes in ON state. In the present state, when both input signal INB and input signal INC are H level, the MOS transistors PQ1-PQ4 become in OFF state, the MOS transistors NQ4, NQ5 become in ON state, and the output node 160b becomes as L level. Therefore, the output signal OUT from the inverter INV becomes as H level (logical value “1”).

When the input signal INA is L level, and when at least one of the input signal INB and the input signal INC is L level, at least one of the MOS transistor NQ4 and the MOS transistor NQ5 becomes in OFF state, and a discharge path of the output nodes 160a, 160b is cut off. At this time, the MOS transistor PQ5 and at least one of the MOS transistor PQ3 and the MOS transistor PQ4 become in ON state, the output signal line 162 is charged to the level of the power supply voltage VDD, and the output signal OUT from the inverter INV becomes as L level (logical value “0”).

When the input signal INA is H level, the MOS transistor PQ5 becomes in OFF state and the MOS transistor NQ2 becomes in ON state. When both input signal INB and input signal INC are L level, the MOS transistors PQ1, PQ2 are in ON state, all the MOS transistors NQ1, NQ3, NQ4, NQ5 become in OFF state. The output signal line 162 is charged to the level of the power supply voltage VDD, and the output signal OUT from the inverter INV becomes as L level.

When the input signal INA is H level and at least one of the input signal INB and the input signal INC is H level, the MOS transistor PQ5 becomes in OFF state, and at least one of the MOS transistor PQ1 and the MOS transistor PQ2 becomes in OFF state, accordingly, a charge path for charging the output nodes 160a and 160b at both ends of the output signal line 162 is cut off. On the other hand, when the MOS transistor NQ2 becomes in ON state and at least one of the MOS transistor NQ1 and the MOS transistor NQ3 becomes in ON state according to the input signals INB and INC, the output signal line 162 is discharged to the level of the ground voltage VSS. Therefore, the output signal OUT from the inverter INV becomes H level. Accordingly, the majority circuit MJKi illustrated in FIG. 28 satisfies the truth table illustrated in FIG. 29, and the majority circuit MJKi is proven to perform the majority processing to the input signals.

By utilizing the majority circuit MJKi illustrated in FIG. 28, compared with configuration using the ordinary AND/NOR compound gates, the number of transistor elements can be reduced, the layout area of the majority circuit can be reduced correspondingly.

In the ordinary MRAM, after performing data writing in a PROM mode, data set up by the final test process is written in an OTP mode. Therefore, when a chip single body is shipped, the PROM/OTP-merged circuit operates in the OTP mode, and only data reading is executed. Therefore, the voltage VREFDL and VREFBL used at the time of writing is not used after shipment. Therefore, the pads (PAD0, PAD1) which transfer the voltage VREFDL and VREFBL should just be fixed to the ground voltage level at the time of shipment. The configuration concerned is realized by providing a switching transistor to a pad which supplies the voltage in question, and by setting internally the switching transistor to ON state with a control signal.

As described above, according to Embodiment 1 of the present invention, a common memory array is operated as a PROM and an OTPROM, and destructive writing is performed in particular to a memory cell at the time of data writing in the OTP mode. Therefore, the layout area can be reduced compared with configuration which provides a PROM and an OTPROM separately, and data rewriting in the PROM mode can be performed. By performing data writing in the OTP mode, the stored data are not destroyed by a leakage magnetic field which the normal array induces at the time of actual use of MRAM, and data can be held stably over a long period of time.

### Embodiment 2

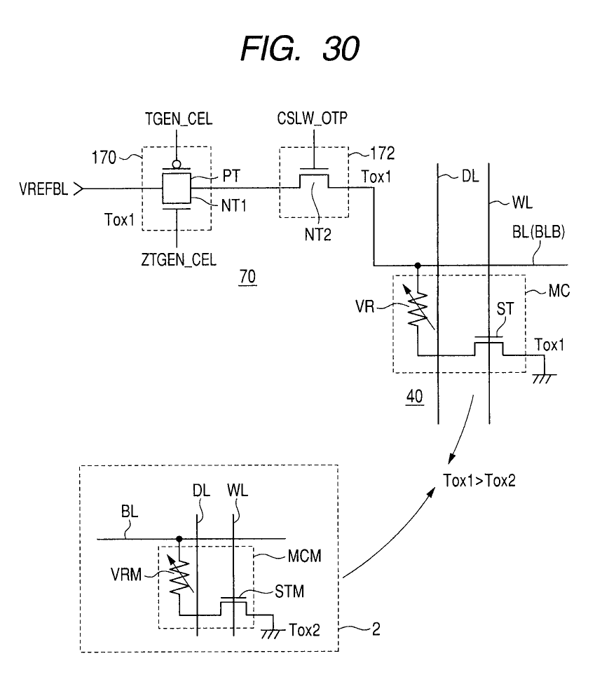

FIG. 30 is a drawing illustrating configuration of the principal part of a PROM/OTP-merged circuit according to Embodiment 2 of the present invention with cell structure of a normal array. In FIG. 30, a memory cell MC comprises a series body of a variable magnetoresistive element VR and a select transistor ST in a PROM/OTP array 40. The gate insulating film of the select transistor ST has a film thickness of Tox1.

On the other hand, in a bit-line write drive circuit 70, an OTP write drive circuit which performs data writing in an OTP mode is illustrated. In the OTP write drive circuit, a CMOS transmission gate 170 and a write column selection gate 172 are coupled in series between a bit line BL and a node which supplies a high bit-line writing voltage VREFBL. The CMOS transmission gate 170 includes a parallel body of a P-channel MOS transistor PT and an N-channel MOS transistor NT1, and write control signals TGEN_CEL and ZTGEN_CEL are supplied to the respective gates.

The write column selection gate 172 includes an N-channel MOS transistor NT2, and a write column selection signal CSLW_OTP is supplied to the gate. The MOS transistors PT, NT1, and NT2 as well as the select transistor ST have a gate insulating film of a film thickness of Tox1.

The CMOS transmission gate 170 and the write column selection gate 172 correspond to the CMOS transmission gates 90 and 92 and the write column selection gates 91 and 93 which are illustrated in FIG. 10, respectively.

In a normal array 2, a normal MRAM cell MCM is arranged corresponding to a cross point of a bit line BL with a word line WL and a digit line DL. The MRAM cell MCM includes a variable magnetoresistive element VRM and a select transistor S™. The present variable magnetoresistive element VRM has the same structure as the variable magnetoresistive element VR of the memory cell MC. The select transistor S™ of the MRAM cell MCM has a gate insulating film of a film thickness of Tox2. As for relationship of the film thicknesses Tox1 and Tox2 of the gate insulating films, the film thickness Tox1 of the gate insulating film of the select transistor ST of the memory cell MC included in the PROM/OTP array 40 is made greater than the film thickness Tox2 of the gate insulating film of the select transistor STM of the MRAM cell MCM.

At the time of data writing in an OTP mode, a bit-line writing voltage VREFBL is set as about two times higher voltage level than the power supply voltage. In order to transfer the present bit-line writing voltage VREFBL, the write column selection signal CSLW_OTP is also stepped up to a voltage level higher than the power supply voltage. The write control signal ZTGEN_CEL is also set to a high voltage level. In the select transistor ST, at the time of writing to the variable magnetoresistive element VR, a high voltage is applied and large current flows. The variable magnetoresistive element VR becomes in a super-low resistance state after destruction, and a high voltage is transferred to the select transistor ST. In particular in a memory cell MC of a selected column and a non-selected row, when the memory cell has a variable magnetoresistive element of a super-low resistance state after completion of writing, a high voltage is applied to the gate insulating film of the select transistor ST. Therefore, the film thickness of the gate insulating film of the transistors PT, NT1, NT2, and ST is made thick enough, and the isolation voltage is guaranteed. Accordingly, the development of dielectric breakdown is prevented at the time of data writing in the OTP mode.

Since a high voltage is not applied to the gate insulating film of the select transistor STM in the MRAM cell MCM in the normal array 2, the gate insulating film is made as thin as possible, making the select transistor STM operate at high speed. In order to thicken the gate insulating film of the select transistor in the PROM/OTP array, a pitch of the select transistors is made larger than a pitch of the select transistors of the MRAM array. Hereafter, arrangement of memory cells in the PROM/OTP array and in the normal MRAM array is explained.

(Configuration of a Normal Array)

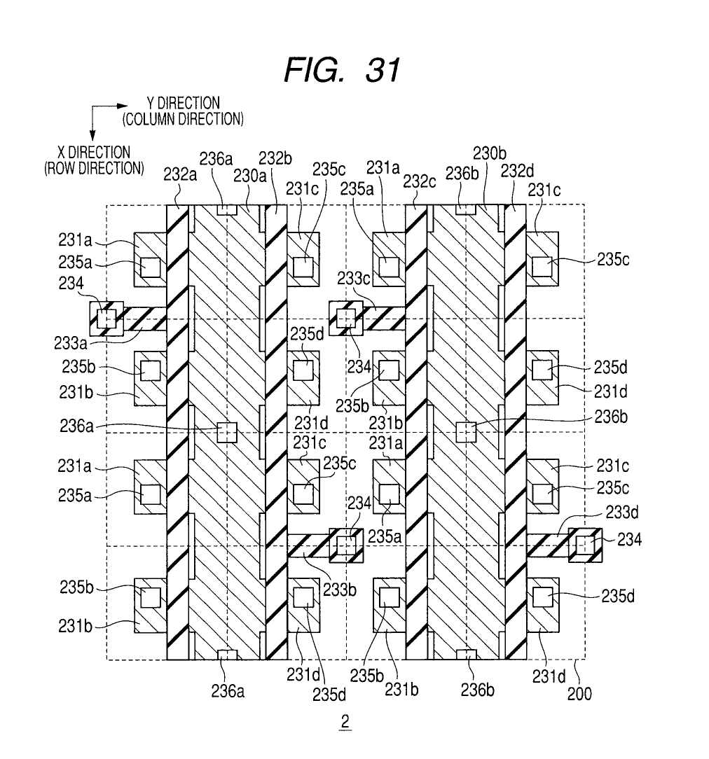

FIG. 31 illustrates roughly a plane layout of a memory cell of the normal array 2. In FIG. 31, a rough plane layout of memory cells arranged at four columns by four rows is illustrated. In FIG. 31, an area of one memory cell is indicated by a rectangular area 200 enclosed by a dashed line. A forming region of one normal memory cell (MRAM cell) is allocated to a block enclosed by a dashed line, namely, a base unit area 200.

In FIG. 31, active areas (impurity regions) 230a and 230b are formed, extending in the direction of X continuously. The active areas 230a and 230b form a source diffusion wiring (impurity region), and are provided common to two columns of memory cells. By the same process as the active areas 230a and 230b, rectangle drain impurity regions 231a, 231b, 231c, and 231d are arranged, shifting from a central position with respect to X direction of the memory cell forming region 200. The drain impurity regions 231a and 231b are arranged in a reflectional symmetry with respect to a boundary region of each base unit area 200 in X direction. Similarly, the drain impurity regions 231c and 231d are also arranged in a reflectional symmetry with respect to a boundary region of the base unit area 200 in X direction. Similarly, with respect to a boundary region of the base unit area 200 in Y direction, the drain impurity regions 231a and 231c are arranged in a reflectional symmetry, and the drain impurity regions 231b and 231d are also arranged in a reflectional symmetry.

A gate word line 232a composed by polysilicon for example is arranged in an area between the source impurity region 230a and the drain impurity regions 231a and 231b, extending continuously in X direction. A gate word line 232b is arranged in an area between the source impurity region 230a and the drain impurity regions 231c and 231d, extending continuously in X direction. Similarly, gate word lines 232c and 232d are provided, extending continuously in X direction in both sides of the source impurity region 230b.

The gate word lines 232a, 232b, 232c, and 232d have respectively projection parts 233a, 233b, 233c, and 233d which extend to a boundary of the base unit area 200 in Y direction, at a predetermined spacing in X direction. The projection parts 233a, 233b, 233c, and 233d are arranged for every four-bit memory cells in X direction, shifted by two-bit memory cells in the adjoining gate word line (for example, gate word lines 232a and 232b) in Y direction.

The projection parts 233a and 233b of the gate word lines 232a and 232b provided to the same source impurity region 230a are arranged in an opposite Y direction with each other, and the projection parts 233c and 233d of the gate word lines 232c and 232d provided to the source impurity region 230b are also arranged in an opposite Y direction with each other. The projection parts 233a and 233c of the gate word lines 232a and 232c of the every other gate word line are provided in the same position in X direction, and the projection parts 233b and 233d are also provided in the same position in X direction. In the adjoining gate word lines, by arranging the projection parts 233b and 233c in a different position in X direction, it is possible to arrange the word line projection parts with an enough margin. A layered word-line structure is realized using the word line projection parts.

Source contacts 236a and 236b are arranged to the source impurity regions 230a and 230b corresponding to the normal cell boundary region. The source contacts 236a and 236b are arranged in X direction for every two-bit normal memory cells as an example, respectively.

Drain contacts 235a, 235b, 235c, and 235d are provided also to the drain impurity regions 231a-231d, respectively. The drain contacts 235a-235d are arranged in a reflectional symmetry with respect to the boundary region of the base unit area 200 in X direction and Y direction. A shunting contact 234 is provided to each of the projection parts 233a-233d. Electrical coupling with upper layer metal wires explained later is formed via the present shunting contact 234. Each of the drain contacts 235a-235d to the drain impurity region is coupled electrically with a variable magnetoresistive element formed in the upper layer via a plug.

By arranging the gate word line projection part 233a-233d in an area where the distance between the drain impurity regions is large, it is possible to arrange the projection parts with a margin. By extending the projection parts 233a-233d up to the boundary region of the base unit area 200 in Y direction, the distance between each of the drain contacts 235a-235d and the shunting contact 234 can be made large. Therefore, even if misalignment or a pattern shift (patterning failure) at the time of patterning of the projection parts occurs, it is possible to avoid defect generation such as overlap of the drain impurity region and the projection part, contact of the projection part and the drain contact, etc. It is also possible to arrange the shunting contact 234 and the drain contacts 235a-235d with a sufficient margin even at the time of memory cell miniaturization.

A word-line shunting area can be provided in the memory cell forming region, accordingly, an area increase of the memory array (normal array) can be suppressed.

The drain contacts 235a-235d are arranged in a reflectional symmetry with respect to the boundary of a memory cell forming region in X direction. Therefore, the distance in X direction between the drain contacts 235b and 235a can be made large in the area corresponding to the forming region of the source contacts 236a and 236b. Accordingly, in the present area, it is possible to arrange a metal source line, extending continuously in Y direction. The width of the metal source line can be made sufficiently large, and the source-line resistor can be reduced fully.

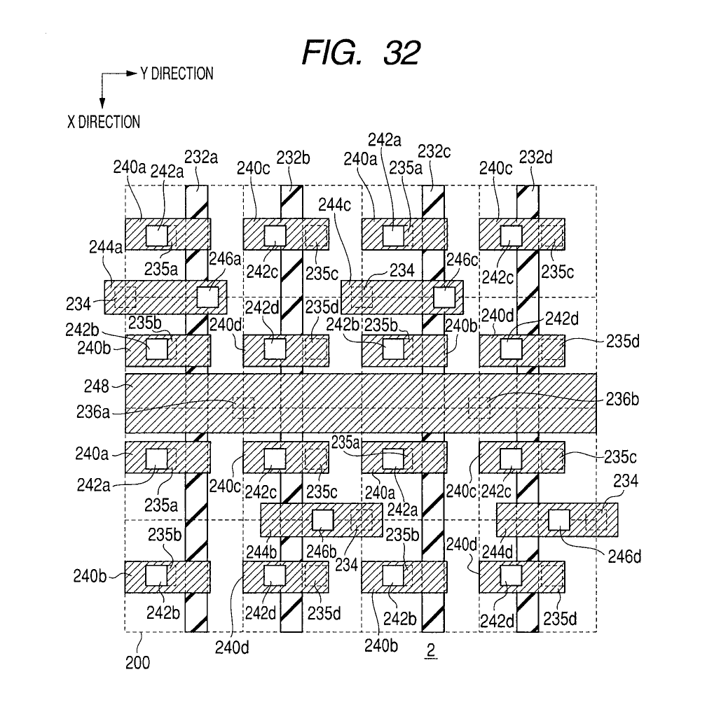

FIG. 32 illustrates roughly a layout of a first metal wiring of the upper layer of the plane layout illustrated in FIG. 31. In FIG. 32, the gate word lines 232a-232d, the drain contacts 235a-235d, and the shunting contact 234 are illustrated in addition.

In FIG. 32, first middle wirings 240a-240d formed by a first metal wiring corresponding to each of the drain contacts 235a-235d are arranged. The first middle wirings 240a and 240b are alternately arranged along X direction, and the first middle wirings 240c and 240d are alternately arranged along X direction. The first middle wirings 240a and 240c are alternately arranged along Y direction, and the first middle wirings 240b and 240d are alternately arranged along Y direction.

The first middle wiring 240a-240d have the shape of a rectangle long in Y direction, and are arranged so as to cross the corresponding gate word lines 232a and 232b from a boundary of the base unit area 200. The first middle wirings 240a-240d form a part of a middle plug for coupling electrically with a variable magnetoresistive element formed in the upper layer. The drain impurity regions 231a-231d (not shown in FIG. 32) of access transistors are electrically coupled to the corresponding upper variable magnetoresistive elements via the drain contacts 235a-235d.

The first middle wirings 240a-240d are arranged repeatedly with the same pattern in X direction and Y direction. Each of the first middle wirings 240a-240d is arranged nearly in a center region of the base unit area 200.

For coupling with an upper-layer wiring, first via holes 242a-242d are provided to the first middle wirings 240a-240d corresponding to the drain contacts 235a-235d, respectively. The first via holes 242a-242d are arranged, nearly in a line in X direction and Y direction. The first via holes 242a and 242b are alternately arranged in X direction, and the first via holes 242c and 242d are alternately arranged in X direction. The first via holes 242a and 242c are alternately arranged in Y direction, and the first via holes 242b and 242d are alternately arranged in Y direction.

First middle wirings 244a and 244c are arranged in a line in Y direction between the first middle wirings 240a and 240b, corresponding to the gate word lines 232a and 232c, respectively. First middle wirings 244b and 244d are arranged in a line in Y direction, corresponding to the gate word lines 232b and 232d and corresponding to the shunting contact 234. The first middle wirings 244a-244d are a middle wiring for realizing word-line shunt structure, and arranged, extending from the corresponding shunting contact 234 to over the corresponding gate word lines 232a-232d. In the adjoining column, a shunting contact 234 is arranged at a pitch of two memory cells, and in the same row, a shunting contact 234 is arranged for a memory cell of every two rows. Therefore, the middle wirings 244a-244d are also arranged with the same pitch as the shunting contact 234.

To the first middle wirings 244a and 244c for shunt, first via holes 246a and 246c are provided in the upper layer of the corresponding gate word lines 232a and 232c. To the first middle wirings 244b and 244d, first via holes 246b and 246d are provided in the upper layer of the corresponding gate word lines 232c and 232d. The first middle wirings 244a-244d for shunt are arranged in a translational symmetry with respect to Y direction.

A metal source line 248 which is formed by a first metal wiring is arranged in the central part corresponding to the source contacts 236a and 236b, and extending continuously in Y direction. The metal source line 248 is electrically coupled to the lower layer source impurity region (not shown in FIG. 32) via the source contacts 236a and 236b.

The first via hole 246a for the word line shunt is arranged in a zigzag pattern with the first via holes 242a and 242b for drain coupling. The first via holes 246b-246d to the first middle wirings 244b-244d for the other word line contacts are arranged also in a zigzag pattern with the first via holes 242a-242d for drain coupling. Accordingly, the distance among the first via holes can be fully secured. Even if the distance between the drain impurity regions is narrow, since the distance between the adjoining drain contacts in X direction, among the drain contacts 235a-235d is large enough, the metal source line 248 can be arranged with sufficient width. Correspondingly, the metal source line 248 with low resistance can be arranged.

By arranging in X direction the drain contacts 235a and 235b positioned in both sides of the source contact 236a, shifted in the direction which separates from the source contact 236a with respect to the center of the drain impurity regions 231a and 231b, it is possible to widen the line width of the metal source line 248 which is formed in the same layer as the first middle wirings 240a and 240b.

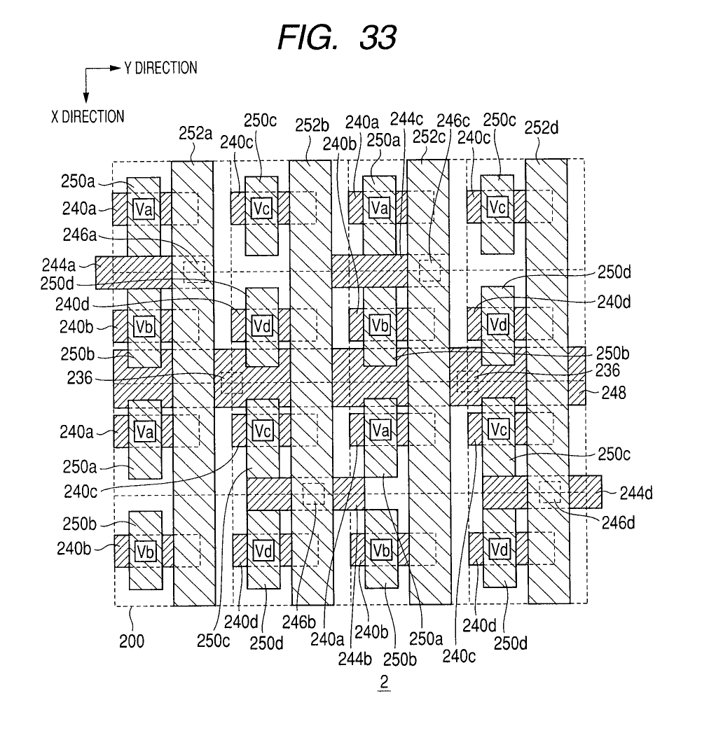

FIG. 33 illustrates a plane layout of a second metal wiring in the upper layer of the plane layout illustrated in FIG. 32 with arrangement of second via holes. In FIG. 33, the arrangement of the first metal wiring in the lower layer is also illustrated in addition.

In FIG. 33, second middle wirings 250a-250d formed by the second metal wiring in the shape of a rectangle long in X direction are arranged so as to intersect each of the first middle wirings 240a-240d, respectively. As to the second middle wirings 250a-250d, the second middle wirings 250a and 250b are arranged alternately in X direction, and the second middle wirings 250c and 250d are arranged alternately in X direction.

Over the first via holes 246a-246d provided corresponding to the first middle wirings 244a-244d for shunt illustrated in FIG. 32, second metal wirings (metal word lines) 252a-252d are arranged, extending continuously in X direction and corresponding to the gate word lines (not shown). The second metal wirings 252a-252d are coupled to the first middle wirings 244a-244d of the lower part via the first via holes 246a-246d, respectively. The first middle wirings 244a-244d are electrically coupled respectively to the corresponding gate word line via the shunting contact 234 illustrated in FIG. 32. Therefore, the second metal wirings 252a-252d are electrically coupled respectively to the gate word line arranged in the lower layer. Accordingly the word-line layered structure in which a word line is formed by a gate word line and a metal word line is realized, and the word line with low resistance is realized.

The second metal wirings 252a-252d are a metal wiring in the upper layer of the first middle wirings 244a-244d. Therefore, even in a case where the first middle wirings 244a-244d for shunt extend to the boundary of the base unit area 200 in Y direction, the first middle wirings 244a-244d for shunt do not have an adverse influence on arrangement of the second metal wirings 252a-252d at all.

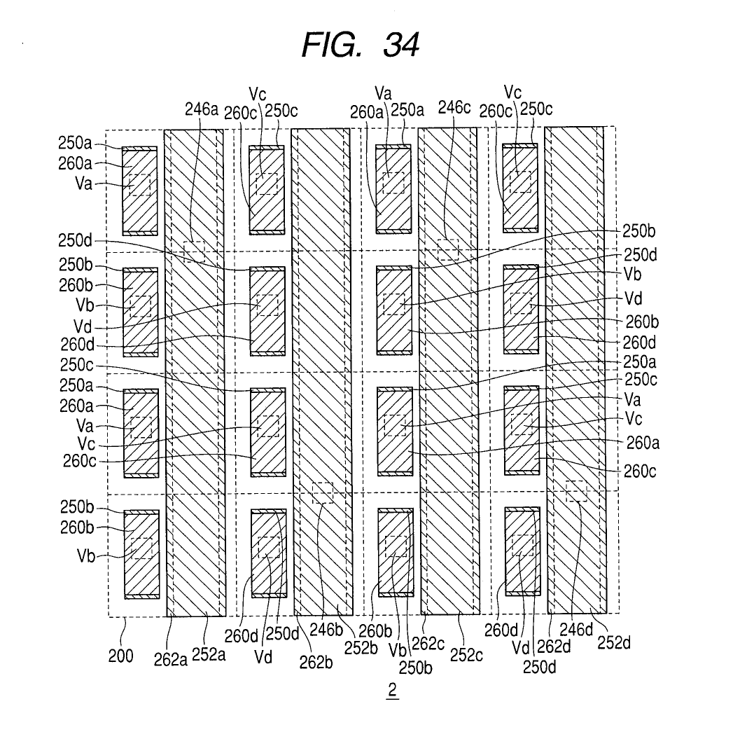

FIG. 34 illustrates roughly a plane layout of a third metal wiring of the upper layer of the plane layout illustrated in FIG. 33. In FIG. 34, the arrangement of the second metal wirings are also illustrated in addition.

In FIG. 34, corresponding to each of the second middle wirings 250a-250d, third middle wirings 260a-260d formed by a third metal wiring are arranged so as to overlap with the corresponding second middle wiring. The third middle wirings 260a-260d are electrically coupled to the corresponding second middle wirings 250a-250d via second via holes Va-Vd, respectively.

Third metal wirings 262a-262d are arranged so as to overlap with the second metal wirings 252a-252d, respectively. The third metal wirings 262a-262d are out of contact with the second metal wiring 252a-252d in the lower layer. The second via holes 246a-246d for word line contact are arranged at the predetermined intervals, respectively. This is for taking an electrical coupling between the second metal wirings 252a-252d and the first middle wirings (250a-250d) in the lower layer.

By arranging the third metal wirings 262a-262d so as to overlap with the second metal wirings 252a-252d, a level difference of arrangement between the variable magnetoresistive element and the write word line (digit line) in the upper layer is made uniform. It is also made possible to form the MRAM cell by the same manufacturing process as the processor (not shown).

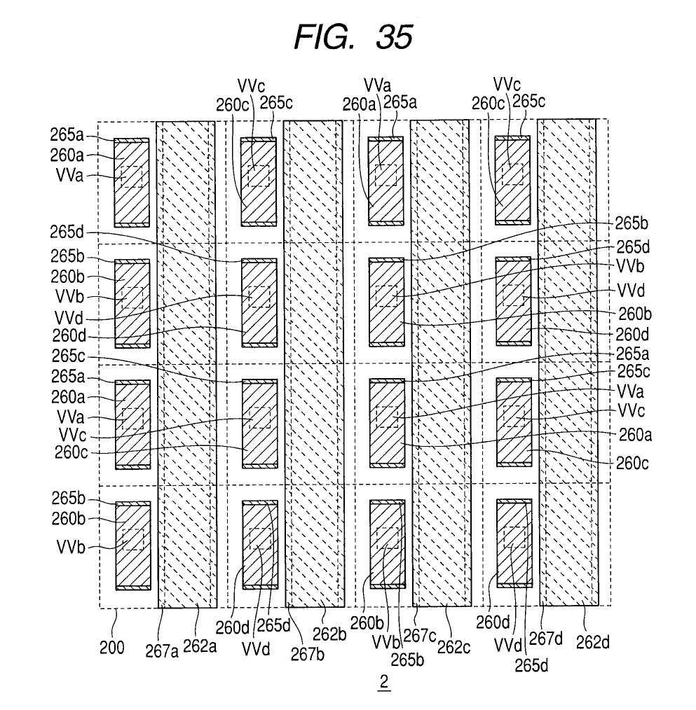

FIG. 35 illustrates roughly a plane layout of a fourth metal wiring of the upper layer of the plane layout illustrated in FIG. 34. In FIG. 35, the arrangement of the third middle wirings 260a-260d and the third metal wirings 262a-262d illustrated in FIG. 34 is illustrated in addition.

In FIG. 35, fourth middle wirings 265a-265d formed by a fourth metal wiring are arranged, so as to overlap respectively with the third middle wirings 260a-260d. The fourth middle wirings 265a-265d are electrically coupled to the third middle wirings 260a-260d via third via holes VVa-VVd, respectively.

On the other hand, fourth metal wirings 267a-267d are arranged so as to overlap with the third metal wirings 262a-262d. The fourth metal wirings 267a-267d form write word lines (digit lines).

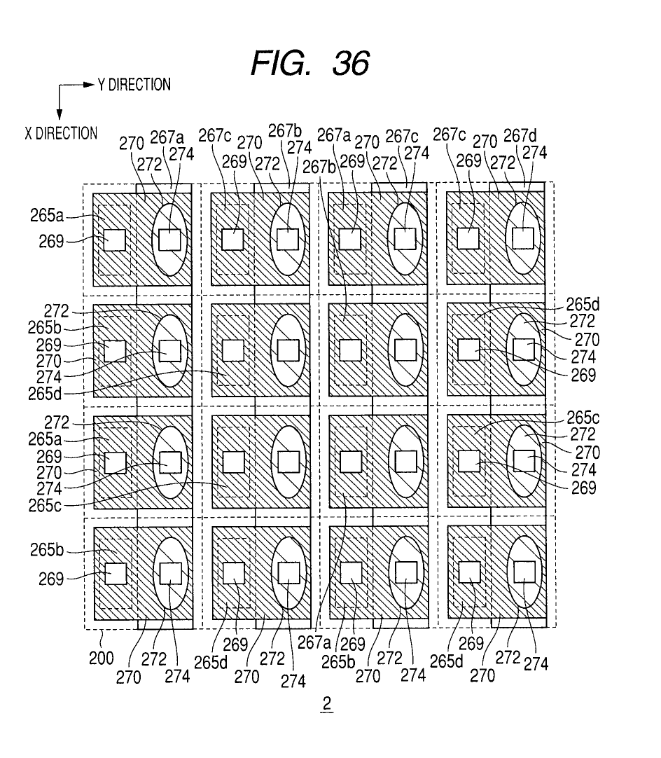

FIG. 36 illustrates roughly a plane layout of variable magnetoresistive elements arranged over the plane layout illustrated in FIG. 35. In FIG. 36, a pattern of identical shape is arranged in each base unit area 200. That is, a third via hole 269 is arranged in the central part of each of the fourth middle wirings 265a-265d. Over the third via hole 269, a local wiring 270 of the shape of a nearly square is arranged. The local wiring 270 is electrically coupled to the fourth middle wirings 265a-265d in the lower layer via the third via hole 269. The arrangement of the local wiring 270 and the third via hole 269 is the same in the base unit area 200 arranged at four columns by four rows as illustrated in FIG. 36, therefore, reference symbols to these components are attached only to the base unit areas arranged in the outer circumference of the four columns by four rows.

A variable magnetoresistive element 272 is arranged in a position over the local wiring 270 and corresponding to each of the fourth metal wirings 267a-267d. The present variable magnetoresistive element 272 has a track-like ellipse shape as an example. The variable magnetoresistive element may be formed in a shape which suppresses occurrence of erroneous writing by suppressing magnetization reversal in the adjacent areas.

An upper electrode 274 is arranged in the central part of the variable magnetoresistive element 272. The upper electrode 274 has in addition a function which forms electrical contact to a bit line arranged in the upper layer.

As illustrated in FIG. 36, the layout of a part relevant to the variable magnetoresistive element has the same pattern arranged repeatedly in X direction and Y direction. Accordingly, the pattern layout of the variable magnetoresistive element is simplified, allowing realization of exact patterning, and suppressing variation in the value of resistance of the variable magnetoresistive element.

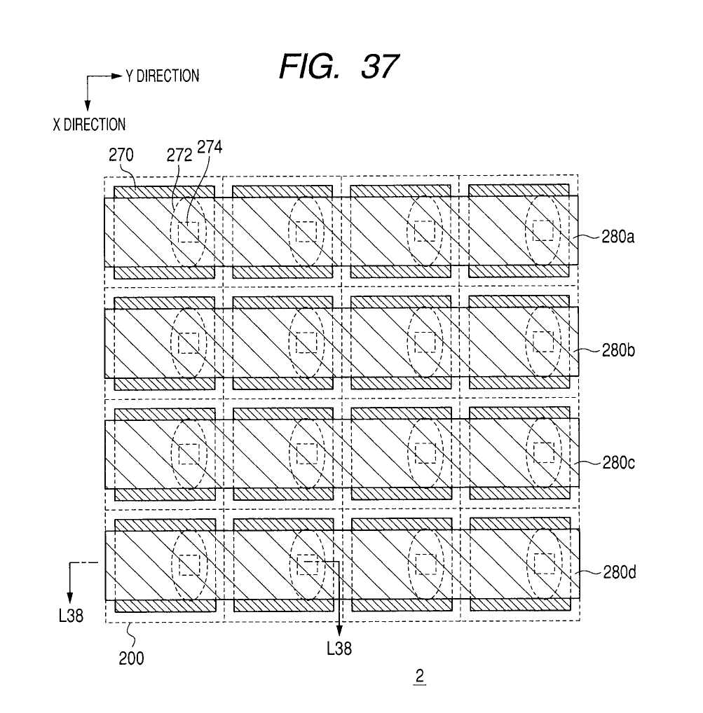

FIG. 37 illustrates roughly a layout of a fifth metal wiring of the upper layer of the plane layout illustrated in FIG. 36. In FIG. 37, reference numbers are attached only to a plane layout of one MRAM cell in referring to the configuration of the MRAM cell. Arrangement of the local wiring 270, the variable magnetoresistive element 272, and the upper electrode 274 in one base unit area 200 is the same in each base unit area 200, and the same pattern is repeatedly arranged to each base unit area 200 in X direction and Y direction.

Fifth metal wirings 280a-280d are arranged at successive intervals, extending continuously in Y direction and corresponding to each memory cell column. The fifth metal wirings 280a-280d respectively form a bit line and are electrically coupled to the upper electrode 274 of the memory cell (variable magnetoresistive element) of the corresponding column. Accordingly, the variable magnetoresistive element 272 is electrically coupled to the corresponding bit line (the fifth metal wirings 280a-280d). According to the present arrangement, a select transistor and a variable magnetoresistive element are arranged in each base unit area 200, and a memory cell is arranged in each base unit area.

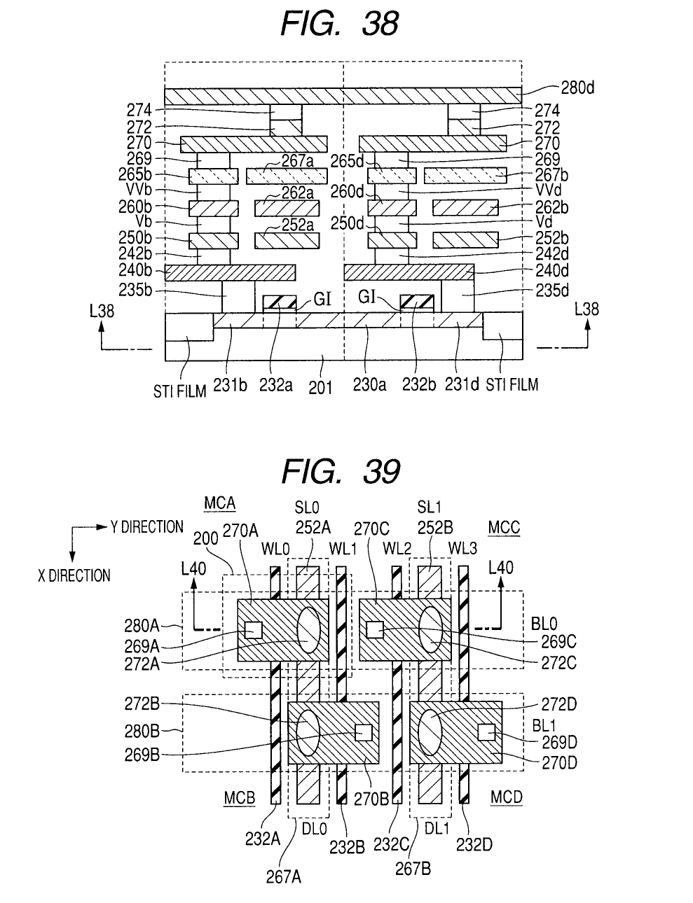

FIG. 38 illustrates roughly a cross-section structure along a line L38-L38 illustrated in FIG. 37. An access transistor is formed over a surface of a semiconductor substrate area 201 in FIG. 38. The drain impurity regions 231b and 231d are arranged over the surface of the semiconductor substrate area 201, opposing to each other on both sides of the source impurity region 230a. An element isolation region STI (STI film) is arranged adjoining to the drain impurity regions 231b and 231d. The present element isolation region STI is formed by the so-called shallow trench isolation film.

The gate word line 232a is formed, through the intermediary of a gate insulating film GI, over a substrate area between the source impurity region 230a and the drain impurity region 231b. The gate word line 232b is formed, through the intermediary of a gate insulating film GI, over a substrate area between the source impurity region 230a and the drain impurity region 231d. The drain contacts 235b and 235d are provided over the drain impurity regions 231b and 231d, respectively. The gate insulating film GI has a film thickness of Tox2, which is made comparatively thin so that high-speed operation may be possible.

Ordinarily, a channel is formed in lower part of the gate word lines 232a and 232b when the access transistor is conducted. Impurity injection is performed in the lower part of the gate word lines 232a and 232b for threshold voltage adjustment etc. In the following explanation, the term an “active area” is used for indicating an area where an impurity is injected, including the source impurity region 230a, the drain impurity regions 231b and 231d, and a channel forming region (the lower part area of the gate word line).

The drain impurity regions 231b and 231d are electrically coupled to the first middle wirings 240b and 240d via the drain contacts 235b and 235d, respectively. The first middle wirings 240b and 240d are electrically coupled to the second middle wirings 250b and 250d via the second via holes 242b and 242d, respectively. The second metal wirings 252a and 252b are arranged, adjoining the second middle wirings 250b and 250d. The second middle wiring 250b and the third middle wiring 260b are arranged in alignment. The fourth middle wiring 265b formed by the fourth metal wiring is arranged in alignment with the third middle wiring 260b. The third middle wiring 260b and the second middle wiring 250b are electrically coupled by the first via hole Vb. The third middle wiring 260b and the fourth middle wiring 265b are electrically coupled by the second via hole VVb.

The third metal wiring 262a and the fourth metal wiring 267a are arranged in alignment over the second metal wiring 252a. The fourth metal wiring 267a forms a digit line (write word line).

Similarly, the third middle wiring 260d and the fourth middle wiring 265d are arranged in alignment over the second middle wiring 250d, and the third metal wiring 262b and the fourth metal wiring 267b are arranged in alignment over the second metal wiring 252b. The second middle wiring 250d and the third middle wiring 260d are electrically coupled each other via the first via hole Vd, and the third middle wiring 260d and the fourth middle wiring 265d are electrically coupled via the second via hole VVd.

The metal wirings 252b, 262b, and 267b are separated each other. The fourth metal wirings 267a and 267b form a digit line, respectively.

By electrically coupling from the first middle wiring formed by the first metal wiring up to the fourth middle wiring formed by the fourth metal wiring with the use of the via holes, it is possible to establish electrical contact surely, even in a case where an aspect ratio of electrical contact/plug to the variable magnetoresistive element formed in the upper layer becomes high.

The third via hole 269 is arranged over each of the fourth middle wirings 265b and 265d. The third via hole 269 is electrically coupled to the corresponding local wiring 270. The variable magnetoresistive element 272 is arranged over the local wiring 270 in alignment with each of the fourth metal wirings 267a and 267b. The variable magnetoresistive element 272 is electrically coupled to the fifth metal wiring 280d in the upper layer via the upper electrode 274. The present fifth metal wiring 280d forms a bit line.

As illustrated in FIG. 31 through FIG. 38, wiring arranged in the upper layer of the access transistor is repeatedly arranged in X direction and Y direction by the same pattern, so that the wiring may have translational symmetry; accordingly, wiring can be arranged in high density.

(a Modified Example of a Plane Layout of an MRAM Cell)

FIG. 39 illustrates roughly a modified example of a layout of the memory cell of the normal memory array. FIG. 39 illustrates typically a layout of four MRAM cells MCA-MCD arranged by two columns by two rows. In FIG. 39, one normal cell (MRAM cell) is arranged in one base unit area 200 indicated by a dashed-line block. In FIG. 39, poly gate lines 232A-232D which form word lines WL0-WL3 are arranged at successive intervals, extending in X direction respectively. A first metal wiring 252A which forms a source line

SL0 is arranged between the poly gate lines 232A and 232B, and a first metal wiring 252B which forms a source line SL1 is arranged between the poly gate lines 232C and 232D which form word lines WL2 and WL3, respectively.

In the memory cell MCA, a local wiring 270A in the shape of a rectangle long in Y direction is arranged over the poly gate line 232A and the first metal wiring 252A. Also in the memory cell MCC, a local wiring 270C is arranged so as to overlap with the poly gate line 232C and the first metal wiring 252B which forms the source line SL1. In the memory cell MCB, a local wiring 270B in the shape of a rectangle is arranged so as to overlap with the first metal wiring 252A which forms the source line SL0, and the poly gate line 232B which forms the word line WL1. In the memory cell MCD, a local wiring 270D in the shape of a rectangle is arranged so as to overlap with the first metal wiring 252B and the poly gate line 232D.

In the local wirings 270A-270D, variable magnetoresistive elements 272A-272D are arranged, so as to respectively overlap with third metal wirings 267A and 267B which form digit lines DL0 and DL1 in the lower layer. The local wirings 270A-270D are coupled to a drain impurity region of each access transistor arranged in the lower layer, with the use of plugs 269A-269D arranged in an opposing position, with respect to the variable magnetoresistive elements 272A -272D and the poly gate line which forms the corresponding word line. A fifth metal wiring 280A is arranged corresponding to the memory cells MCA and MCC, and extending continuously in Y direction. A fifth metal wiring 280B is arranged corresponding to the memory cells MCB and MCD, and extending continuously in Y direction. The fifth metal wirings 280A and 280B form bit lines BL0 and BL1, and are electrically coupled to the corresponding variable magnetoresistive elements via an upper electrode.

In the arrangement of the memory cells illustrated in FIG. 39, a memory cell (a variable magnetoresistive element and a local wiring) is arranged in a reflectional symmetry in X direction, and a variable magnetoresistive element is repeatedly arranged with the same layout in Y direction. In the present case, the source lines SL0 and SL1 are arranged corresponding to each memory cell row, and are not shared by the memory cell of the adjoining row.

Although the variable magnetoresistive elements 272A-272D illustrated in FIG. 39 are formed in the shape of a track, they may be formed in the shape of a crescent moon surrounded with two arcs with different curvature, for example. If the shape of a variable magnetoresistive element can suppress magnetization reversal in its periphery, the shape is arbitrary.

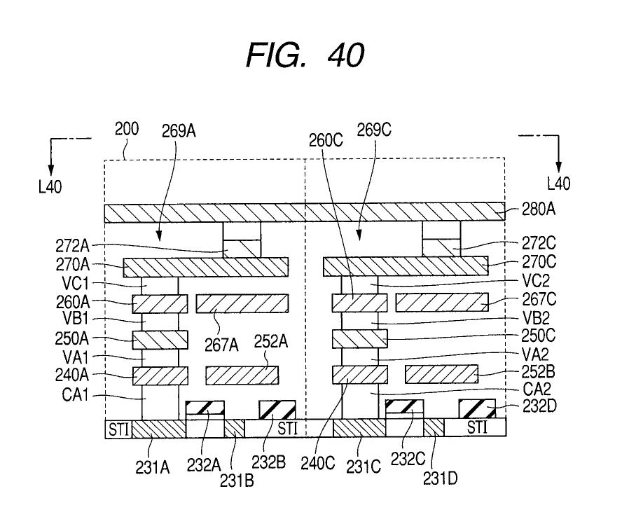

FIG. 40 illustrates roughly a cross-section structure along a line L40-L40 illustrated in FIG. 39. Impurity regions 231A-231D are formed on the surface of a substrate area in FIG. 40. The gate word line 232A is arranged over an area between the impurity regions 231A and 231B, through the intermediary of a gate insulating film (the reference symbol not shown), and the gate word line 232C is arranged over an area between the impurity regions 231C and 231D through the intermediary of a gate insulating film (the reference symbol not shown). An element isolation region STI is arranged between the impurity regions 231B and 231C, and an element isolation region STI is arranged also in areas outside the impurity regions 231A and 231D.

The impurity regions 231A and 231C are electrically coupled to first middle wirings 240A and 240C formed by a first metal wiring via contacts CA1 and CA2, respectively. In the first metal wiring layer, the first metal wiring 252A is arranged over the gate word lines 232A and 232B, and the first metal wiring 252B is arranged over the gate word lines 232C and 232D. The first metal wirings 252A and 252B are electrically coupled to the source impurity regions 231B and 231D, respectively, in a not-shown area, and form the metal source lines SL0 and SL1, respectively.

The first middle wirings 240A and 240C are electrically coupled to second middle wirings 250A and 250C in a second metal wiring layer via first via holes VA1 and VA2, respectively. The second middle wirings 250A and 250C are electrically coupled to third middle wirings 260A and 260C of a third metal wiring layer via second via holes VB1 and VB2, respectively. The third middle wirings 260A and 260C are electrically coupled to the local wirings 270A and 270C via third via holes VC1 and VC2, respectively.

The local wirings 270A and 270C formed by a fourth metal wiring are formed in the shape of a rectangle as shown in FIG. 39. The variable magnetoresistive elements 272A and 272C are disposed over the local wirings 270A and 270C, respectively. The variable magnetoresistive elements 272A and 272C are electrically coupled to the fifth metal wiring 280A that forms the bit line, via an upper electrode. The third metal wirings 267A and 267C are disposed in alignment under the variable magnetoresistive elements 272A and 272C, respectively. The third metal wirings 267A and 267C form a digit line (write word line), respectively.

The plugs 269A and 269B illustrated in FIG. 39 correspond to the wiring structure formed by from the third via hole VC1 to the contact CA1 and the wiring structure formed by from the third via hole VC2 to the contact CA2, respectively.

In the cross-section structure of the memory cell illustrated in FIG. 40, the pillar-shaped plug parts 269A and 269C (formed by middle wirings and contact/via holes) which are electrically coupled to the drain impurity regions 231A and 231C are disposed, respectively, to the local wirings 270A and 270C over which the variable magnetoresistive elements 272A and 272C are arranged. Since the present structure differs from the memory cell structure having a translational symmetry illustrated in FIG. 38, and since the source impurity region does not need to be shared by the adjacent memory cell, the plug part to the local wiring can be arranged with a small layout area. In the structure illustrated in FIG. 40, the word line is formed by the poly gate line alone, and no layered word-line structure is used; accordingly, the number of wiring layers can be reduced by one.

An MRAM cell may be arranged in the normal array 2 using the layout of the MRAM cell illustrated in FIGS. 39 and 40.

(Configuration of a PROM/OTP Array)

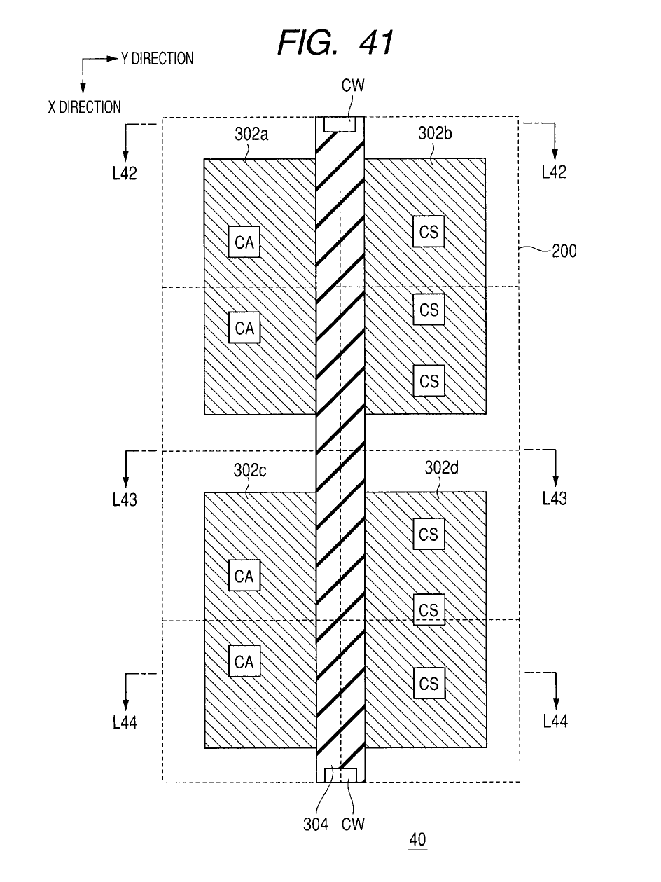

FIG. 41 illustrates roughly a plane layout of the PROM/OTP array 40 according to Embodiment 2 of the present invention. FIG. 41 illustrates a typical arrangement of base unit areas 200 arranged in two columns by four rows. One memory cell is formed in four base unit areas 200. The present base unit area 200 is the same as the forming region of the memory cell (MRAM cell) in the normal array 2 illustrated in FIG. 31 through FIG. 37. Therefore, in the PROM/OTP array, a memory cell and a reference cell are arranged in a twice as many pitch in X direction and Y direction of the normal cell, and cells of the PROM/OTP array are arranged in two columns by one row in FIG. 41.

In FIG. 41, a poly gate line 304 which forms a word line is arranged, extending continuously in X direction along with a memory cell boundary region with respect to Y direction. Impurity regions 302a and 302b are arranged on both sides of the poly gate line 304, each corresponding to two base unit areas 200 in X direction, and impurity regions 302c and 302d are arranged, each corresponding to two base unit areas 200. The impurity regions 302a and 302c which align in X direction are separated with each other, and the impurity regions 302b and 302d are also separated with each other.

The impurity regions 302a and 302c form a drain impurity region, respectively, and a drain contact CA is arranged to each base unit area 200. The impurity regions 302b and 302d form a source impurity region, respectively, and a source contact CS is arranged in each base unit area, at a predetermined spacing. The source contacts CS are arranged in a reflectional symmetry with respect to the line L43-L43 illustrated in FIG. 41, and the drain contacts CA are arranged at a reflectional symmetry with respect to the boundary region of the memory cell forming region in X direction.

To the poly gate line 304, a word line contact CW is arranged in a boundary part of the base unit area 200. The word line contact CW establishes an electrical coupling with a main word line in a upper layer, and realizes a layered word line. The word line contacts CW are arranged at a predetermined interval.

In the configuration illustrated in FIG. 41, one memory cell is formed by four base unit areas 200 which adjoin along X direction and Y direction. The length of the source impurity region and drain impurity region in X direction, namely, the channel width of the select transistor, is made larger than that of a normal cell, allowing a large current to flow; accordingly, the situation where a gate insulating film is destroyed by a high electric field in the drain at the time of writing in the OTP mode is prevented. In this case, according to a scaling rule of an MOS transistor, the film thickness of the gate insulating film under the gate word line 304 is made large.

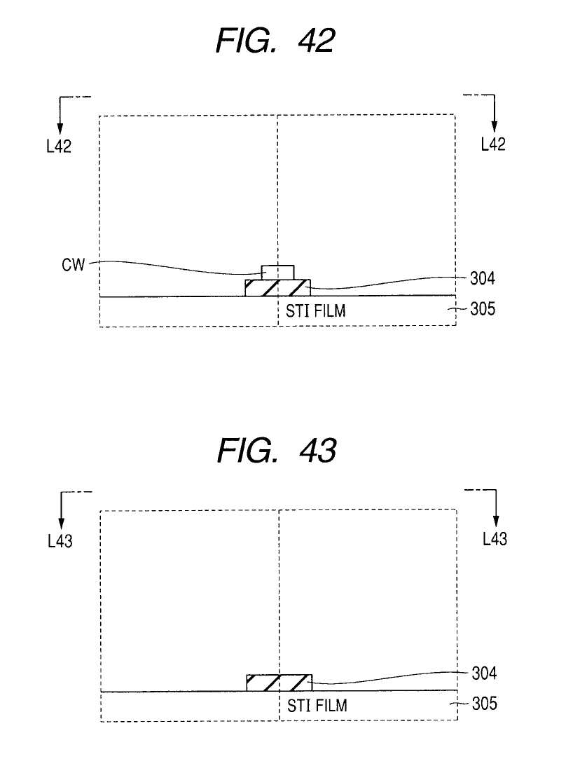

FIG. 42 illustrates roughly a cross-section structure along a line L42-L42 illustrated in FIG. 41. In FIG. 42, since a memory cell column is not formed in the memory cell boundary region, no impurity region is provided. In the area, an element isolation region 305 is arranged in the lower layer all over the substrate area. The element isolation region 305 is formed by an STI (shallow trench isolation) film. The gate word line 304 is formed over the element isolation region 305, and the word line contact CW is arranged so as to contact with the gate word line 304. Also in FIG. 42, a dashed-line block illustrates a base unit area. Also in the following drawings, unless otherwise noted, the dashed-line block in the shape of a rectangle indicates the base unit area 200.

FIG. 43 illustrates roughly a cross-section structure along the line L43-L43 illustrated in FIG. 41. In an area illustrated in FIG. 43, the area is the memory cell boundary region and no impurity region is formed. The poly gate line 304 which forms the word line is simply arranged over the element isolation region (STI film) 305 in the lower layer.

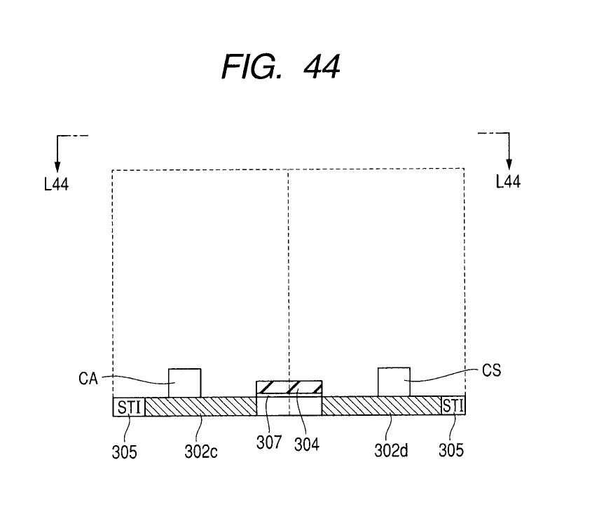

FIG. 44 illustrates roughly a cross-section structure along a line L44-L44 illustrated in FIG. 41. In FIG. 44, the impurity regions 302c and 302d are arranged between the element isolation regions 305 on both sides. The gate word line 304 is formed over the surface of a substrate area between the impurity regions 302c and 302d through the intermediary of a gate insulating film 307. In the impurity regions 302c and 302d, the drain contact CA and the source-line contact CS are arranged, respectively. An area of the lower part of the gate word line is a channel forming region. The gate insulating film 307 has a film thickness Tox1, which is thicker than the film thickness Tox2 of the gate insulating film of the select transistor of the normal cell.

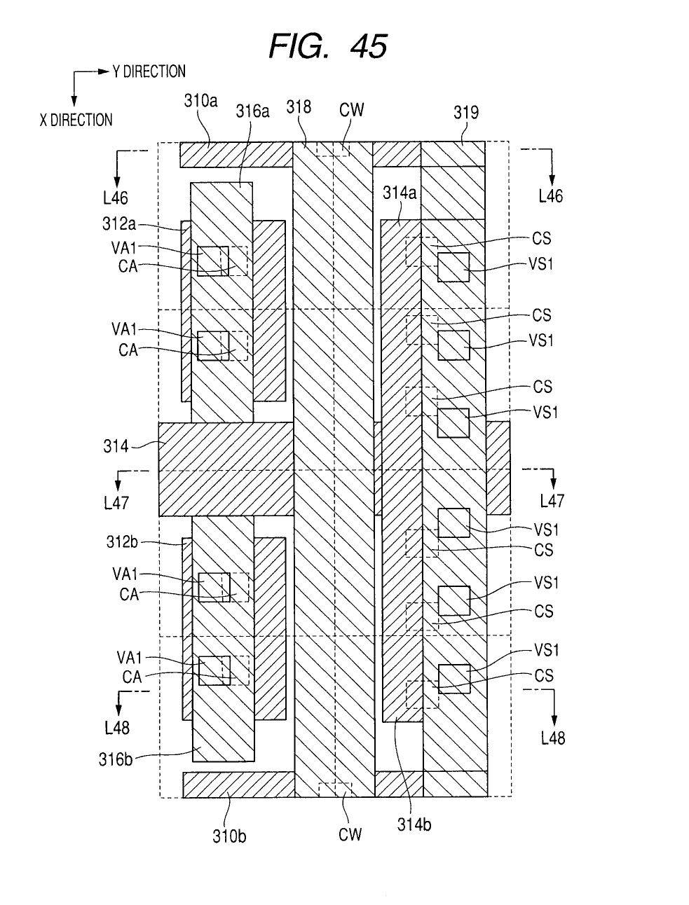

FIG. 45 illustrates roughly a plane layout of a first metal wiring and a second metal wiring in the upper layer of the plane layout illustrated in FIG. 41. In FIG. 45, the drain contact CA, the source-line contact CS, and the word line contact CW which are formed in the lower layer are illustrated in addition.

In FIG. 45, metal wirings 310a and 310b are arranged, extending in Y direction inside the base unit area, and corresponding to the word line contact CW. Corresponding to the drain contact CA, first middle wirings 312a and 312b in the shape of a rectangle formed by a first metal wiring are arranged corresponding to two memory cells which align in X direction. Second middle wirings 316a and 316b formed by a second metal wiring are arranged, corresponding to the first middle wirings 312a and 312b. The second middle wirings 316a and 316b are electrically coupled to the first middle wirings 312a and 312b in the lower layer via a first via hole VA1, respectively. The first middle wirings 312a and 312b are electrically coupled to the corresponding drain impurity regions 302a and 302c via the drain contact CA.

A first layer metal wiring 314 is arranged, extending continuously in Y direction, between the second middle wirings 312a and 312b. The first layer metal wiring 314 includes projection parts 314a and 314b arranged corresponding to an area in which the source-line contact CS is formed, and extending in X direction. The first metal wirings 314, 314a, and 314b are electrically coupled to the source impurity regions 302b and 302d arranged in the lower layer via the source-line contact CS in the lower layer.

A second metal wiring 318 is arranged corresponding to the word line contact CW, and extending continuously in X direction. The second metal wiring 318 is electrically coupled to the gate word line (304) formed in the lower layer, via the word line contact CW. The second metal wiring 318 forms a metal word line. By the second metal wiring 318 and the gate word line 304, a layered word-line structure is realized and resistance reduction of the word line is attained.

A second metal wiring 319 is arranged corresponding to the source-line contact CS, extending continuously in X direction. The second metal wiring 319 is electrically coupled to the first metal wiring 314 in the lower layer via a first via hole VS1. The second metal wiring 319 forms a metal source line. The source line is disposed in the shape of a mesh using the first metal wiring 314 and the second metal wiring 319, accordingly, reduction of resistance of the source line and stabilization of the source line voltage are attained.

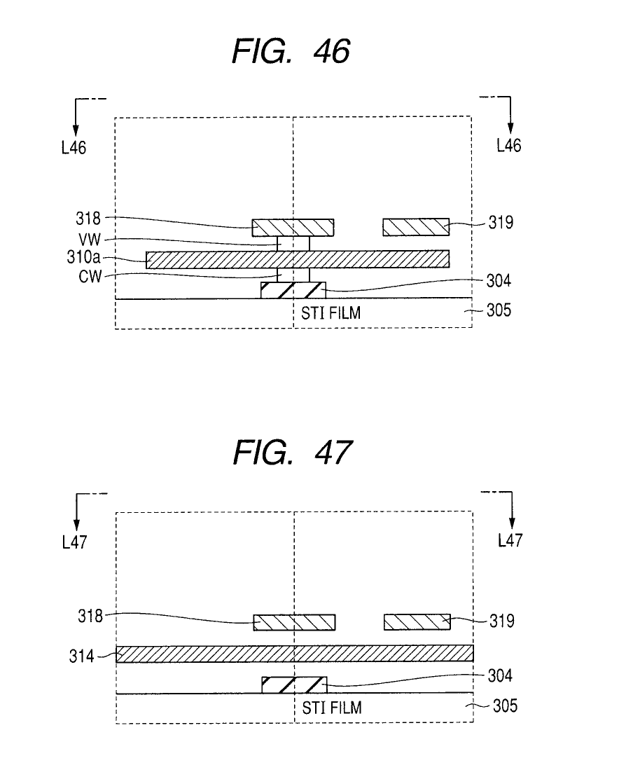

FIG. 46 illustrates roughly a cross-section structure along a line L46-L46 illustrated in FIG. 45. In the cross-section structure illustrated in FIG. 46, the first metal wiring and the second metal wiring are arranged further in addition to the cross-section structure illustrated in FIG. 42. Therefore, in FIG. 46, the same reference number is attached to a part corresponding to the part illustrated in FIG. 42, and the detailed explanation thereof is omitted.

In FIG. 46, the first middle wiring 310a formed by the first metal wiring is arranged in the base unit area, and is electrically coupled to the gate word line 304 via the word line contact CW. The first middle wiring 310a is electrically coupled to the second metal wiring 318 via a word-line via hole VW. The second metal wiring 319 is arranged in the same wiring layer as the second metal wiring 318, and in parallel with the second metal wiring 318. The second metal wiring 319 forms the source line, and is separated electrically from the first middle wiring 310a.

FIG. 47 illustrates roughly a cross-section structure along a line L47-L47 illustrated in FIG. 45. The cross-section structure in FIG. 47 illustrates the arrangement of wiring in the upper layer of the cross-section structure illustrated in FIG. 43. Therefore, in FIG. 47, the same reference number is attached to a part corresponding to the part illustrated in FIG. 43, and the detailed explanation thereof is omitted.

In FIG. 47, the first metal wiring 314 is disposed in the direction which intersects the gate word line 304. Over the first metal wiring 314, the second metal wiring 319 is arranged so as to intersect the first metal wiring 314. The first metal wiring 314 and the second metal wiring 319 are electrically coupled by the source-line via hole VS1, in another area as illustrated in FIG. 45.

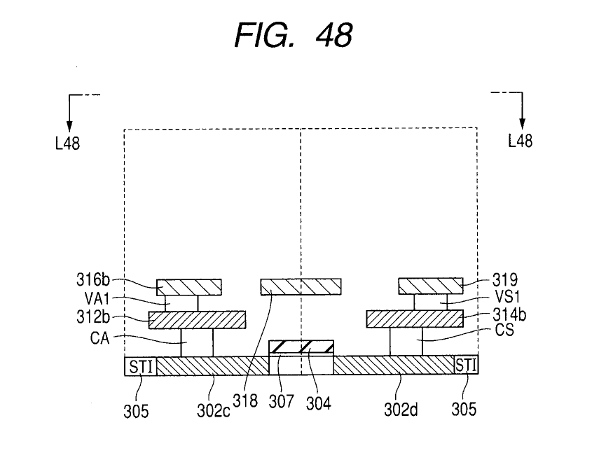

FIG. 48 illustrates roughly a cross-section structure along a line L48-L48 illustrated in FIG. 45. The cross-section structure in FIG. 48 illustrates the arrangement of wiring in the upper layer of the cross-section structure illustrated in FIG. 44. Therefore, in FIG. 48, the same reference number is attached to a part corresponding to the part illustrated in FIG. 44, and the detailed explanation thereof is omitted.

In the configuration illustrated in FIG. 48, the first middle wiring 312b formed by the first metal wiring is electrically coupled to the drain impurity region 302c, via the contact CA. The first middle wiring 312b is electrically coupled to the second middle wiring 316b formed by the second metal wiring, via the first via hole VA1. The second metal wiring 318 is arranged in alignment with the gate word line 304. On the other hand, the projection part 314b of the first metal wiring 314 is electrically coupled to the source-line contact CS, and the source impurity region 302d and the first metal wiring 314 (314b) are electrically coupled. The present projection part 314b of the source metal wiring 314 is further electrically coupled to the second metal wiring 319 via the source-line via hole VS1. Accordingly, the layered structure of the first metal wiring 314 (314b) and the second metal wiring 319 of the source line is realized, allowing reduction of the value of resistance of the source line.

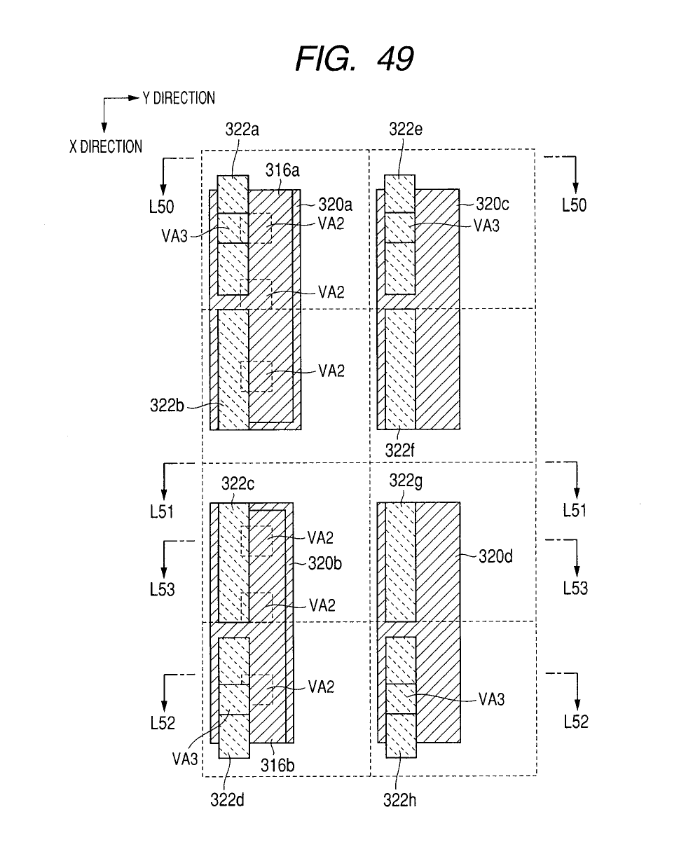

FIG. 49 illustrates roughly a layout of a third metal wiring and a fourth metal wiring in the upper layer of the wiring layout illustrated in FIG. 45. In FIG. 49, third middle wirings 320a and 320b which are respectively formed by a third metal wiring are arranged, corresponding to the second metal middle wirings 316a and 316b. The second metal middle wirings 316a and 316b are electrically coupled to the third metal middle wirings 320a and 320b via a second via hole VA2, respectively. In an upper part of the area where the second metal wiring forming the source line is arranged, third middle wirings 320c and 320d in the shape of a rectangle which is formed by the third metal wiring are similarly arranged with an interval therebetween in X direction. The third metal middle wirings 320c and 320d are separated from the lower layer wiring.

Over the third metal middle wiring 320a, fourth middle wirings 322a and 322b in the shape of a rectangle which is formed by the fourth metal wiring are arranged with an interval therebetween in X direction. Similarly, over the third metal wiring 320b, fourth middle wirings 322c and 322d in the shape of a rectangle which are formed by the fourth metal wiring are arranged with an interval therebetween in X direction.

Similarly, corresponding to the third metal middle wiring 320c, fourth middle wirings 322e and 322f which are formed by the fourth metal wiring are arranged with an interval therebetween in X direction. Corresponding to the third metal middle wiring 320d, fourth middle wirings 322g and 322h which are formed by the fourth metal wiring are arranged with an interval therebetween in X direction.

The fourth middle wiring 322a is electrically coupled to the third metal wiring 320a via a third via hole VA3. The fourth middle wiring 322b is separated electrically from the third middle wiring 320a. Similarly, the fourth middle wiring 322d is electrically coupled to the third metal middle wiring 320b via the third via hole VA3. On the other hand, the fourth middle wiring 322c is separated from the fourth middle wiring 320b which is formed by the fourth metal wiring.

The fourth middle wiring 322e is electrically coupled to the third metal middle wiring 320c via the third via hole VA3, and the fourth middle wiring 322h is electrically coupled to the third metal wiring 320d via the third via hole VA3. The fourth middle wirings 322f and 322g are electrically separated from the third metal middle wirings 320c and 320d, respectively. Therefore, in the region of four normal cells, one of the fourth metal middle wirings is electrically coupled to the third metal middle wiring in the lower layer. Accordingly, one of the fourth metal middle wirings is electrically coupled to the drain impurity region in the lower layer.

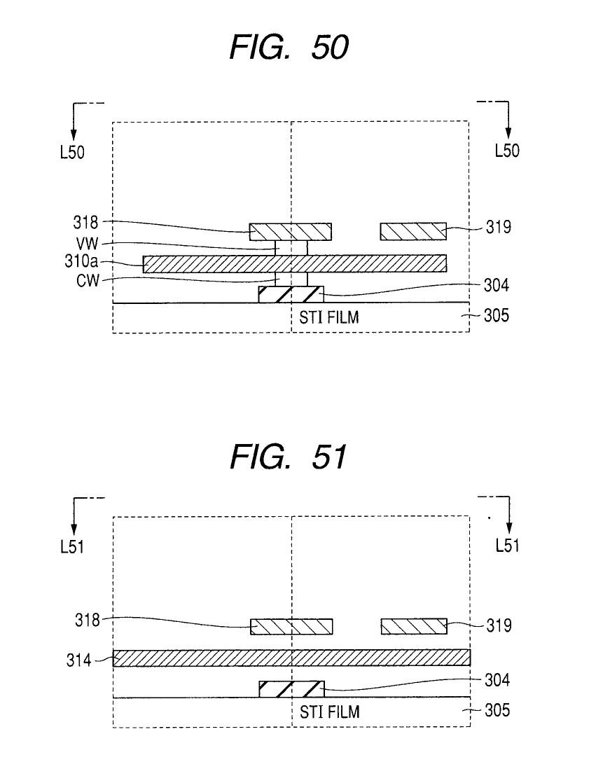

FIG. 50 illustrates roughly a cross-section structure along a line L50-L50 illustrated in FIG. 49. In a boundary region of the memory cell in X direction, an impurity region is not formed and the third and the fourth metal wiring (middle wiring) for coupling with the upper-layer wiring are not arranged. Accordingly, the cross-section structure of the present part is the same as the cross-section structure illustrated in FIG. 46. Therefore, in FIG. 50, the same reference number is attached to a part corresponding to the component illustrated in FIG. 46, and the detailed explanation thereof is omitted.

FIG. 51 illustrates roughly a cross-section structure along a line L51-L51 illustrated in FIG. 49. The present area is also a memory cell boundary region, accordingly, an impurity region is not formed and the third and the fourth metal wiring are not arranged. Accordingly, the cross-section structure illustrated in FIG. 51 is the same as the cross-section structure illustrated in FIG. 47. Therefore, in FIG. 51, the same reference number is attached to a part corresponding to the component illustrated in FIG. 47, and the detailed explanation thereof is omitted.

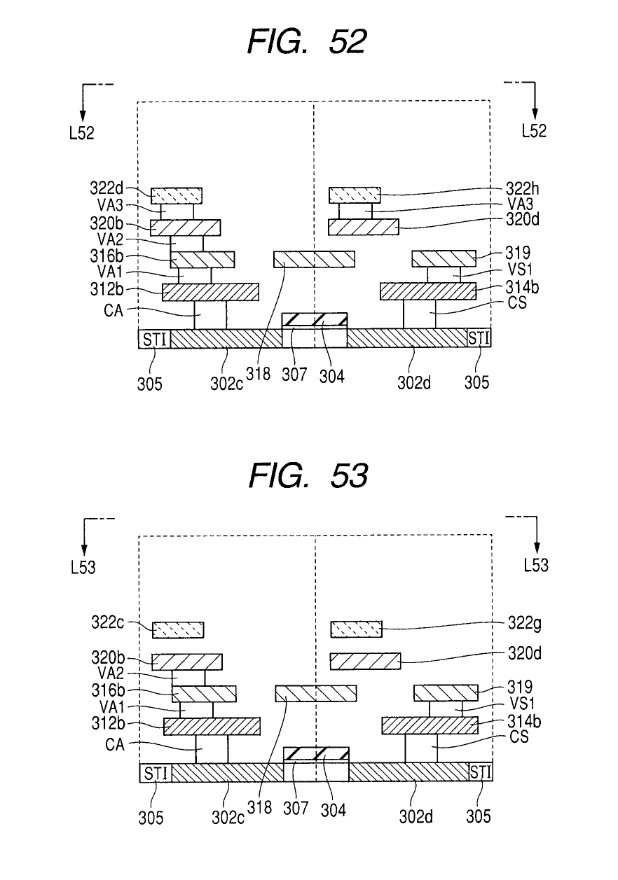

FIG. 52 illustrates roughly a cross-section structure along a line L52-L52 illustrated in FIG. 49. The cross-section structure illustrated in FIG. 52 includes the arrangement of wiring in the upper layer of the cross-section structure illustrated in FIG. 48. Therefore, in the components illustrated in FIG. 52, the same reference number is attached to a part corresponding to the component illustrated in FIG. 48, and the detailed explanation thereof is omitted.

In FIG. 52, the second metal middle wiring 316b is electrically coupled, via the second via hole VA2, to the second middle wiring 320b which is formed by the second metal wiring of the upper layer. The second middle wiring 320b is electrically coupled, via the third via hole VA3, to the third middle wiring 322d which is formed by the third metal wiring.

In the upper layer of the second metal wirings 318 and 319, the third middle wiring 320d which is formed by the third metal wiring is arranged so as to partially overlap with the second metal wiring 318. The third middle wiring 320d is separated from the lower layer wiring. The third middle wiring 320d is electrically coupled, via the third via hole VA3, to the fourth middle wiring 322h which is formed by the fourth metal wiring.

FIG. 53 illustrates roughly a cross-section structure along a line L53-L53 illustrated in FIG. 49. In FIG. 53, the arrangement of a part formed by the first metal wiring through the third metal wiring is the same as the arrangement of the cross-section structure illustrated in FIG. 52, therefore the same reference number is attached to the corresponding part, and the detailed explanation thereof is omitted.

In FIG. 53, the third middle wiring 322c which is formed by the third metal wiring is disposed in the upper layer of the second middle wiring 320b which is formed by the second metal wiring. To the third middle wiring 322c, the third via hole is not provided and the middle wirings 322b and 322c are separated.

Similarly, the third via hole is not provided between the third middle wiring 320d which is formed by the third metal wiring and the fourth middle wiring 322g which is formed by the fourth metal wiring. Therefore, the fourth middle wiring 322g is electrically separated from the third middle wiring 322d.

As illustrated in FIG. 49 and FIG. 53, the third metal wiring and the fourth metal wiring are also arranged in reflectional symmetry with respect to the memory cell boundary region in X direction, and the via holes are similarly arranged in reflectional symmetry with respect to the memory cell boundary region in X direction. In this case, when a variable magnetoresistive element is arranged, to the unit area (base unit area) indicated by the dashed-line block, as well as the normal MRAM cell array, the third middle wiring and the fourth middle wiring are electrically coupled only in one area among the four unit areas (base unit area), the number of select transistors is reduced to one-fourth the number of select transistors in the normal MRAM cell array in the PROM/OTP array, and the size of the select transistor is enlarged sufficiently. The second via hole VA2 and the third via hole VA3 are arranged respectively so that their numbers may become the same to each impurity region, and the translational symmetry in the arrangement of wiring is maintained.

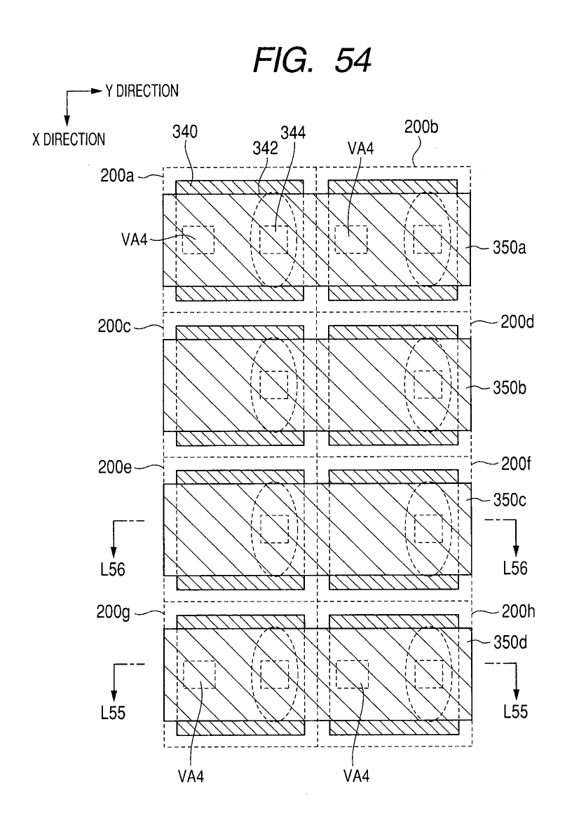

FIG. 54 illustrates roughly a layout of variable magnetoresistive elements arranged in the upper layer of the plane layout illustrated in FIG. 49. In FIG. 54, local wiring 340 is provided in each of base unit areas (unit areas) 200a-200h. In FIG. 54, in order to simplify the drawing, a reference number is attached only to a variable magnetoresistive element arranged to the area 200a. The configuration of the variable magnetoresistive element is the same in all the base unit areas 200a-200h.

A variable magnetoresistive element 342 is arranged on one side of the local wiring 340. The configuration of the variable magnetoresistive element 342 is the same as the structure of an MRAM cell (normal cell). An upper electrode 344 is provided over the variable magnetoresistive element 342. Corresponding to each column of the variable magnetoresistive elements (340, 342, 344), fifth metal wirings 350a-350d are arranged respectively, extending continuously in Y direction. The fifth metal wirings 350a-350d form bit lines, respectively.

In the present configuration, the upper electrode 344 of the variable magnetoresistive element is coupled to the corresponding one of the fifth metal wirings 350a-350d. However, as for the local wiring 340, a fourth via hole VA4 is provided in each of the unit areas (base unit areas) 200a, 200b, 200g, and 200h, and the local wiring 340 is electrically coupled to the fourth middle wiring (322a, 322e, 322d, 322h) which is formed by the fourth metal wiring in the lower layer. On the other hand, as for the local wiring 340 in each of the base unit areas 200c-200f, no fourth via hole VA4 is provided; accordingly, the local wiring 340 concerned is separated from the lower layer wiring.

By arranging a variable magnetoresistive element in each of the base unit areas, it is possible to maintain the regularity of a pattern of the variable magnetoresistive element, and it is possible to arrange in the PROM/OTP array a variable magnetoresistive element of the same characteristic as the characteristic of a variable magnetoresistive element of the normal cell array.

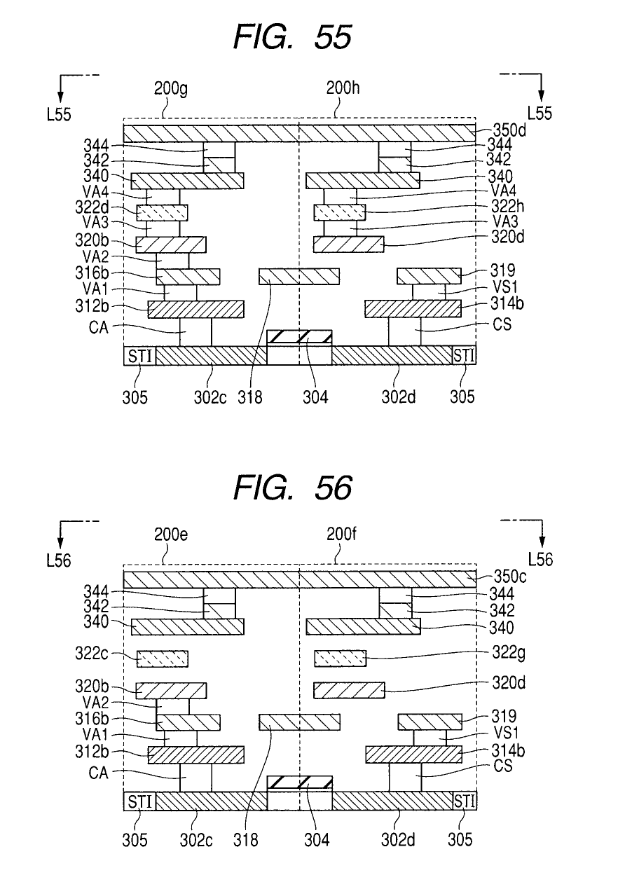

FIG. 55 illustrates roughly a cross-section structure along a line L55-L55 illustrated in FIG. 54. The cross-section structure illustrated in FIG. 55 includes the cross-section structure illustrated in FIG. 52 and the configuration of arrangement of the variable magnetoresistive elements in the upper layer thereof. Therefore, in the parts illustrated in FIG. 55, the same reference number is attached to a part corresponding to the configuration illustrated in FIG. 52, and the detailed explanation thereof is omitted.

In the base unit area 200g with reference to FIG. 55, the fourth middle wiring 322d is electrically coupled to the local wiring 340 via the fourth via hole VA4. Similarly, in the base unit area 200h, the fourth middle wiring 322h is electrically coupled to the local wiring 340 via the fourth via hole VA4. In any of the base unit areas 200g and 200h, the variable magnetoresistive element 342 mounted over the local wiring 340 is electrically coupled to the bit line formed by the fifth metal wiring 350d via the upper electrode 344.

In the case of the configuration illustrated in FIG. 55, in the base unit area 200g, a path from the fifth metal wiring 350d to the impurity region 302c is electrically coupled through the aid of the variable magnetoresistive element 342 and a plug which is formed by the middle wirings and the via holes. On the other hand, in the base unit area 200h, the fifth metal wiring 350d is electrically coupled only up to the third middle wiring 320d which is formed by the third metal wiring, via the variable magnetoresistive element 342, and is not coupled to the select transistor. Therefore, the configuration in which one select transistor is arranged in two forming regions of the variable magnetoresistive element (two base unit areas) in Y direction becomes realizable. Accordingly, it is possible to enlarge the size of the select transistor sufficiently.

FIG. 56 illustrates roughly a cross-section structure along a line L56-L56 illustrated in FIG. 54. The cross-section structure illustrated in FIG. 56 includes the cross-section structure illustrated in FIG. 53, and in addition, includes arrangement of variable magnetoresistive elements in the upper part thereof. Therefore, in the parts illustrated in FIG. 56, the same reference number is attached to a part corresponding to the component illustrated in FIG. 53, and the detailed explanation thereof is omitted.

In the configuration illustrated in FIG. 56, in each of the base unit areas 200e and 200f, the variable magnetoresistive element 342 is electrically coupled to the fifth metal wiring 350c via the upper electrode 344, and coupled to the local wiring 340 via a lower electrode (not shown). However, as for the fourth middle wirings 322c and 322g, neither third via hole nor fourth via hole are provided in the upper part and the lower part thereof; therefore, the variable magnetoresistive element 342 of the base unit areas 200e and 200f is electrically separated from the select transistor.

Therefore, also in the present part, one variable magnetoresistive element out of the total four variable magnetoresistive elements 342 which adjoin each other in X direction and Y direction is coupled to one select transistor. The source impurity region and the drain region of one select transistor are an area corresponding to the arrangement area (base unit area 200) of two variable magnetoresistive elements in X direction. Accordingly, it is possible to enlarge the size of the select transistor sufficiently.

In the present configuration, the variable magnetoresistive element 342 is arranged in the same pitch as the pitch of the variable magnetoresistive element of the normal MRAM cell array, and the size is also the same. Therefore, variation in the characteristic of a variable magnetoresistive element can be suppressed, a variable magnetoresistive element having the same characteristic as the variable magnetoresistive element of the MRAM cell array can be arranged in the PROM/OTP array; accordingly, exact program can be realized.

The layout illustrated in FIG. 54 is repeatedly arranged along X direction and Y direction. In a memory cell of the adjoining column, a variable magnetoresistive element at a position in reflectional symmetry with respect to a cell boundary is coupled to the corresponding bit line. In the configuration illustrated in FIG. 54, only the fifth metal wirings 350a and 350d are utilized as the bit line, and the bit line is thinned out at a ratio of 2:1, as will be described in the following.

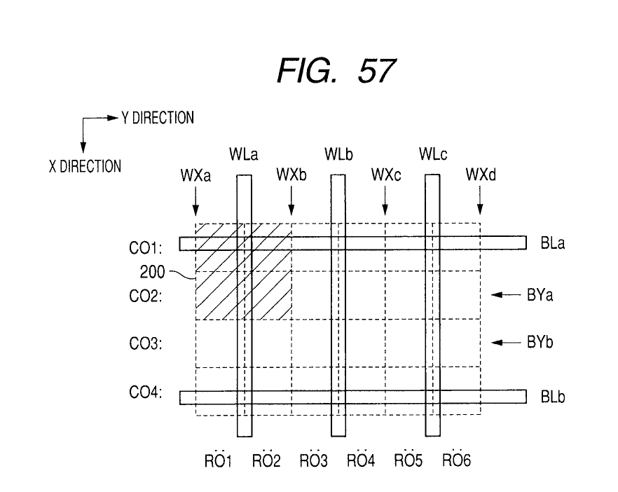

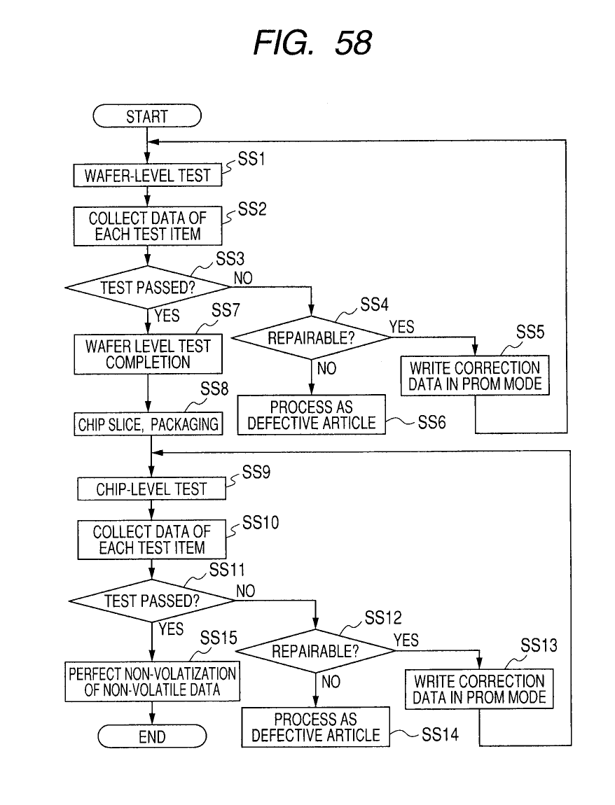

FIG. 57 illustrates roughly arrangement of a word line and a bit line of the PROM/OTP array according to Embodiment 2 of the present invention. In FIG. 57, an example is considered for a case where a base unit area 200 is arranged in four columns (columns CO1-C04) by six rows (rows RO1-RO6). In four base unit areas 200 arranged in two columns by two rows, one select transistor is arranged, one variable magnetoresistive element is coupled to the corresponding bit line and the corresponding select transistor, accordingly, one memory cell is arranged. In the present case, one word line is arranged in a boundary region of two rows of base unit areas. That is, word lines WLa-WLc (the gate word line 304 and the second metal wiring 318) are arranged, respectively to a region between rows RO1 and RO2, a region between rows RO3 and RO4, and a region between rows RO5 and RO6.

In a normal MRAM cell array, a word line is arranged corresponding to each of the base unit area rows RO1-RO6. Therefore, the PROM/OTP array has equivalently the configuration in which the word lines WXa-WXd are thinned out in comparison to the arrangement of the normal cell array. That is, since one word line is arranged every two rows, the number of word lines becomes one half, compared with the word line arrangement of the normal MRAM cell array.

On the other hand, in the columns CO0-CO4 of the base unit area 200, one bit line is arranged every two base unit areas in X direction. That is, in FIG. 57, base unit areas arranged in columns CO1 and CO4 are coupled to bit lines BLa and BLd in every two base unit areas. In the present case, no coupling to the corresponding bit line is provided in the columns CO2 and CO3 therebetween (coupling between a select transistor and a corresponding bit line is cut off). Therefore, in the normal MRAM cell array, a bit line is arranged for every base unit area column, however, in the PROM/OTP array, bit lines BYa and BYb are thinned out equivalently. Therefore, the number of bit lines in the PROM/OTP array also becomes one half, compared with the number of bit lines in the normal MRAM cell array. In the PROM/OTP array, a memory cell is arranged in a pitch of two base unit areas, and the pitch is enlarged compared with the pitch of a memory cell in the normal cell array (MRAM array).

Therefore, one memory cell (reference cell) is arranged at four base unit areas 200 shaded with oblique lines in FIG. 57. In the PROM/OTP array, by setting the number of select transistors to one half in the column direction and to one half in the row direction, compared with the number of base unit areas, it is possible to enlarge the channel width of a select transistor, and it is possible to arrange a select transistor which has sufficient gate insulating film thickness and sufficient channel width.

As described above, according to Embodiment 2 of the present invention, word lines and bit lines are thinned out in arrangement of the normal cell array, and the layout area of a select transistor is increased. Accordingly, it is possible to arrange a select transistor which has a sufficient gate insulating film thickness and a sufficient current drive power. Furthermore, even if destructive writing with a high voltage is performed at the time of writing in the OTP mode, it is possible to guarantee a sufficiently high withstand voltage of the select transistor, and it is possible to perform accurate and stable data writing in the OTP mode.

### Embodiment 3

FIG. 58 is a flow chart illustrating operation of a semiconductor device according to Embodiment 3 of the present invention. Hereafter, with reference to FIG. 58, operation of the semiconductor device according to Embodiment 3 of the present invention is explained.

After completion of manufacturing process of a semiconductor integrated circuit device, a wafer-level test is conducted (Step SS1). In the wafer-level test, a pad over a chip is exposed, and various characteristic tests are conducted by contacting a test probe to the pad. Detection of a bad cell of a memory cell, etc. are also performed by applying test data. In the first test, a test is carried out according to a default value of operating environment setup data.

In the test, test result data about each test item is collected (Step SS2). After the completion of the wafer-level test, it is determined whether a semiconductor device under test is a nondefective article which satisfies specification values etc., according to the test result data of each test item (Step SS3). Subsequently, at Step SS3, when it is determined that the semiconductor device is defective, it is determined whether the defect is repairable or not (Step SS3, Step SS4). For example, when a bad memory cell exists and the bad memory cell is not repaired by redundancy substitution by a spare cell, or when an electrical property is largely shifted from a correctable range to the specification values, it is determined that the bad memory cell is unrepairable. In the present case, the semiconductor device is processed as a defective article (Step SS6).

Even if it is determined to be repairable, when correction has been made a prescribed number of times until then, the semiconductor device may be determined to be unrepairable and may be processed as a defective article.

At Step SS4, when it is determined to be repairable, correction data is generated in an external tester etc., based on analysis of the test result data, and the correction data (defect repair/trimming data) will be written in the PROM/OTP array 40 in the PROM mode (Step SS5).

Flow returns to Step SS1 again. According to the correction data, a test of an electrical property etc. is carried out (after reading the correction data in the PROM read mode and setting up the internal state). Subsequently, the present operation is executed for the necessary number of times.

At Step SS3, when it is determined to be nondefective, the wafer-level test is completed (Step SS7).

When the wafer-level test is completed, processing proceeds to a slicing process, and a wafer undergoes dicing and is divided into chips. A nondefective chip is sorted out among the chips, and the nondefective chip is encapsulated into a package (Step SS8). To a semiconductor device after packaging, test data and voltage can be applied only via a pin terminal from the exterior.

To a chip or a semiconductor device after packaging, a final test (chip-level test) before product shipment is carried out (Step SS9). At the time of the chip-level test, data based on the result of the wafer-level test is stored in a PROM/OTP array as a default value. After the internal state (operating environment) is set up based on the stored data, the chip-level test is carried out (internal read of the stored data and storing into a fuse register).

In the chip-level test, the contents of the test differs from the item of the wafer-level test, due to a limitation that voltage/data is applied from a pin terminal. However, also in the chip-level test, a test item specified by the same operation is executed, and the test-result data is collected (Step SS10).

According to the collected test-result data, it is determined whether it is a nondefective article, as in the wafer-level test (Step SS11). Subsequently, when it is defective, it is determined whether the detected defect is repairable (Step SS12). When it is determined to be unrepairable based on the degree of the defect, the number of times of tests, etc., the semiconductor device is processed as a defective article (Step SS14).

On the other hand, when it is determined to be repairable at Step SS12, defect repairing/trimming data are written in the PROM/OTP array in the PROM mode, according to the test-result data (Step SS13). Flow returns to Step SS9 again, and the chip-level test is executed according to the correction data.

When it is determined to be nondefective at Step SS11, the correction data (PROM correction nonvolatile data) stored in the PROM/OTP array are converted into perfect nonvolatile data (OTP data) (Step SS15). In the perfect non-volatization of the nonvolatile data, data written in the PROM/OTP array in the PROM mode is read internally, and is stored again in the OTP mode. When the perfect non-volatization (writing in the OTP mode) of the internal state setup data (operating environment setup data) is completed, the chip-level test process is completed.

Then, the semiconductor device as a nondefective article is transported to a shipment process which performs a process necessary for shipment, and is shipped.

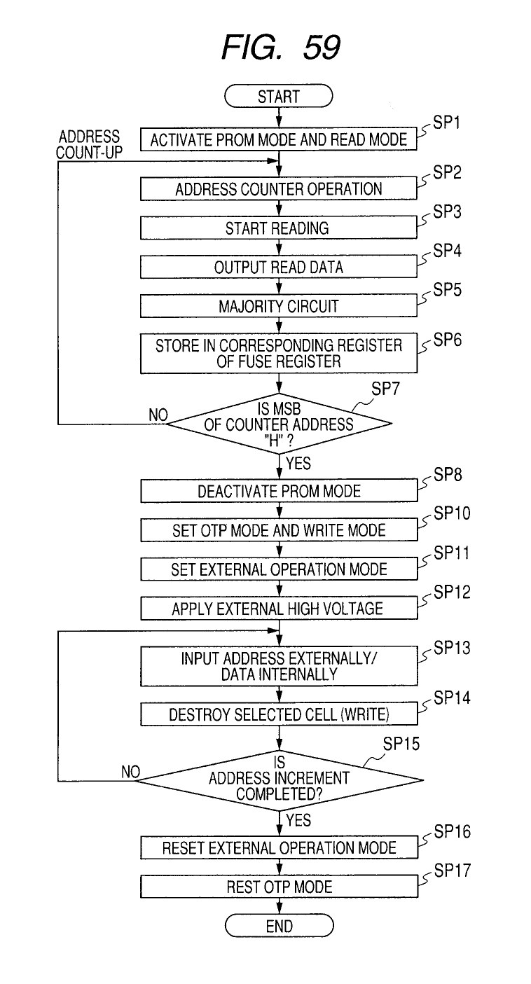

FIG. 59 is a flow chart illustrating more detailed process of the perfect non-volatization of the internal state setup data at the time of completion of a chip-level test at Step SS15 illustrated in FIG. 58. Hereafter, with reference to FIG. 59, converting operation of the PROM nonvolatile data to OTP perfect nonvolatile data is explained. Overall configuration of a semiconductor device and configuration of a control circuit are the same as explained in Embodiment 1, and the following explanation will be made with suitable reference to drawings relevant to Embodiment 1.

In a PROM/OTP array (40), according to a test result in a chip-level test process, operating environment setup data, such as trimming data, are generated and stored in a PROM mode.

First, a data read mode is set up according to a perfect non-volatization specifying command from the exterior (Step SP1). In the read mode which performs data reading, any of a PROM mode and an OTP mode may be set up. However, FIG. 59 illustrates as an example a case where a PROM mode is specified, as is the case with Embodiment 1. The read mode is set up according to a read/write mode instruction signal W/R of an external control signal (perfect non-volatization specifying command). By specifying an operation mode according to the external control signal, it is possible to realize the operation mode for writing destructively in the OTP mode the data which is written and stored in the PROM mode.

When the read mode is rendered ON state (when set up), the internal address generating circuit 100 and the internal control signal generating circuit 102 which are illustrated in FIG. 14 generate an internal address INAD and an internal control signal INCTL according to the mode instruction signal supplied from the exterior. The internal address generating circuit 100 includes an address counter inside. When activated according to the mode instruction signal, the internal address generating circuit 100 performs the count operation according to an external clock signal EXCLK, and generates the internal address (Step SP2).

The read/write mode instruction signal W/R is set as the state of specifying a read mode, and the write control signal is maintained in the initial state (non-active state). The column decoder (50l, 50r) illustrated in FIG. 6 generates a read column selection signal CSLR according to the internal address INAD. The bottom row decoder (42, 44b) drives a word line WL of a selected row to a selected state according to the row address of the internal address INAD. Data of the selected memory cell is supplied to the sense amplifier circuits (SA0-SAm), and internal read of the data is carried out (Step SP3).

The internal read data from the sense amplifier circuits are supplied to the majority circuit (24:MJK0-MJKk) illustrated in FIG. 6, decision of the logical value of the internal read data is made according to a majority decision criterion, and the majority decision result is stored in the corresponding register of the fuse register 26 (refer to FIG. 5) (Steps SP4, SP5, SP6). As a register which stores the read data, another register other than the fuse register may be used.

Subsequently, it is determined whether the most significant bit MSB of the counter address of the address signal generated from the address counter is set as H level (Step SP7). When the most significant bit MSB of the address (counter address) generated by the address counter is determined to be H level, the PROM mode is set to OFF state since all the stored data of memory cells as reading targets have been read and stored in the fuse register, and the data reading operation is completed (Step SP8).

On the other hand, at Step SP7, when the most significant bit MSB of the counter address is determined not to be H level, the address counter will operate again to perform count-up of the address, and henceforth operations from Step SP4 to Step SP7 are repeated. Operation from Step SP2 to Step SP7 are repeatedly executed until the most significant bit MSB of the counter address reaches H level, and internal read of necessary data, majority decision, and storing in a register, such as a fuse register are performed.

By a series of the operations, the test-result data in the chip final process is stored in a register. At the time of a product shipment, it is necessary to write the operating environment setup data in the OTP mode, and to store them permanently. At the time of data writing in the OTP mode, by performing internal read and internal writing of data, external supply of data is not necessary and external data writing which is different for every semiconductor device is also not necessary at the time of data writing in the OTP mode. Accordingly, control of data writing is simplified.

At Step SP8, when internal read of data in the PROM mode is completed (PROM mode becomes OFF), the OTP mode and the write mode indicating data writing are set internally. The control circuit may be formed so that, in the internal setup of a write mode, count-up of an address counter is detected in the interior, and the mode may shift to the OTP write mode (the present configuration is explained later). In the present case, it is necessary to output to the exterior a signal which indicates that the data reading in the PROM mode has completed. It is necessary to secure sufficient write time at the time of data writing in the OTP mode, because it is necessary to externally control the row/column selection.

As is the case with Embodiment 1, the setup of the OTP write mode may be performed in the mode setting circuit (32) illustrated in FIG. 4, with the aid of the mode selection signal MODESEL, the fuse activation signal FUSEN, and the read/write mode instruction signal W/R which are supplied from an external tester. Also in the present case, the most significant bit MSB of the counter address is outputted to the exterior as a ready signal at the time of completion of the data reading in the PROM mode, and the completion of the PROM read mode is notified to an external device (tester).

When the internal control signal is set as the state which indicates data writing in the OTP mode, an internal operation mode is set in the write control circuit 104 illustrated in FIG. 14 (Step SP10).

Subsequently, a bit-line writing voltage (VREFBL) is set to a high voltage level (Step SP12). By supplying the bit-line writing voltage VREFBL from the exterior, the necessity of generating a high writing voltage in the interior of the PROM/OTP-merged circuit is abolished as is the case with Embodiment 1, and the layout area otherwise to be occupied by the internal high voltage generation circuit is reduced.

Subsequently, the operating environment setup data after correction is read from the fuse register of the storage destination, and an address and a control signal are supplied from the exterior (Step SP13). At the time of the writing, data internally read from the fuse register as the write data is supplied instead of the external data. Time necessary for the OTP writing is secured by controlling the address externally.

In the present case, an internal address obtained from the address counter may be used instead of the external address. However, it is necessary to set a count operation cycle of the address counter as a period necessary for writing in the OTP mode, and it is also necessary to make the count cycle of the address counter longer than that of the PROM read mode in the interior.

At the time of the external operation in the OTP mode, a bit-line writing voltage and a digit-line writing voltage are applied from the exterior.

At the time of the external operation, an external control signal EXCTL and an external address signal EXAD are supplied. In the OTP-mode write control unit 107 of the write control circuit 104 illustrated in FIG. 14, the write control signals OTPW_CEL and OTPW_REF are generated, according to the external control signal EXCTL and the external address signal EXAD and the internal write data WD from the register. According to the data write directions in the OTP mode, the row decoder drives a word line of a selected row to a selected state according to the address signal. To the addressed three-bit memory cells, the high bit-line writing voltage VREFBL is applied, a barrier film of the variable magnetoresistive element is destroyed, an upper electrode and a lower electrode of the variable magnetoresistive element are short-circuited, and destructive writing is performed (Step SP14).

After the data writing has completed, it is determined whether the write address has arrived at the last address (Step SP15). The determination should just be performed in an external device (tester) by determining whether a bit corresponding to the most significant bit of the address counter is set to H level.

When the address has not arrived at the last address, flow returns to Step SP13 again, and the destructive writing of data is executed according to the external address signal EXAD, the external control signal EXCTL, and the write data WD, which are supplied from the exterior.

When the internal address from the address counter is utilized in the OTP-mode writing, an external device may perform determining of whether the most significant bit MSB of the internal address is H level and determining of whether the OTP-mode writing to all the addresses has been carried out. Alternatively, when the address counter is used, the most significant bit of the counter address may be utilized as a write completion flag.

At Step SP15, when it is determined that the address has arrived at the last address, the read/write mode instruction signal W/R is set to a non-active state, and the external operation mode is reset (Step SP16). Then, the mode selection signal MODESEL and the fuse activation signal FUSEN are deactivated, and the OTP mode is reset (Step SP17). Accordingly, the internal writing of data in the OTP mode to the necessary memory cells is completed.

When the OTP-mode data write in the interior is completed at Step SP17, the OTP write verify mode illustrated in FIG. 18 is executed to check the OTP-mode write data.

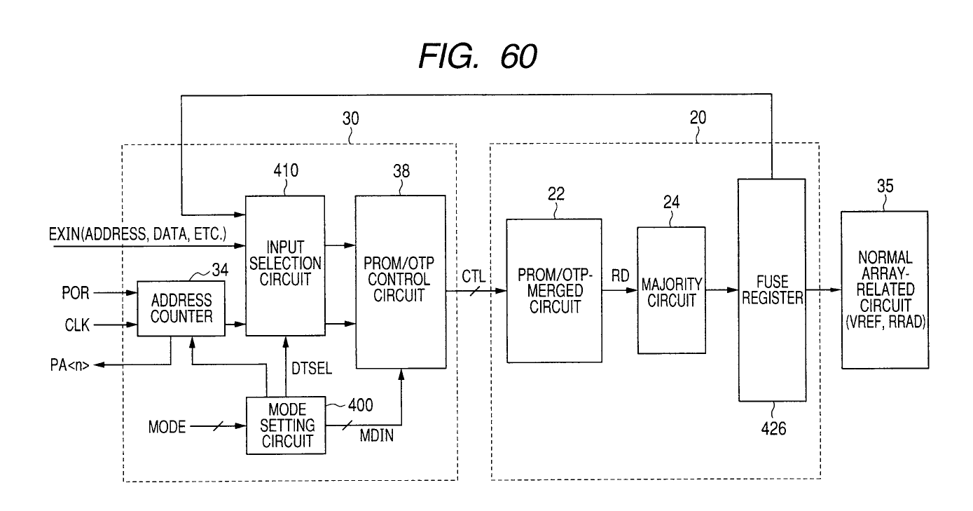

FIG. 60 illustrates roughly entire configuration of the semiconductor device according to Embodiment 3 of the present invention. The semiconductor device illustrated in FIG. 60 differs in configuration from the semiconductor device illustrated in FIG. 4 in the following points. That is, in the semiconductor device illustrated in FIG. 60, a fuse register 426 is formed by a shift register, and data read on an FIFO basis is supplied to an input selection circuit 410. The internal read data from the majority circuit 24 is stored in the fuse register 426 on an FIFO basis. The fuse register 426 supplies the stored data to the normal array circuit 35 in parallel, and sets up the operating environment (internal state) of the normal array circuit 35.

At the time of data writing in the OTP mode, the input selection circuit 410 selects the data read from the fuse register 426 in lieu of the data included in the external signal EXIN, and supplies the selected data to the PROM/OTP control circuit 38.

A path selection of the input selection circuit 410 and a data storing operation of the fuse register are controlled by a mode setting circuit 400. When the operation mode instruction signal MODE specifies perfect non-volatization of the stored data, the mode setting circuit 400 activates the address counter 34 to generate an internal address in a predetermined sequence. In the present case, the address counter 34 performs an address increment according to a signal of a logical addition of the power-on detection signal POR and the perfect non-volatilization mode instruction signal from the mode setting circuit 400.

The most significant bit PA<n> of the internal address (counter address) generated by the address counter 34 is externally outputted as a flag indicating access completion in all addresses to an external device.

The other configuration of the semiconductor device illustrated in FIG. 60 is the same as that of the semiconductor device illustrated in FIG. 4, therefore, the same reference number is attached to a corresponding part, and the detailed explanation thereof is omitted.

In the configuration illustrated in FIG. 60, by applying the operation mode instruction signal MODE to the mode setting circuit 400 from the exterior as a perfect non-volatilization instruction command, the PROM read mode is set up internally and data sequentially read is stored to the fuse register 426. When the external device (tester) determines that the PROM read mode has been completed, according to the most significant bit PA<n> of the counter address, voltage necessary for the OTP write mode is applied from the exterior, an address and a control signal necessary for selecting a row and a column are applied. At this time, the input selection circuit 410 selects data read from the fuse register 426, and supplies it to the PROM/OTP control circuit 38 as the internal write data.

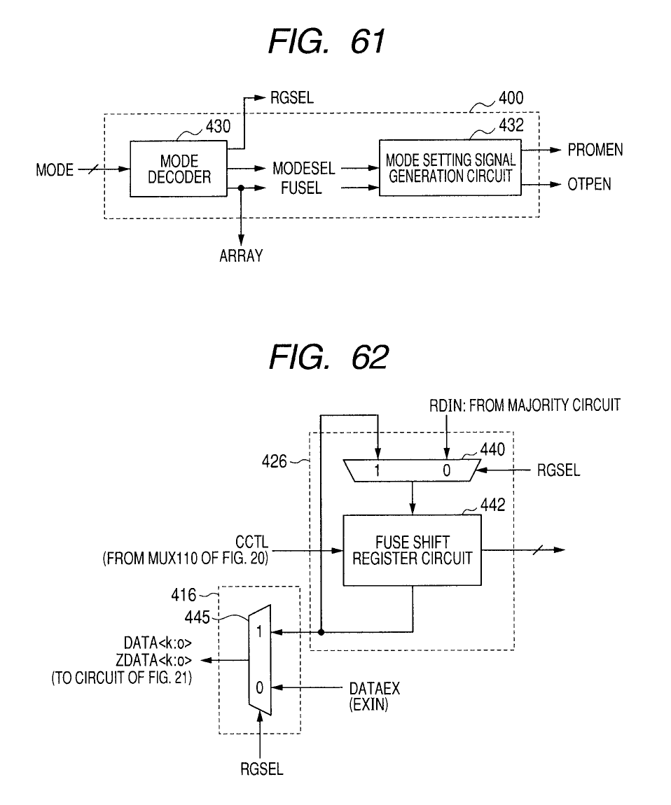

FIG. 61 illustrates roughly an example of configuration of the mode setting circuit 400 illustrated in FIG. 60. In FIG. 61, when the operation mode instruction signal MODE supplied from the exterior specifies the perfect non-volatilization mode of data, the PROM read mode and the OTP write mode are set up internally.

In FIG. 61, the mode setting circuit 400 includes a mode decoder 430 which generates an internal operation mode specification signal for specifying an operation mode, and a mode setting signal generation circuit 432 which generates an internal operation mode instruction signal according to the output signal of the mode decoder 430.

The mode decoder 430 decodes a control signal (command) MODE from the exterior, and generates internal operation mode instruction signals RGSEL, MODESEL, and FUSEN which correspond to the specified operation mode. The control signal RGSEL is a register selection signal, and sets up the data input path of the fuse register 426. The control signals MODESEL and FUSEN are equivalent respectively to the mode selection signal and the fuse activation signal which are illustrated in FIG. 8. That is, the mode selection signal MODESEL specifies either a PROM mode or an OTP mode. The fuse activation signal FUSEN is activated (set to H level) when performing a data access to the PROM/OTP-merged circuit. Access to the normal array is prohibited while the fuse activation signal FUSEN is activated.

The external device (tester) sets the OTP write mode, when the most significant bit PA<n> of the counter address becomes H level. That is, the external device (tester) monitors the most significant bit PA<n> of the counter address, and changes the operation mode from the PROM read mode to the OTP write mode.

The mode setting signal generation circuit 432 has the same configuration as the mode setting circuit illustrated in FIG. 8. When the fuse activation signal FUSEN is activated, according to the mode selection signal MODESEL, the mode setting signal generation circuit 432 activates selectively the PROM-mode enable signal PROMEN and the OTP-mode enable signal OTPEN. The enable signals PROMEN and OTPEN from the mode setting signal generation circuit 432 are supplied to the PROM/OTP control circuit 38.

Therefore, in reading and writing of the internal data in Embodiment 3 of the present invention, the internal control is performed as is the case with Embodiment 1 and the internal reading and internal writing of data are performed.

FIG. 62 illustrates roughly an example of configuration of the fuse register 426 and the input selection circuit 410 illustrated in FIG. 60. In FIG. 62, the fuse register 426 includes a multiplexer 440 which selects one of an internal read data RDIN from the majority circuit and internal read data from the fuse register according to a register selection signal RGSEL, and a fuse shift register circuit 442 which stores the data from the multiplexer 440 sequentially by a shift operation according to an internal clock signal INTCLK.

The multiplexer 440 selects the data read from the fuse register 426 when the register selection signal RGSEL is in a deassertion (negation) state, and selects the internal read data from the majority circuit when the register selection signal RGSEL is in an assertion state (when set to H level of “1”).

The fuse shift register circuit 442 performs a shift operation according to a column group control signal CCTL from the multiplexer 110 illustrated in FIG. 20, and stores the data from the multiplexer 440 sequentially.

The input selection circuit 416 includes a data multiplexer 445 which selects one of external data DATAEX (EXIN) and data read from the fuse register 426, according to the register selection signal RGSEL.

The data multiplexer 445 selects the external data when the register selection signal RGSEL is in a negation state, and selects data read from the fuse register 426 when the register selection signal RGSEL is in an assertion state. According to the selected data, the data multiplexer 445 generates complementary internal write data DATA<k:0> and ZDATA<k:0>, and supplies the data to the control circuits 124 and 126 illustrated in FIG. 21.

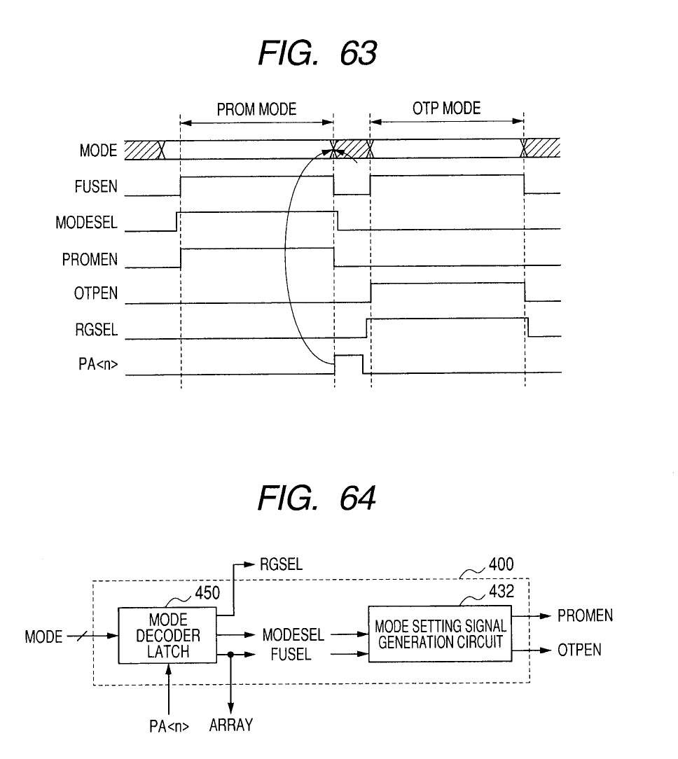

FIG. 63 is a timing chart illustrating operation of the circuits illustrated in FIG. 60 through FIG. 62. Hereafter, with reference to FIG. 63, the operation of the circuits illustrated in FIG. 60 through FIG. 62 is explained.

The mode control signal (mode specifying command) MODE is first set as the PROM read mode. Correspondingly, the fuse activation signal FUSEN supplied from the mode decoder 430 of the mode setting circuit 400 illustrated in FIG. 61 is activated, and the mode selection signal MODESEL is set to H level. Correspondingly, the PROM enable signal PROMEN is asserted and the PROM mode is specified. The OTP-mode enable signal OTPEN is maintained in a negation state. A read/write instruction signal W/R (not shown) is set in a state of data read.

At this time, the register selection signal RGSEL is in a negation state of L level, and the multiplexer 440 in the fuse register 426 illustrated in FIG. 62 is set in a state of selecting the internal read data from the majority circuit. In the input selection circuit 416 at this time, the data multiplexer 445 is set in a state of selecting the external data DATAEX.

As illustrated in FIG. 20, a PROM read mode is set up at this time, accordingly, even if the external write data is selected, the circuit relevant to writing is in a non-active state, and no malfunction occurs at all.

The address counter is activated and an address and a control signal are generated internally. According to the address and the control signal which are generated internally, read of the PROM-mode data is performed, and according to the column selection control signal, the fuse shift register 442 performs a shift operation for each column cycle to store the internal read data sequentially.

When the most significant bit PA<n> of the address outputted from the counter reaches H level, read of necessary data is completed. In response to the shift to H level of the most significant bit PA<n>, the external tester issues the mode specifying command again, and specifies an OTP mode. At this time, the fuse activation signal FUSEN and the OTP-mode enable signal OTPEN are asserted, and data writing in the OTP mode is performed. The register selection signal RGSEL is set to H level, and the multiplexers 440 and 445 select the output signal of the fuse shift register circuit 442. The read/write instruction signal W/R (not shown) is set in a state of data writing.

The fuse shift register circuit 442 shifts according to the column group control signal CCTL. At this time, the external address and the external control signal are selected, and the data writing in the OTP mode is performed under the external control. A shift operation of the fuse register is also performed (as illustrated in FIG. 20, in the write mode, the external control signal and the external address signal are selected). The address counter is maintained in a non-active state at this time.

Therefore, the data stored in the PROM mode is written in the OTP mode, and the perfect non-volatization of the stored data is accomplished. The reason why the re-writing of the read data of the fuse shift register circuit 442 is performed by the multiplexer 440 in the fuse register 426 is to prevent an unfixed data from being written in the fuse shift register circuit 442 with the result of unstable operation of the fuse shift register circuit.

When all the stored data of the fuse register 426 are written in the PROM/OTP array, the verifying operation as illustrated in FIG. 18 in performed. The completion of the data writing in the OTP mode can be effected by the external device (tester) detecting that a bit corresponding to the most significant bit (for example, count-up signal) of the counter address becomes H level. Accordingly, the internal read of non-destructive data in the PROM mode and the internal destructive writing of the data in the OTP mode can be performed.

(An Example of Modification)

FIG. 64 illustrates roughly configuration of a mode setting circuit of the semiconductor device as a modified example according to Embodiment 3 of the present invention. The mode setting circuit 400 illustrated in FIG. 64 differs in configuration from the mode setting circuit 400 illustrated in FIG. 61 in the following point. That is, in the mode setting circuit illustrated in FIG. 64, the operation mode instruction command MODE and the most significant bit PA<n> of the counter address from the interior is supplied to the mode decoder latch 450.

The mode decoder latch 450 maintains the fuse activation signal FUSEN at H level, when the operation mode specification signal MODE indicates the perfect non-volatization of data. When the most significant bit PA<n> of the address (counter address) from the address counter is L level, the mode decoder latch 450 sets the mode selection signal MODESEL to H level, and maintains the state. When the most significant address bit PA<n> rises to H level, the mode decoder latch 450 sets the mode selection signal MODESEL to L level, and maintains the state even if the most significant bit PA<n> falls to L level.

The other configuration of the mode setting circuit 400 illustrated in FIG. 64 is the same as the configuration illustrated in FIG. 61, therefore, the same reference number is attached to the corresponding part, and the detailed explanation thereof is omitted. The other configuration of the semiconductor device is the same as the configuration illustrated in FIGS. 60 and 62, and the detailed explanation thereof is omitted.

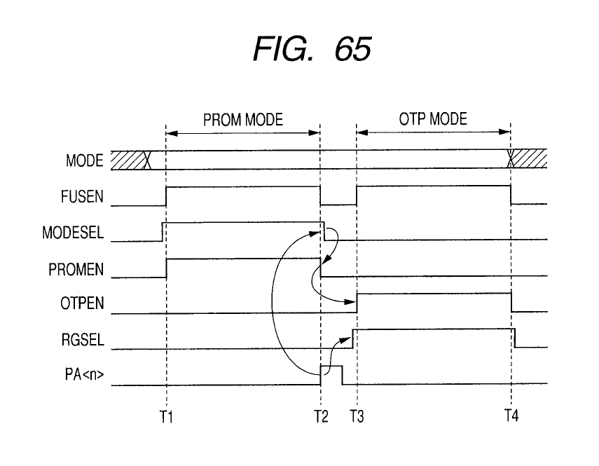

FIG. 65 is a timing chart illustrating operation of the mode setting circuit illustrated in FIG. 64. Hereafter, with reference to FIG. 65, operation of the mode setting circuit illustrated in FIG. 64 is explained.

At time T1, the operation mode instruction command MODE from the exterior is set as the state which specifies the perfect non-volatization of data. At this time, the most significant bit PA<n> of the internal counter address is L level, and the mode decoder latch 450 sets the mode selection signal MODESEL to H level and the fuse activation signal FUSEN to H level. Accordingly, the PROM mode is specified. The address counter operates internally, and the data read mode is specified by the internal control signal generation circuit. The register selection signal RGSEL is at L level, and data from the majority circuit is sequentially stored in the fuse register. Accordingly, data written in nondestructively is read in the PROM mode internally and is stored in the fuse register.

At time T2, when the most significant bit PA<n> of the counter address rises to H level, the mode decoder latch 450 sets the mode selection signal MODESEL to L level, maintaining the fuse activation signal FUSEN at H level. At time T3, the OTP-mode enable signal OTPEN becomes H level. Accordingly, the OTP write mode which performs destructive writing of data written nondestructively is set up. The internal address counter is reset and maintained in a non-active state. Even if the most significant bit PA<n> of the counter address is reset to L level, the mode decoder latch 450 maintains the mode selection signal MODESEL at L level and the fuse activation signal FUSEN at H level, respectively.

Responding to the most significant bit PA<n> of the counter address rising to H level, the external device (tester) generates an address signal and a control signal, and performs selection operation of a column and a row of the memory cell. At this time, the input selection circuit is set in the state which selects the control signal and the address signal from the exterior according to the write-mode instruction. As write data, read data from the fuse register is selected according to the register selection signal RGSEL. Accordingly, the data from the fuse register is destructively written in the PROM/OTP array, and the perfect non-volatization of the data is performed.

When the destructive writing of data is completed to the required address at time T4, the external device sets the mode instruction command MODE as a destructive write completion state, and the final test process at chip-level of the semiconductor device is completed.

Internal read and internal write of data are performed according to the same operation as in the case explained with reference to FIG. 60 through FIG. 63. Therefore, also in the configuration of the modified example illustrated in FIG. 64, it is possible to perform internal read of data, storing data in the fuse register, and destructive writing of data stored in the fuse register to the array, by following the same operation as in Embodiment 1.

As an alternative, at time T1, a command to specify the mode which performs destructive writing of non-destructively stored data may be supplied in a single shot mode, and after performing data reading and writing internally, the external device may supply a single-shot pulse indicative of a write-mode completion command at time T4. The external device has supplied the address externally at the time of data writing in the OTP mode, accordingly, the external device can identify the issue time of the last address.

As described above, according to Embodiment 3 of the present invention, by storing the chip-level test data nondestructively and writing the stored data destructively, the perfect non-volatization of the stored data is performed. Accordingly, it is possible to perform the perfect non-volatization of the operating environment setup data after the completion of the chip-level test, furthermore, it is possible to maintain the internal operation state of the semiconductor device in the predetermined state stably over a long period of time.

In Embodiments 1, 2, and 3, a cell is illustrated as an MRAM cell which sets up a magnetization direction of the free layer of the variable magnetoresistive element by a current-induced magnetic field. However, even if the cell is a spin torque transfer MRAM in which data writing by spin injection is performed to the variable magnetoresistive element, the present invention can be applied. In the spin torque transfer MRAM based on the spin injection method, current is flowed between a bit line and a source line in the direction determined by the logical value of write data, and the magnetization direction of the free layer is set up by spin torque transfer to the variable magnetoresistive element. The spin injection is performed at the time of data writing in the PROM mode, and a high voltage is applied between a bit line and a source line at the time of data writing in the OTP mode.

Generally, the nonvolatile memory unit of the semiconductor device according to the present invention is applicable to a memory unit, if the memory unit has circuit configuration in which the internal operation is set by programming operation internally. The memory unit may be used as a memory incorporated in a processor, and may be used as a memory single body. In this case, data writing in the PROM mode is performed at the time of a test mode, and after the completion of the test, operation is performed in the OTPROM mode at the time of the final test in commercial production, and the final data is programmed on a uncorrectable basis. Accordingly, satisfactory data storing characteristics can be realized, allowing accurate holding of data/parameters.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor device comprising:
a memory array including a plurality of nonvolatile memory cells arranged in a matrix, each memory cell operable to store data in a nonvolatile manner; and
a write control circuit operable to write data to the nonvolatile memory cells non-destructively in a rewritable manner in a first operation mode, and operable to write data to the nonvolatile memory cells destructively in a non-rewritable manner in a second operation mode.

2. The semiconductor device according to claim 1, further comprising:
a selection circuit operable to select a pair of nonvolatile memory cells according to a given address signal, in the first operation mode and the second operation mode,
wherein, in the first operation mode and the second operation mode, the write control circuit generates complementary data from given data and writes the complementary data concerned to the selected pair of nonvolatile memory cells.

3. The semiconductor device according to claim 1, further comprising:
a selection circuit operable to select in parallel a group of odd number of the nonvolatile memory cells according to a given address signal, in the first operation mode and the second operation mode;
a read circuit; and
a majority circuit,
wherein the write control circuit writes the same data to the selected group of odd number of the nonvolatile memory cells, and
wherein, in reading data, the read circuit reads data in parallel from the group of odd number of the nonvolatile memory cells and generates internal read data, and the majority circuit generates read data according to a majority decision criterion provided to the internal read data.

4. The semiconductor device according to claim 1,
wherein, in the first operation mode, the write control circuit generates a writing current internally and performs data writing to a selected memory cell according to the writing current concerned, and
wherein, in the second operation mode, the write control circuit performs data writing by applying an externally supplied voltage to a selected memory cell.

5. The semiconductor device according to claim 1, further comprising:
a normal array including a plurality of nonvolatile memory cells arranged in a matrix, each memory cell being operable to store normal data,
wherein each of the nonvolatile memory cells included in the memory array and the normal array has a series body of a variable magnetoresistive element and a selection transistor, and
wherein a gate insulating film of the selection transistor possessed by the memory cell of the memory array is thicker than a gate insulating film of the selection transistor possessed by the memory cell of the normal array.

6. The semiconductor device according to claim 1, further comprising:
a normal array including a plurality of nonvolatile memory cells arranged in a matrix, each memory cell being operable to store normal data,
wherein an arrangement interval of the memory cells included in the memory array is greater than an arrangement interval of the memory cells included in the normal array.

7. A semiconductor device comprising:
a memory array including a plurality of nonvolatile memory cells arranged in a matrix, each memory cell being operable to store data in a nonvolatile manner;
a register circuit operable to store data read from the memory array;
a write control circuit operable to write data to the nonvolatile memory cells non-destructively in a rewritable manner in a first operation mode, and operable to write data to the nonvolatile memory cells destructively in a non-rewritable manner in a second operation mode; and
a read control circuit operable to read data written in the memory array non-destructively in the second operation mode and operable to store the read data to the register circuit.
